(19) United States
(12) Patent Application Publication
(10) Pub. No.: US 2021/0036249 A1
(43) Pub. Date: Feb. 4, 2021

(54) SYSTEMS AND METHODS FOR BULK SEMICONDUCTOR SENSITIZED SOLID STATE UPCONVERSION

(71) Applicant: THE FLORIDA STATE UNIVERSITY RESEARCH FOUNDATION, INCORPORATED, Tallahassee, FL (US)

(72) Inventors: Lea Nienhaus, Tallahassee, FL (US); Sarah Wieghold, Tallahassee, FL (US)

(21) Appl. No.: 16/983,147

(22) Filed: Aug. 3, 2020

Related U.S. Application Data
(60) Provisional application No. 62/882,303, filed on Aug. 2, 2019.
(60) Provisional application No. 62/884,096, filed on Aug. 7, 2019.

(51) Int. Cl. H01L 51/42; H01L 51/00

(52) U.S. Cl. CPC H01L 51/4253; H01L 51/0026; H01L 51/0003

(57) ABSTRACT

Systems and methods for upconversion based on bulk semiconductor sensitizers are provided. In some aspects, issues with previous upconversion approaches are overcome using bulk-semiconductor thin films as sensitizers for the triplet state to achieve efficient upconversion based on triplet-triplet annihilation. Varying the film thickness shifts the threshold of efficient upconversion to subsolar incident powers, enabling practical applications for solar energy harvesting. Systems and methods are provided for upconversion of light in a solid state electronic device, the methods including exposing a bulk semiconductor to a first light source comprising light of a first wavelength, wherein the bulk semiconductor is associated with an organic material capable of upconversion via triplet-triplet annihilation from triplet states in the organic material; and observing light emitted from the organic material at a second wavelength, wherein the second wavelength is shorter than the first wavelength. A one-step synthesis of solid-state upconversion devices is also provided.

### CROSS REFERENCE TO RELATED APPLICATIONS

This application claims the benefit of U.S. Provisional Application No. 62/882,303, filed on Aug. 2, 2019 and U.S. Provisional Application No. 62/884,096, filed on Aug. 7, 2019, both of which are incorporated herein by reference in their entireties.

### TECHNICAL FIELD

The present disclosure generally relates to systems and methods for upconversion in solid state optoelectronic devices.

### BACKGROUND

Photon upconversion (UC) bears the potential in aiding to overcome the Shockley-Queisser limit determining the achievable power conversion efficiency (PCE) of single-junction photovoltaics (PVs) (Shockley, W., and Queisser, H. J., J. Appl. Phys. 32, 510-519, 1961). Infrared light is neither visible to the eye, nor to silicon-based optoelectronic devices such as photovoltaics (PVs) or cameras. The light simply passes through the device unused. Upconversion describes the process of converting low energy light into high energy light, which can then be utilized in the optoelectronic devices. As a result, photon UC can be used to overcome the Shockley-Queisser limit (denoting the maximum efficiency) in single-junction PVs by combining two or more low-energy photons to create one higher-energy photon. Hence, UC allows for the collection of sub-band-gap photons in PVs or the extension of the observable wavelengths of silicon-based devices.

UC allows for the collection of sub-bandgap photons in PVs or the extension of the observable wavelengths of silicon-based devices resulting in low-cost infrared imaging devices (Trupke, T., Green, M. A., and Würfel, P., J. Appl. Phys. 92, 4117-4122, 2002; Meng, F.-L., et al., Nanoscale 9, 18535-18545, 2017; He, M., et al., Angew. Chem. 128, 4352-4356, 2016). In photon UC, two or more low-energy photons are combined to create one higher-energy photon, effectively shortening the wavelength of the light emitted upon irradiation.

In organic semiconductors, the UC process is obtained via diffusion-mediated triplet-triplet annihilation (TTA) (Schmidt, T. W., and Castellano, F. N., J. Phys. Chem. Lett. 5, 4062-4072, 2014; Schulze, T. F., and Schmidt, T. W., Energy Environ. Sci. 8, 103-125, 2014). This is in contrast to nonlinear crystals or lanthanide-based nanoparticles, where the process is achieved by second-harmonic frequency generation or through the ladder-like electronic structure of the nanoparticles, respectively (Zhou, J., et al, Chem. Rev. 115, 395-465, 2015). Since the energy is stored in the long-lived triplet states, TTA has the advantage over the other UC processes of being efficient at even low photon fluxes (Singh-Rachford, T. N., and Castellano, F. N., Coord. Chem. Rev. 254, 2560-2573, 2010; Mahboub, M., et al., Nano Lett. 16, 7169-7175, 2016).

In TTA-UC in organic molecules, energy is stored in long-lived spin-triplet states, which cannot be directly excited by the incident light. These triplet states interact to form a higher energy emissive singlet state. Hence, sensitizers are required which absorb the light and funnel the energy to the triplet state of the organic molecules. Current UC techniques involve metal-organic complexes and or nanocrystals as sensitizers. However, current state-of-the-art solid-state UC devices are limited by poor exciton diffusion or large exchange energies between the singlet and triplet states. While direct triplet sensitization in organic molecules has been reported at high incident powers, this avenue is not feasible for solar applications of UC (Cruz, C. D., et al., J. Phys. Chem. C 122, 17632-17642, 2018). As triplets are “spin-forbidden” and are therefore not, or only weakly optically accessible, certain aspects herein rely on sensitizers to obtain sufficient triplet population for efficient TTA at sub-solar fluxes. In general, sensitized TTA-UC systems contain two parts: a sensitizer which is directly optically excited, and the emitter or annihilator, which is then indirectly excited via a spin-allowed Dexter-type triplet energy transfer (TET) process. Thus, one requirement for the sensitizer is the efficient interconversion of singlet states to triplet states, ideally with minimal energy loss in the process.

Recently, semiconductor nanocrystals (NCs) of lead sulfide (PbS), cadmium selenide (CdSe), or cesium lead halide perovskites (CsPbX₃, X═Br/I) have been employed as triplet sensitizers (Mahboub, M., et al, Nano Left. 16, 7169-7175, 2016; Nienhaus, L., et al., ACS Nano 11, 7848-7857, 2017; Huang, Z., et al., Nano Lett. 15, 5552-5557, 2015; Huang, Z., et al., Chem. Mater. 27, 7503-7507, 2015; Mase, K., et al., Chem. Commun. 53, 8261-8264, 2017; and Luo, X., et al., J. Am. Chem. Soc. 141, 4186-4190, 2019). Historically, metal-organic complexes containing heavy metal atoms were used as sensitizers, however energy losses exceeding 300 meV were observed due to the large exchange energies between the singlet and the triplet states. One drawback of employing NCs as sensitizers are the long insulating ligands passivating the NC surface, which add an additional energy barrier for the TET process. Subsequently, these cause poor exciton transport to the organic-inorganic interface in NC-based device structures. While this energy barrier has been able to be overcome in solution-based UC schemes by implementing transmitter ligands, this has not yet been demonstrated to be beneficial in solid-state UC (Huang, Z., and Tang, M. L., J. Am. Chem. Soc. 139, 9412-9418, 2017). In solid-state PbS-based UC devices for example, lack of long-range exciton diffusion restricts the PbS NC layer thickness to one or two monolayers, resulting in very low NIR absorption of well under 1%, limiting their achievable external UC efficiency (Geva, N., et al., J Phys. Chem. Lett, 10, 3147-3152, 2019; Wu, M., et al., Nat. Photon. 10, 31-34, 2016; Nienhaus, L., et al., ACS Nano 11, 7848-7857, 2017; and Nienhaus, L., et al., Daton Trans. 47, 8509-8516, 2018).

There remains a need for improved systems and methods for upconversion in solid state devices that overcome the aforementioned deficiencies. There further remains a need for simplified methods of construction of solid state upconversion devices that can reduce production time and costs while simultaneously improving performance of the devices. The present disclosure addresses these needs.

### SUMMARY

In various aspects, systems and methods are provided that overcome one or more of the aforementioned deficiencies with prior upconversion approaches. In some aspects described herein, these issues are overcome using bulk-semiconductor thin films as sensitizers for the triplet state to achieve efficient upconversion based on triplet-triplet annihilation. By varying the film thickness, the threshold of efficient upconversion is shifted to subsolar (monochromatic) incident powers enabling practical applications for solar energy harvesting. Also, because the upconversion can be based on the injection of free electrons and holes into the upconverting semiconductor, exemplary approaches described herein eliminate the need for efficient singlet-to-triplet converters, as in previous excitonic solid-state UC systems.

In various aspects, methods and systems are provided for upconversion of light in a solid-state optoelectronic device. Applicants have demonstrated in various aspects herein that, using bulk-semiconductor thin films as sensitizers for the triplet state the systems and methods can achieve efficient upconversion based on triplet-triplet annihilation. By varying the film thickness, the threshold of efficient upconversion is shifted to subsolar incident powers enabling practical applications for solar energy harvesting. In some aspects, the methods include exposing a bulk semiconductor to a first light source having light of a first wavelength, wherein the bulk semiconductor is associated with an organic material capable of upconversion via triplet-triplet annihilation from triplet states in the organic material; and observing light emitted from the organic material at a second wavelength, wherein the second wavelength is shorter than the first wavelength. Systems are also provided for the upconversion of light in a solid state optoelectronic device, e.g. including a bulk semiconductor layer capable of absorbing the first wavelength of light, and an organic material in contact with the bulk semiconductor, wherein the organic material is capable of upconversion via triplet-triplet annihilation from triplet states in the organic material to produce light at a second wavelength.

Additionally, disclosed herein is a one-step process for synthesizing solid state upconversion devices that overcomes some of the deficiencies of existing devices, including, but not limited to, photobleaching upon initial illumination.

Other systems, methods, features, and advantages of solid state upconversion systems and methods will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Further aspects of the present disclosure will be readily appreciated upon review of the detailed description of its various embodiments, described below, when taken in conjunction with the accompanying drawings.

FIG. 1 is a photograph of exemplary fabricated devices for the 380, 100, 30, and 20 nm thick methylammonium formamidinium lead triiodide (MAFA) films and the MAFA+rubrene/1%dibenzotetraphenylperiphlanthene (DBP) bilayer devices. The rubrene/1% DBP-only device is shown on the bottom right. The perovskite is dissolved by the epoxy resin (compare top right corners of each device), resulting in thinner films near the epoxy.

FIGS. 2A-2B are atomic force microscopy (AFM) images (3×3 μm²) of the 380 nm MAFA film (FIG. 2A) and the 380 nm MAFA film with spin-coated rubrene on top (FIG. 2B) showing the rubrene conforming to the underlying polycrystalline MAFA film.

FIG. 3 is a plot of the normalized steady-state photoluminescence (PL) of the MAFA films with varying thickness. The excitation wavelength was set to 405 nm.

FIG. 4 is a log-log plot of the MAFA PL intensity (NIR MAFA PL; λ>800 nm) as a function of the incident excitation power for the 380 (black), 100 (blue), 30 (green), and 20 nm (gray) thick films under 780 nm excitation. The dashed lines are fitted curves to extract the slope α.

FIGS. 5A-5B are log-log plots of the 14 nm MAFA+rubrene bilayer device PL intensity (NIR MAFA PL; λ>800 nm) as a function of the incident excitation power under 780 nm excitation (FIG. 5A). The dashed lines are fitted curves to extract the slope α. (FIG. 58) Power dependency of the upconverted PL (λ<650 nm) for the 14 nm MAFA+rubrene bilayer device. The dashed lines are fitted curves to extract the slope β. The TTA threshold (Iₜₕ) is marked as vertical line (purple) yielding a value of 767.1 mW/cm². The yellow vertical line indicates the equivalent solar irradiance of 1 sun (i.e. integrated AM1.5G standard spectrum).

FIG. 6 plots of the PL decay dynamics of the 20 nm MAFA film (left) and the MAFA+rubrene bilayer device (middle) under varying incident fluxes at an excitation wavelength of 780 nm. The graph on the right shows the difference in the dynamics, the extracted trap filling time (<1 ns) is seen in yellow. The extracted characteristic time of charge transfer is extracted as τ_{CT}=2 ns.

FIG. 7 is a steady-state UC PL spectra of the 380, 100 and 30 nm MAFA+rubrene bilayer devices under 780 nm continuous wave (CW) excitation.

FIG. 8 is the extracted characteristic lifetimes of trap filling for the (left) 380 nm MAFA+rubrene, (middle) 100 nm MAFA+rubrene and (right) 30 nm MAFA+rubrene bilayer devices.

FIGS. 9A-9F demonstrate the thickness dependent MAFA film morphology. FIG. 9A is a semi-log plot of the MAFA perovskite film thickness dependence on the varying molar precursor concentrations. The measured film thickness for the 1.2 M film is marked in the graph as (FIG. 9B) which results in a 380 nm thick film. A 0.06 M film yielding a 14 nm thick film is used as lower limit for the film thickness approximation and is marked in the graph as Ref. [43]. The film thicknesses of the 0.6, 0.24, and 0.12 M concentrations can be estimated according to the graph which result in film thicknesses of 100, 30, and 20 nm, respectively. (FIG. 98) Cross-sectional SEM image of the 1.2 M film yielding a film thickness of approx. 380 nm. Scale bar 500 nm. (FIGS. 9C-9F) AFM images of the 20 nm (FIG. 9C), 30 nm (FIG. 90), 100 nm (FIG. 9E), and 380 nm (FIG. 9F) MAFA perovskite thin films. Scale bar in all AFM images: 1 μm.

FIGS. 10A-10D depict exemplary schematics and optical film characterization. (FIG. 10A) Schematic of the UC bilayer device structure which is excited at a wavelength of 780 nm. To measure the MAFA film PL, an 800 nm long pass (LP) filter is used (i.e. NIR MAFA PL). To measure the UC properties, a 650 nm short pass (SP) filter is used (i.e. UC PL). (FIG. 10B) Schematic of the proposed rubrene sensitization mechanism: 1) incident light promotes an electron from the valence band (VB) (˜5.8 eV) to the conduction band (CB) (˜4.25 eV) of the MAFA perovskite. This excitation can be quenched by several pathways: 2) bimolecular free carrier recombination, 3) defect level trapping and 4) trap-assisted recombination or 5) carrier extraction to rubrene. The holes can be readily extracted to the highest occupied molecular orbital (HOMO) (˜5.4 eV) of rubrene, while the 1 eV mismatch of the perovskite CB and rubrene lowest unoccupied molecular orbital (LUMO) blocks direct electron injection into rubrene. However, the bound triplet state T₁ of rubrene can be populated. (FIG. 10C) Absorbance spectra of the MAFA thin films (solid lines) and the respective MAFA+rubrene bilayer devices highlighting the additional absorption caused by rubrene/1% DBP in the range of 430-530 nm (dashed lines). The absorption onset of MAFA can be seen at 800 nm for the devices, as expected for a 1.55 eV bandgap material. (FIG. 10D) Normalized steady-state PL of the MAFA+rubrene bilayer devices. The inset shows the rubrene/1% DBP PL for all four films. For comparison, spin-coated rubrene/1% DBP on bare glass is shown as a purple dashed line. The excitation wavelength of the laser was set to 405 nm.

FIGS. 11A-11H demonstrate the power-dependence under CW excitation. (FIGS. 11A-11D) Log-log plot of the MAFA+rubrene bilayer device PL intensity (NIR MAFA PL; λ>800 nm) as a function of the incident excitation power for the 380 nm (FIG. 11A), 100 nm (FIG. 11B), 30 nm (FIG. 11C) and 20 nm (FIG. 11D) films under 780 nm excitation. The dashed lines are fitted curves to extract the slope α, which increases with increasing film thickness. (FIGS. 11E-11H) Power dependency of the UC PL (λ<650 nm) for the MAFA+rubrene bilayer devices for the 380 nm (FIG. 11E), 100 nm (FIG. 11F), 30 nm (FIG. 11G) and 20 nm (FIG. 11H) films under 780 nm excitation. The dashed lines are fitted curves to extract the slope β. The TTA threshold (Iₜₕ) is marked as vertical line (purple). The PL slope changes are marked in the graphs as a black (380 nm), blue (100 nm), and green (30 nm) vertical line. The yellow vertical line indicates the equivalent solar irradiance of 1 sun (i.e. integrated AM1.5G standard spectrum), highlighting the sub-solar Iₜₕ values of the 30, 100 and 380 nm thick MAFA+rubrene devices.

FIGS. 12A-12I depict time-resolved PL spectra of the exemplary MAFA thin films and MAFA+rubrene bilayer devices. (FIGS. 12A-12C) NIR PL lifetimes of the 380, 100 and 30 nm thick MAFA thin films under varying incident powers or carrier densities at an excitation wavelength of 780 nm. At higher powers, the early time quenching diminishes due to an increased amount of trap filling, while the free carrier lifetimes decrease due to an increase in probability of recombination with carrier density. (FIGS. 12D-12F) NIR PL lifetimes of the 380, 100 and 30 nm thick MAFA+rubrene bilayer device under the same incident power. (FIGS. 12G-12I) Extracted difference in the lifetimes of the MAFA films vs. MAFA+rubrene devices, resulting in an extracted characteristic time of charge transfer of τ_{CT}=19 ns for the 100 nm device and τ_{CT}=3 ns for the 30 nm device. The samples were excited by a 780 nm laser at a repetition rate of 250 kHz.

FIGS. 13A-13C depict UC dynamics of the exemplary MAFA+rubrene bilayer devices. (FIG. 13A) UC PL dynamics (<650 nm) of the 100 nm MAFA+rubrene bilayer device at a repetition rate of 31.25 kHz, showing the characteristic rise and fall expected of TTA-UC. The inset shows the visible emission obtained from the bilayer device under 780 nm excitation. (FIG. 138) UC PL dynamics (<650 nm) of the 100 nm MAFA+rubrene bilayer device at a repetition rate of 250 kHz, highlighting the reduction in the characteristic time of diffusion-mediated TTA and the triplet decay when increasing the repetition rate due to a build-up of the triplet population. (FIG. 13C) Extracted difference in the MAFA PL (>800 nm) for the 380 nm MAFA+rubrene device, overlaid with a simple back transfer model accounting for exciton recycling.

FIG. 14 is a time-dependence of the UC PL counts under slow 20 Hz modulation of the pulsed laser by a mechanical chopper, resulting in a 25 ms “on time” and a 25 ms “off time,” highlighting the reproducibility of the fast PL decay in the first 5 s. Slow photobleaching of the sample is also observed.

FIG. 15 is a PL spectrum of the NIR MAFA emission from the bilayer device under 405 nm excitation. No shift of the MAFA PL peak at ˜780 nm is observed.

FIG. 16 is a time-dependent UC PL dynamics, highlighting the change in the magnitude of the early time component with increasing triplet population.

FIG. 17A is an absorbance spectrum of the bilayer device, showing the expected onset of absorption at 800 nm (black). PL of the bilayer device under 405 nm CW excitation (blue), highlighting the visible DBP emission at 605 nm, and the NIR MAFA emission at 780 nm. Visible UC PL is obtained under 780 nm CW excitation (orange). FIG. 17B is a time-dependence of the UC PL counts upon 780 nm pulsed excitation. FIG. 17C is a time-dependence of the UC PL counts under slow 20 Hz modulation of the pulsed laser by a mechanical chopper, resulting in a 25 ms “on time” and a 25 ms “off time.” FIG. 17D is the dynamics of the UC PL (600±40 nm) under 780 nm excitation, showing three different regimes: a fast-rising component (regime 1), a slow-rising component (regime 2) and a slow decay (regime 3) corresponding to the long-lived triplet lifetime (τₜᵣᵢₚₗₑₜ>12 μs). The repetition rate of the pulsed laser is set to 31.25 kHz at an average incident power of 4 μW.

FIG. 18A is a time-dependent evolution of the MAFA+rubrene/1% DBP emission spectrum obtained under 780 nm CW excitation. The MAFA emission is observed at 700 nm, the rubrene/1% DBP emission is obtained at 605 nm. FIG. 18B is a PL intensity of the NIR MAFA PL at 700 nm (black) and the UC PL at 605 nm (orange) as a function of time. FIG. 18C is a plot of the ratio of the emission obtained at 605 and 700 nm, indicative of a change in the UC efficiency as a function of time. FIG. 18D is a time-dependent PL spectra of the MAFA+rubrene/1% DBP bilayer device under 20 Hz chopped 780 nm excitation. FIG. 18E is a PL intensity tracking of the NIR MAFA PL at 700 nm (black) and the UC PL at 605 nm (orange). FIG. 18F is a ratio of the emission detected at 605 and 700 nm under chopped excitation. The laser power is set to an average CW power of 37 mW.

FIG. 19A is a NIR MAFA PL dynamics under pulsed excitation at 31.25 kHz at an average incident power of 4 μW (black), 2 μW (purple), as well as under 20 Hz chopped illumination (gray, 4 μW incident power, 50% chopper duty cycle, 25 ms “on time,” 2 μW average power). FIG. 19B is a UC PL dynamics (600±40 nm) under the same excitation conditions. FIG. 19C is a zoom in on the early time dynamics of the time-resolved UC PL, highlighting the two rise times observed. FIG. 19D is a schematic of the triplet population modulation by the chopped excitation source. FIG. 19E is a schematic of the triplet population under continuous pulsed excitation rate that does not allow the triplets to fully decay between pulses. FIG. 19F is a schematic highlighting the long triplet diffusion lengths at low triplet concentrations, followed by TTA far from the MAFA/rubrene interface. FIG. 19G is a schematic of the two regimes occurring at high triplet populations: rapid interface-mediated TTA, which is subject to strong parasitic back-transfer of the emissive singlet states, and slow-diffusion mediated TTA.

FIG. 20A is a schematic of an organic semiconductor (OSC) device. FIG. 20B shows molecular structures of the organic semiconductors: rubrene (purple) and dibenzotetraphenylperifanthene (DBP, yellow). FIG. 20C shows absorption of the OSC devices with various amounts of the dopant dye DBP. FIG. 20D shows steady-state emission spectra under 405 nm excitation of the OSC thin film devices. The gray arrow indicates the increase of the shoulder at ˜680 nm, indicating DBP aggregation. FIG. 20E shows PL lifetimes of the OSC films under 405 nm excitation. The early time component is elongated, and the delayed fluorescence is reduced (black arrows).

FIG. 21A shows absorbance spectra of the MAFA/rub films doped with varying DBP percentages. FIG. 21B is a schematic of the device architecture: both 405 nm and 780 nm excitation result in OSC and MAFA emission. FIG. 21C shows steady-state emission spectra under 405 nm excitation of the MAFA/rubDBP devices. The OSC emission is shown on the left, and the perovskite emission is shown on the right (black). FIG. 21D shows PL dynamics of the MAFA/rubDBP films under 405 nm excitation at an incident power of 7.1 μW and a repetition frequency of 250 kHz. The lifetimes were integrated over a spectral region of 760 to 810 nm from the time resolved emission spectra (TRES) in FIG. 21E. FIG. 21E shows a time resolved emission map for the MAFA/1.4% DBP film (left) and the normalized integrated emission spectra (right). The map was collected under 405 nm excitation at a repetition frequency of 250 kHz. FIG. 21F shows PL dynamics from 550 to 650 nm extracted from the TRES in FIG. 21E.

FIGS. 22A-B are box plots of the integrated PL intensities from 500-700 nm of 7 different spots on various films with varying DBP doping percentages. The “whiskers” show the range of the data, while the line gives the median. FIG. 22A shows upconversion photoluminescence (UCPL) emission intensities of the various doping concentrations under 780 nm excitation. The dashed gray line shows the average integrated photoluminescence (PL) intensity, while the gray box indicates the range of uncertainty based on the whiskers. FIG. 22B shows the UCPL intensities shown in FIG. 22A divided by the emission under 405 nm excitation (compare FIGS. 32A-B).

FIGS. 23A-B show PL dynamics of the MAFA/rubDBP films under 780 nm excitation at 31.25 kHz and a power density of 21 mW/cm². FIG. 23A shows PL decay dynamics of the MAFA perovskite emission (>800 nm). FIG. 23B shows UCPL dynamics of the MAFA/rubDBP samples, showing the typical rise and fall of the upconverted PL.

FIG. 24A shows a log-log plot of the UCPL intensity (integrated over 20 s) as a function of the incident laser power density. The curves are offset for clarity, and therefore not an indication of the absolute PL intensity. The dashed lines are added to guide the eye to the observed slope changes. The gray shaded region highlights the uncertainty region of the extracted Iₜₕ values. FIG. 24B shows steady-state emission spectrum of the UCPL emission of the MAFA/rubDBP samples under 780 nm excitation. The black arrow highlights the decrease of the rubrene PL at 565 nm, and the gray and blue-green arrow highlight the increasing red-shift of the upconverted PL. FIG. 24C shows the ratio of the 565/605 nm emission peaks for the MAFA/rubDBP samples under 405 nm excitation (blue outline) and 780 nm excitation (red outline).

FIG. 25 shows UV-Vis absorbance of the OSC-only films on glass.

FIGS. 26A-C show OSC solution characterization. FIG. 26A shows normalized UV-Vis absorption of rubrene and DBP in toluene (10 mg/mL). FIG. 26B shows normalized steady-state emission of rubrene and DBP in toluene under 405 nm excitation. FIG. 26C shows time-resolved PL lifetimes of rubrene and DBP in toluene under 405 nm excitation at an incident power of 0.2 μW and a repetition frequency of 5 MHz.

FIG. 27 shows integrated PL emission of the MAFA/rub devices doped with various amounts of DBP under 405 nm excitation. The PL emission was normalized to their relative maxima of the perovskite emission (˜780 nm). The PL emission was recorded at a repetition frequency of 250 kHz and an incident power of 7.1 μW, and spectrally resolved using the Gemini interferometer.

FIGS. 28A-B show PL decay dynamics of the MAFA only and MAFA/1.4% DBP under 405 nm (FIG. 28A) and 780 nm excitation (FIG. 28B). The 405 nm lifetimes were taken at an incident power of 7.1 μW and a repetition frequency of 250 kHz. The 780 nm lifetimes were taken at an incident power of 8.2 μW and a repetition frequency of 62.5 kHz.

FIGS. 29A-H show integrated PL spectra and TRES of the OSC thin films under pulsed 405 nm excitation at an incident power of 306 μW and a repetition frequency of 10 MHz.

FIGS. 30A-H show extracted PL spectra and TRES of the MAFA/OSC devices under pulsed 405 nm excitation at an incident power of 7.1 μW and a repetition frequency of 250 kHz.

FIGS. 31A-G show upconverted PL of the MAFA/OSC devices in seven different locations. The films were measured under continuous wave 780 nm excitation at an incident power of 40 mW. A 700 nm short pass filter was used to remove excess laser scatter.

FIGS. 32A-B are box plots of the integrated PL intensities from 500 to 700 nm on 7 different spots on MAFA/OSC (FIG. 32A) films and OSC-only films (FIG. 32B).

FIG. 33 shows upconverted PL dynamics of three different MAFA/rub spot locations. UC PL dynamics were recorded under 780 nm excitation at an incident power of 4.1 μW with a repetition frequency of 31.25 kHz.

FIGS. 34A-D show detector external quantum efficiency (EQE) influence on the TRES, lifetime, and spectrum for the MAFA/1.4% DBP film. FIG. 34A shows TRES under 405 nm excitation without the detector EQE compensation. FIG. 34B shows PL decay dynamics with and without the detector EQE compensation. FIG. 34C shows TRES accounting for the detector EQE. FIG. 34D shows detector EQE.

FIG. 35A is schematic of the investigated bilayer device architecture showing molecular structures of the used OSC layers: rubrene (pink), dibenzotetraphenylperifianthene (DBP, purple), and 9,10-diphenylanthracene (DPA, blue). FIG. 35B shows absolute energy levels of the perovskite (black) valence and conductions bands, and the HOMO,LUMO and triplet energies T₁ of rubrene (pink), DBP (purple) and DPA (blue). FIG. 35C shows absorbance and steady-state photoluminescence (405 nm excitation): MAFA, MAFA/rub/DBP, MAFA/toluene, MAFA/rub, MAFA/DBP, and MAFA/DPA. The dashed line indicates the MAFA peak PL and is a guide to the eye to highlight the slight blue-shift of the additionally solution-processed films.

FIG. 36 is a log-log plot of the power dependence of the MAFA PL (λ>800 nm) as a function of the incident power. The MAFA film (black) shows the expected slope of α=1.6. The MAFA/toluene film exhibits a change from α=1.0 to α=1.4, indicative of a higher trap density due to the second solution-processed step. The power dependence of the PL is mostly recovered with the addition of the organic layers, indicative of MAFA surface trap passivation.

FIG. 37 shows NIR MAFA PL decay dynamics for the MAFA (black), MAFA/toluene (gray) and MAFA/organic bilayer devices (green, pink, purple, blue). The lifetimes were taken at 3.2 mW/cm² incident power density at 31.25 kHz repetition rate, 780 nm excitation wavelength using an 800 nm long pass filter to remove laser scatter.

FIG. 38A shows band alignment diagram showing the upward band bending of the perovskite of 0.1 eV and the downward band bending of rubrene of 0.3 eV. Due to the energetic alignment, electrons accumulate in the perovskite layer near the interface and holes in the rubrene layer to achieve equilibrium. This induces an electric field which “pins” the charges and creates an energy barrier for diffusion. Upon initial excitation, the rubrene triplet state is rapidly populated and TTA can occur efficiently despite parasitic singlet back-transfer. Under constant illumination, a diffusion-limited steady-state condition is achieved. Also shown is a schematic of the processes occurring in the band alignment diagram. FIG. 38B shows normalized UC PL (λ=600±40 nm) intensity under 3.2 mW/cm² excitation density, using a pulsed 780 nm laser at 31.25 kHz. The maroon dashed line highlights the time when the sample is illuminated. The purple box indicates the first 5 s after illumination, over which the “precharged” electrons and holes are depleted. FIG. 38C shows normalized NIR PL (λ>800 nm) of the underlying MAFA sensitizer under the same conditions. The purple dashed lines in FIGS. 38B-C are guides to the eye to highlight the slow photobleach of the perovskite and UC PL over the 25 s on-time investigated.

FIG. 39 shows normalized UC PL intensity under 3.2 mW/cm² excitation density using a pulsed 780 nm laser at 31.25 kHz monitored for 25 s after illumination. First, the sample is kept in the dark until initial illumination (maroon dashed line), then left in the dark for 16 h to recover and illuminated again. Both samples show the previous trend, a rapid “photobleach” over the first 5 s, and then a slow plateauing. After 3 min rest in the dark, the UC PL has only marginally recovered, highlighted by the black and dark gray dashed lines as guides to the eye. After 35 min in the dark, the UC PL has recovered more (light gray dashed line), indicating that interfacial charge accumulation occurs on a time-scale of several hours.

FIGS. 40A-C show thin film characterization. FIG. 40A is a schematic of the one-step UC device fabrication (top) and a schematic of the bilayer device fabrication (bottom). FIG. 40B shows absorbance spectra of the MAFA control (black), bilayer (gray), and in situ fabricated UC devices (blue), showing the same absorption onset and optical density (left), corresponding emission spectra of the MAFA peak under 405 nm excitation (center), and rubrene emission under 405 nm excitation (right). FIG. 40C shows x-ray diffraction (XRD) patterns of the respective perovskite thin films, showing the expected cubic crystal structure (left) and enlargement of the XRD pattern at ˜14° to highlight the gradual peak shift to larger angles, indicating a slight contraction of the lattice upon increasing amounts of rubrene (center). The dotted line is a guide to the eye and marks the peak position of the bilayer perovskite film. Also shown are the grazing incidence x-ray diffraction (GIXRD) patterns of the MAFA control, bilayer, and in situ fabricated devices (right).

FIGS. 41A-F show atomic force microscopy. 3×3 μm² AFM images of the MAFA control (FIG. 41A), bilayer device (FIG. 41B), and one-step fabricated UC devices (FIGS. 41C-F). The polycrystalline nature of the underlying MAFA thin film is clearly visible. The addition of rubrene results in an amorphous layer and large agglomerates with increasing rubrene concentration.

FIGS. 42A-D show PL mapping of a 10×10 μm² area. Emission maps of the MAFA emission (left) and rubrene emission (right) for the 10 mg/mL (FIG. 42A), and 5 mg/mL one-step UC devices (FIG. 42B) under 488 nm excitation. Corresponding MAFA (left) and upconverted rubrene (right) emission maps of the 10 mg/mL (FIG. 42C), and 5 mg/mL UC devices (FIG. 42D) under 640 nm excitation.

FIG. 43A shows MAFA PL decay dynamics under 780 nm excitation (31.25 kHz, 21 mW/cm²) for the control (black), bilayer (gray) and one-step fabricated UC devices. FIG. 43B shows upconverted emission spectra obtained for the respective UC devices under 780 nm continuous wave illumination. FIG. 43C shows dynamics of the upconverted emission under 780 nm excitation (31.25 kHz, 21 mW/cm²). With increasing rubrene concentration, the dynamics change from interface-mediated rapid TTA to slower diffusion-mediated TTA. FIG. 43D is a double logarithmic plot of the power dependence of the upconverted emission as a function of the incident power density for the bilayer device (gray) and the one-step fabricated devices (blue). The curves are offset for clarity, therefore the position on the y-axis does not correlate to the actual intensity. The gray shaded region highlights where TTA saturates. The E=10 mW/cm² for the bilayer device is shown by the dotted line. The expected slope change from quadratic (α=3.2) to linear (α=1.6) shifts to lower incident power densities with decreasing rubrene concentration in the antisolvent.

FIGS. 44A-B are schematics of the bilayer and one-step fabricated UC devices. In the bilayer device, the additional solution-processed step allows the rubrene to coat the underlying MAFA layer. Aggregates are formed on the surface. The interface is limited to the surface area of the created MAFA film (FIG. 44A, left). PL intensity of the upconverted emission in the bilayer film over time, showing a strong decay in the intensity (FIG. 44A, right). In the one-step process, the rubrene is added prior to annealing of the perovskite film. It therefore can intercalate into the film, coating the sides of the perovskite grains, thus creating a much larger interface for charge extraction. Excess rubrene is expelled to the surface and can form agglomerates (FIG. 44B, left). PL intensity of the upconverted emission in the 10 mg/mL one-step fabricated film. The respective insets highlight the directionality of the built-in electric field (FIG. 44B, right).

FIG. 45 shows a schematic of possible variations in the UC device fabrication processes including: solvent choice and its effect on the annihilator layer rubrene/DBP (top left), the presence of an excess of lead iodide at the perovskite sensitizer interface (top right), the composition of the perovskite sensitizer (bottom left), and the use of thermal annealing within each processing step for the bilayer device (bottom right). Additionally, the interplay of these variables is critical (outer middle panels) to the overall performance of the bilayer UC device (middle).

FIGS. 46A-F show absorption and steady-state emission spectra for the bilayer UC devices based on a FIGS. 46A, 46D stoichiometric (S) methylammonium-rich perovskite, FIGS. 468, 46E overstoichiometric (O) methylammonium-rich perovskite, FIGS. 46C, 46F overstoichiometric formamidinium-rich (FO) perovskite. The annihilator layer was spin-coated either from dissolved rubDBP in tol or CB. FIGS. 46A-46C are the bilayer devices as fabricated, whereas FIGS. 46D-F are subject to an additional annealing step at 100° C. for 10 min. The steady state emission spectra were obtained under 405 nm excitation at a power density of 355 mW/cm². A 425 nm long pass filter was used to remove excess laser scatter.

FIGS. 47A-F show perovskite PL decay dynamics under 780 nm excitation showing the pristine UC devices (blue curves) and annealed devices (red curves). The different solvents toluene (tol) and chlorobenzene (CB) for the rubDBP layer are shown as dark and light colors, respectively for the FIGS. 47A-47B stoichiometric (S) methylammonium-rich perovskite rubDBP bilayer, FIGS. 47C-47D overstoichiometric (O) methylammonium-rich perovskite rubDBP bilayer, and FIGS. 47E-47F overstoichiometric (FO) formamidinium-rich perovskite rubDBP bilayer. The decay dynamics were recorded at a repetition frequency of 31.25 kHz and a power density of 4.84 mW/cm².

FIGS. 48A-48E show UC PL emission of FIG. 48A stoichiometric (S) methylammonium-rich perovskite rubDBP bilayer, FIG. 48B overstoichiometric (O) methylammonium-rich perovskite rubDBP bilayer, and FIG. 48C overstoichiometric (FO) formamidinium-rich perovskite rubDBP bilayer. The pristine UC devices are shown in blue, and the annealed devices in red. The different solvents tol and CB for the rubDBP layer are shown as dark and light colors, respectively. FIG. 48D shows box plots of the UC PL intensity integrated from 500-700 nm obtained for 30 different spots on each UC device. The UC PL was recorded under 780 nm CW excitation at a power density of 45.2 W/cm². A 700 nm short pass filter was used to record the UC PL. FIG. 48E shows box plots of the UC PL integrated from 500-700 nm normalized by the same integrated area under 405 nm excitation at a power density of 355 mW/cm².

FIGS. 49A-49C shows box plots depicting the ratio of the residual rubrene peak emission at 560 nm and the DBP peak emission at 605 nm for all investigated UC devices under CW FIG. 49A 780 nm (45.2 W/cm²), and FIG. 49B 405 nm excitation (355 mW/cm²). FIG. 49C shows corresponding spectra using 405 nm excitation.

FIG. 50 shows representative UC PL dynamics of the CB-treated overstoichiometric (O) methylammonium-rich perovskite rubDBP bilayer devices for the pristine (blue) and the annealed UC device (red). The early-time component (0-3 μs) is shown in the inset. The UC PL was recorded under 780 nm excitation at a repetition frequency of 31.25 kHz and a power density of 4.84 mW/cm². A 600/40 nm (center/width) band pass filter was used.

FIGS. 51A-F show absorption and steady-state emission spectra for the perovskite films with and without tol or CB solvent treatment. FIGS. 51A, 51D stoichiometric (S) methylammonium-rich perovskite, FIGS. 51B, 51E overstoichiometric (O) methylammonium-rich perovskite, FIGS. 51C, 51F overstoichiometric formamidinium-rich (FO) perovskite. The solvent treated films were spin-coated with 20 μL of either tol or CB. FIGS. 51A-51C are the films as fabricated whereas FIGS. 51D-51F are subject to an additional annealing step at 100° C. for 10 min. The steady-state emission spectra were obtained under 405 nm excitation at a power density of 355 mW/cm². A 425 nm long pass filter was used to remove excess laser scatter.

FIGS. 52A-52F show steady-state emission spectra normalized to the peak emission of the perovskite for the bilayer UC devices and perovskite films with and without solvent treatment. FIGS. 52A, 52D stoichiometric (S) methylammonium-rich perovskite, FIGS. 52B, 52E overstoichiometric (O) methylammonium-rich perovskite, FIGS. 52C, 52F overstoichiometric formamidinium-rich (FO) perovskite. FIGS. 52A-52C are the perovskite films with and without solvent treatment or the bilayer UC devices as fabricated. FIGS. 52D-52F are the perovskite films with and without solvent treatment or the bilayer UC devices with an additional annealing step at 100° C. for 10 minutes. The steady-state emission spectra were obtained under 405 nm excitation at a power density of 355 mW/cm². A 425 nm long pass filter was used to remove excess laser scatter.

FIGS. 53A-53F show perovskite PL decay dynamics under 780 nm excitation showing the perovskite films with and without solvent treatment. The blue curves are the films as fabricated and the orange curves are the films with the addition annealing step. FIGS. 53A-53B stoichiometric (S) methylammonium-rich perovskite, FIGS. 53C-53D overstoichiometric (O) methylammonium-rich perovskite, and FIGS. 53E-53F overstoichiometric (FO) formamidinium-rich perovskite film. The decay dynamics were recorded at a repetition frequency of 31.25 kHz and a power density of 4.84 mW/cm².

FIGS. 54A-54C show OSC PL decay dynamics under 405 nm excitation for the bilayer UC devices. FIG. 54A stoichiometric (S) methylammonium-rich perovskite rubDBP bilayer, FIG. 54B overstoichiometric (O) methylammonium-rich perovskite rubDBP bilayer, and FIG. 54C overstoichiometic (FO) formamidinium-rich perovskite rubDBP bilayer. The blue traces indicate the bilayer devices as fabricated and the red traces are the post fabrication annealed devices. The OSC PL was recorded under 405 nm excitation at a repetition frequency of 125 kHz and a power density of 0.05 mW/cm². A 650 nm short pass and 425 nm long pass filter was used to remove residual perovskite emission and excess laser scatter.

FIG. 55 shows box plots of the integrated steady-state PL intensity integrated from 500-700 nm obtained from 30 different spots on each of the UC devices. The steady state PL was recorded under 405 nm CW excitation at a power density of 355 mW/cm². A 425 nm long pass filter was used to remove excess laser scatter.

FIG. 56 shows The log-log plot of the (top row) perovskite PL emission (>800 nm) and (bottom row) UCPL intensity plotted against the incident power of the laser. The data sets are offset for clarity and in both cases, the PL intensity was integrated over 20 s under 780 nm excitation under variable incident powers. A 800 nm long pass filter was used to collect the perovskite emission and a 600/40 nm (center/width) band pass filter was used for the UC PL measurements.

FIGS. 57A-57F show UC PL dynamics of the bilayer devices. FIGS. 57A, 57D stoichiometric (S) methylammonium-rich perovskite bilayer, FIGS. 57B, 57E overstoichiometric (O) methylammonium-rich perovskite bilayer, FIGS. 57C, 57F overstoichiometric (FO) formamidinium-rich perovskite bilayer. The light blue and dark red traces indicate the films fabricated with CB as the solvent for rubDBP with and without the post thermal annealing step, respectively. The dark blue and dark red indicate the films fabricated with tol as the solvent for rubDBP with and without the post thermal annealing step, respectively. The UC PL was recorded under 780 nm excitation at a repetition frequency of 31.25 kHz and a power density of 4.84 mW/cm². A 600/40 nm (center/width) band pass filter was used to selectively investigate the UC PL.

### DETAILED DESCRIPTION

In various aspects, systems and methods are provided that overcome one or more of the aforementioned deficiencies with prior upconversion approaches. In some aspects described herein, these issues are overcome using bulk-semiconductor thin films as sensitizers for the triplet state to achieve efficient upconversion based on triplet-triplet annihilation. By varying the film thickness, the threshold of efficient upconversion is shifted to subsolar incident powers enabling practical applications for solar energy harvesting. Also, because the upconversion can be based on the injection of free electrons and holes into the upconverting semiconductor, exemplary approaches described herein eliminate the need for efficient singlet-to-triplet converters, as in previous excitonic solid-state UC systems.

In some aspects, the nanocrystal array of prior upconversion systems are replaced with a bulk semiconductor thin film which shows long carrier diffusion lengths and free carrier lifetimes exceeding the characteristic time of energy transfer from the sensitizer to the annihilator. In some aspects, this is accomplished with perovskite thin films which have shown impressive performances and efficiencies when integrated in perovskite solar cells (PSCs) due to their exceptional material properties.

Besides the sensitizer, some of the upconversion systems and methods described herein employ an annihilator. In this regard, rubrene, a p-type semiconductor tetraphenyl derivative of tetracene has been extensively studied due to the exceptional high hole mobility and chemical stability (Currie, M. J., et al, Science 321, 226, 2008; Sundar, V. C., et al., Science 303, 1644, 2004; Podzorov, V., et al., Phys. Rev. Lett. 93, 086602, 2004). The onset of electroluminescence (EL) is observed at ˜1 eV, or roughly half the rubrene bandgap (2.2 eV) which has been attributed to either Auger-type upconversion, upconversion through a triplet-triplet annihilation (TTA) pathway, or band-to-band recombination of minority carriers (Pandey, A. K., and Nunzi, J.-M., Appl. Phys. Lett. 90, 263508, 2007; Pandey, A. K., Sci. Rep. 5, 7787, 2015; Engmann, S., et al., Nature Commun. 10, 227, 2019).

In representative examples, to take advantage of the UC process, the rubrene triplet sensitization by perovskite thin films is demonstrated based on methylammonium (MA), formamidinium (FA) lead triiodide (MAₓFA₁₋ₓPbI₃, MAFA) of varying thicknesses and compositions. The deposited rubrene layer is doped with 1% dibenzotetraphenylperifianthene (DBP) in a commonly used host-guest/annihilator-emitter approach to increase the quantum yield (QY) of the rubrene film, although higher dopant concentrations can be used in some aspects. This addition is required because rubrene is not only capable of TTA but also the reverse process of singlet fission (SF). Förster resonance energy transfer (FRET) of the singlets generated in rubrene by TTA to the emitter DBP outcompetes SF and thus boosts the QY of the thin film. Rubrene was chosen as the annihilator due to the band alignment known to allow for hole extraction (Cong, S., et al., ACS Appl. Mater. Interfaces 9, 2295-2300, 2017; Qin, P., et al., J. Mater. Chem. A. 7, 1824-1834, 2019; Wei, D., et al., Adv. Mater. 30, 1707583, 2018). Hence, injection of free electrons and holes into the upconverting organic semiconductor provides a new avenue for sensitization of rubrene, and allows us to move away from the necessity of efficient singlet-to-triplet exciton converters (Nienhaus, L., et al., ACS Energy Lett., 4, 888-895. 2019).

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting. The skilled artisan will recognize many variants and adaptations of the embodiments described herein. These variants and adaptations are intended to be included in the teachings of this disclosure.

All publications and patents cited in this specification are cited to disclose and describe the methods and/or materials in connection with which the publications are cited. All such publications and patents are herein incorporated by reference as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is not also expressly repeated in the instant specification should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

Although any methods and materials similar or equivalent to those described herein can also be used in the practice or testing of the present disclosure, the preferred methods and materials are now described. Functions or constructions well-known in the art may not be described in detail for brevity and/or clarity. Embodiments of the present disclosure will employ, unless otherwise indicated, techniques of nanotechnology, organic chemistry, material science and engineering and the like, which are within the skill of the art. Such techniques are explained fully in the literature.

It should be noted that ratios, concentrations, amounts, and other numerical data can be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to about 5%” should be interpreted to include not only the explicitly recited values of about 0.1% to about 5%, but also include individual values (e.g., 1%, 2%, 3%, and 4%) and the sub-ranges (e.g., 0.5%, 1.1%, 2.2%, 3.3%, and 4.4%) within the indicated range. Where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y.’ The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y’, and ‘less than z.’ Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z.’ In some embodiments, the term “about” can include traditional rounding according to significant figures of the numerical value. In addition, the phrase “about ‘x’ to ‘y’”, where ‘x’ and ‘y’ are numerical values, includes “about ‘x’ to about ‘y.’”

In some instances, units may be used herein that are non-metric or non-SI units. Such units may be, for instance, in U.S. Customary Measures, e.g., as set forth by the National Institute of Standards and Technology, Department of Commerce, United States of America in publications such as NIST HB 44, NIST HB133, NIST SP 811, NIST SP 1038, NBS Miscellaneous Publication 214, and the like. The units in U.S. Customary Measures are understood to include equivalent dimensions in metric and other units (e.g., a dimension disclosed as “1 inch” is intended to mean an equivalent dimension of “2.5 cm”; a unit disclosed as “1 pcf” is intended to mean an equivalent dimension of 0.157 kN/m³; or a unit disclosed 100° F. is intended to mean an equivalent dimension of 37.8° C.; and the like) as understood by a person of ordinary skill in the art.

### Definitions

Unless defined otherwise, all technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

The articles “a” and “an,” as used herein, mean one or more when applied to any feature in embodiments of the present invention described in the specification and claims. The use of “a” and “an” does not limit the meaning to a single feature unless such a limit is specifically stated. The article “the” preceding singular or plural nouns or noun phrases denotes a particular specified feature or particular specified features and may have a singular or plural connotation depending upon the context in which it is used.

“Upconversion” is a process in which two or more low-energy photons are converted into one high-energy photon having a shorter wavelength than the wavelength used for excitation. For example, the conversion of infrared light to visible light is an upconversion process. The process of triplet-triplet annihilation (sometimes also referred to as triplet fusion) is a mechanism by which upconversion can be achieved; organic molecules such as, for example, polycyclic aromatic hydrocarbons are capable of this process.

“Perovskite” refers to a crystal structure found in calcium titanium oxide but adopted by numerous other minerals and synthetic materials. An idealized perovskite structure has a cubic phase but non-cubic variants (e.g., orthorhombic, tetragonal) are also known. Perovskites can be structured in layers and/or deposited as thin films. In some aspects, materials having perovskite structures are useful for absorbing low-energy photons during the process of upconversion (i.e., as sensitizers that are directly optically excited).

Upconversion Systems and Methods

In various aspects, methods and systems are provided for upconversion of light in a solid-state optoelectronic device. Applicants have demonstrated in various aspects herein that, using bulk-semiconductor thin films as sensitizers for the triplet state, the systems and methods can achieve efficient upconversion based on triplet-triplet annihilation. By varying the film thickness, the threshold of efficient upconversion is shifted to subsolar incident powers enabling practical applications for solar energy harvesting. In some aspects, the methods include exposing a bulk semiconductor to a first light source having light of a first wavelength, wherein the bulk semiconductor is associated with an organic material capable of upconversion via triplet-triplet annihilation from triplet states in the organic material; and observing light emitted from the organic material at a second wavelength, wherein the second wavelength is shorter than the first wavelength. Systems are also provided for the upconversion of light in a solid-state optoelectronic device, e.g. including a bulk semiconductor layer capable of absorbing the first wavelength of light, and an organic material in contact with the bulk semiconductor, wherein the organic material is capable of upconversion via triplet-triplet annihilation from triplet states in the organic material to produce light at a second wavelength.

Exposing the bulk semiconductor to the first light source can create free charge carriers by promoting electrons from a valence band of the bulk semiconductor to a conduction band of the bulk semiconductor, and the triplet states of the organic material can be efficiently populated by charge transfer from the free charge carriers in the bulk semiconductor. The upconversion is particularly useful for upconversion from a low-energy light source, e.g. in some aspects the first wavelength is from about 400 nm to about 2200 nm, about 400 nm to about 1800 nm, about 400 nm to about 1600 nm, about 500 nm to about 1600 nm, about 600 nm to about 1600 nm, or about 800 nm to about 1600 nm. In some aspects, the first wavelength is at least about 10% greater than the second wavelength, at least about 50% greater than the second wavelength, or at least about 100% greater than the second wavelength. In some aspects, the first wavelength and the second wavelength are related by the formula 1/λ₂≈2*1/λ₁, where λ₁ and λ₂ are the first wavelength and the second wavelength respectively.

A variety of organic materials and bulk semiconductors can be employed in the systems and methods for upconversion as long as the relative energy levels are appropriately chosen. Further, in many aspects the bulk semiconductor has a bandgap greater than a lowest triplet energy of the organic material. In some aspects, the bulk semiconductor has an absorption coefficient at the first wavelength of about 10² cm⁻¹, about 10³ cm⁻¹, about 0.5·10⁴ cm⁻¹, about 10⁴ cm⁻¹, or greater. In some aspects the bulk semiconductor has a bandgap of about 0.5 eV to about 3.0 eV, about 0.5 eV to about 2.5 eV, about 0.8 eV to about 2.5 eV, or about 0.8 eV to about 2.0 eV.

Any suitable bulk semiconductor can in principal be used in the upconversion systems and methods described herein. In particular aspects, the bulk semiconductor is a material which forms free charges upon irradiation in form of a film, a two-dimensional material or stack thereof, or a bulk semiconductor wafer. The bulk semiconductor can be available in wafer form. The bulk semiconductor can be made by a process selected from the group consisting of spin coating, vacuum deposition, e.g. by thermal evaporation or atomic layer deposition of a film of the semiconductor onto a substrate or onto the organic material, or a combination thereof. Such processes are well described in the literature. In some aspects, the bulk semiconductor is a film having a thickness of about 10 nm to about 1000 nm, or of about 10, 50, 100, 150, 200, 250, 300, 350, 400, 450, 500, 550, 600, 650, 700, 750, 800, 850, 900, 950, or about 1000 nm; is a two-dimensional material or stack thereof; or is a bulk semiconductor wafer. The bulk semiconductor can include various materials such as an organic or inorganic metal halide perovskite, a cadmium telluride, an indium phosphide, a transition metal dichalcogenide (e.g. a molybdenum disulfide or a tungsten disulfide), or a combination thereof. In one aspect, the metal halide perovskite can be a lead triiodide perovskite. In some aspects, the metal halide perovskite can be a methylammonium formamidinium lead triiodide (MAFA) perovskite. In one aspect, the methylammonium and formamidinium components of the perovskite can be present at a ratio of from about 5:95 to about 95:5 methylammonium to formamidinium, or of about 5:95, 10:90, 15:85, 20:80, 25:75, 30:70, 35:65, 40:60, 45:55, 50:50, 55:45, 60:40, 65:35, 70:30, 75:25, 80:20, 85:15, 90:10, or about 95:5 methylammonium to formamidinium, or a combination of any of the foregoing values, or a range encompassing any of the foregoing values. In an alternative aspect, the perovskite can include methylammonium and be substantially formamidinium free, and in another aspect, the perovskite can include formamidinium and be substantially methylammonium free. In one aspect, for upconversion to occur, the ratio of methylammonium to formamidinium can be altered to adjust the energy levels of the system for upconversion.

Suitable organic materials can principally include any organic material used in organic optoelectronic devices and subject to the requirements described herein. In some aspects, the organic material is a solid and/or a film. In some aspects, the organic material comprises an oligoacene, a heteroacene, a perylene, a phthalocyanine, an oligothiophene, a furane, an anthracene, a rubrene, a pentacene, or a derivative thereof.

The organic material can include a host (annihilator) material and a guest (emitter) material. For example, the organic material can include (i) an oligoacene, a heteroacene, a perylene, a phthalocyanine, an oligothiophene, a furane, an anthracene, a rubrene, a pentacene, or derivatives thereof, and (ii) about 15%, 10%, 5%, 3%, or 1% by weight or less of an emitter material based upon a total weight of the organic material. Suitable emitter materials can include any materials capable of Förster resonance energy transfer (FRET) of the singlets generated in the host to the emitter such that it outcompetes singlet fission and thus boosts quantum yield of the organic material. Suitable emitter materials can include an oligoacene, a heteroacene, a perylene, a phthalocyanine, an oligothiophene, a furane, an anthracene, a rubrene, a pentacene, or derivatives thereof. In some aspects, the emitter material comprises dibenzotetraphenylperifianthene. In one aspect, the organic material comprises a rubrene and about 1% by weight of dibenzotetraphenylperifianthene.

One-Step Synthesis of Upconversion Devices

Existing perovskite-based upconversion systems are fabricated using a two-step process. In this process, in one aspect, a bulk semiconductor solution is spin coated in a two-step program. In one aspect, in the first step, the bulk semiconductor solution is spin coated on a clean substrate in a two-step program at about 1000 rpm for about 10 sec and at about 5000 rpm for about additional 30 s forming a first layer. In some aspects, variations on these speeds and times are contemplated. In some aspects, an antisolvent can be used during the second stage spin coating process. In a further aspect, the antisolvent can be selected from toluene, chlorobenzene, another aromatic solvent, or a combination thereof. In any of these aspects, the bulk semiconductor solution can include PbI₂, methylammonium iodide (MAI), and formamidinium iodide (FAI), and/or other components, depending on the desired film composition. In one aspect, the PbI₂ can be dissolved in a solvent such as, for example, DMF:DMSO. In one aspect, the DMF and DMSO are present in a 9:1 (v:v) ratio. In another aspect, the PbI₂ has a concentration of about 1.2 M in the solvent. In still another aspect, the PbI₂ can be present in an overstoichiometric ratio with respect to MAI and FAI of about 1.09:1. In one aspect, the bulk semiconductor solution concentration can be related to the thickness of the resultant film. Thus, for example, a 0.6 M bulk semiconductor solution can result in a film with a 100 nm thickness. In any of these aspects, following deposition of the films by spin coating, the films can be annealed. In one aspect, the films are annealed at about 100° C. for about 10 minutes. In another aspect, the films can be annealed under oxygen-free conditions such as, for example, in a glove box or other environment containing an inert gas, or in a vacuum chamber.

In one aspect, following annealing, the organic material can be deposited. In a further aspect, the organic material can include rubrene, dibenzotetraphenylperifianthene, or another compounds as disclosed herein. In one aspect, spin coating can be for about 20 s at about 6000 rpm. In a still further aspect, a solution of the organic material can be prepared and added to the antisolvent used in the second spin-coating step for the bulk semiconductor film. In another aspect, following deposition of the organic material, the film can optionally be annealed for a second time, In some aspects, the second annealing is conducted at about 100° C. for about 10 minutes. In another aspect, the film can be annealed for the second time under oxygen-free conditions. In one aspect, following deposition of the organic material and optional second annealing step, the film can optionally be sealed.

Upconversion systems fabricated using the two-step process may exhibit rapid photobleaching of the UC emission upon initial illumination. It has been demonstrated that, in some aspects, band bending at the rubrene-perovskite interface results in charge separation in the absence of light, which in turn enables a high UC rate upon initial illumination. Furthermore, in existing systems fabricated using the two-stage process, two rates of TTA are found: rapid TTA close to the rubrene-perovskite interface and a slower TTA far from the rubrene-perovskite interface. In one aspect, these two rates of TTA are associated with two different UC efficiencies, wherein efficiencies are defined as the fraction of absorbed photons that are converted into high energy photons, due to a varying fraction of back transfer of the singlet states created by TTA in rubrene to the perovskite sensitizer. Furthermore, additional effects observed in such systems may be artifacts of the synthesis process. In one aspect, interactions between the rubrene and the perovskite film result in a surface passivation effect caused by the additional solution-cast rubrene layer, reducing the negative effects of surface trap states. Additionally, the second solution processing step dissolves some of the underlying perovskite film, despite spin-coating from toluene. Thus, in these aspects, the two-step fabrication technique may deteriorate the underlying perovskite sensitizer properties; a new fabrication procedure including an annealing step as described further herein in the Examples can, in many aspects, address these issues.

In one aspect, disclosed herein is a one-step or in situ fabrication process for generating UC devices. Further in this aspect, a first bulk semiconductor solution can be spin coated on a clean substrate at about 1000 rpm for about 10 sec and at about 5000 rpm for about 30 sec. Further in this aspect, the organic material can be dissolved in an antisolvent. In a further aspect, the first bulk semiconductor solution is substantially the same as the bulk semiconductor solution used for the two-step process described herein. In one aspect, the organic material is dissolved in an antisolvent such as, for example, toluene, chlorobenzene, another aromatic solvent, or a combination thereof. Further in this aspect, following spin coating, the films can then be annealed. In one aspect, the films can be annealed at about 100° C. for about 10 min. In another aspect, annealing can occur under oxygen-free conditions as described for the two-step/bilayer fabrication process. In further aspect, following annealing, the films can be sealed using a 2-part epoxy. In one aspect, the films can be sealed under nitrogen gas.

In one aspect, the bulk semiconductor is selected from an organic or inorganic metal halide perovskite, a cadmium telluride, an indium phosphide, an indium gallium arsenide, a cadmium indium gallium selenide, a transition metal dichalcogenide, or a combination thereof. In another aspect, the metal halide perovskite can be lead triiodide perovskite. In still another aspect, the transition metal dichalcogenide can be molybdenum disulfide or tungsten disulfide.

In any of these aspects, the organic material can be selected from an oligoacene, a heteroacene, a perylene, a phthalocyanine, an oligothiophene, a furane, an anthracene, a rubrene, a pentacene, or a derivative thereof. In one aspect, the second bulk semiconductor solution can include about 5% by weight or less of an emitter material based on the total weight of the organic material. In some aspects, the emitter material can be dibenzotetraphenylperifianthene (DBP). In one aspect, the organic material can be rubrene and about 1% by weight DBP.

In one aspect, the disclosed one-step fabrication technique enables intercalation of the upconverting layer (i.e., the organic material) into the perovskite film prior to annealing, resulting in a larger interface and, consequently, more efficient charge extraction.

Also disclosed herein are UC devices fabricated by the one-step fabrication method described above. In one aspect, the bulk semiconductor in the devices has a bandgap of 0.5 eV to about 3.0 eV, about 0.5 eV to about 2.5 eV, about 0.8 eV to about 2.5 eV, or about 0.8 eV to about 2.0 eV. The upconversion is particularly useful for upconversion from a low-energy light source, e.g. in some aspects the first wavelength is from about 400 nm to about 2200 nm, about 400 nm to about 1800 nm, about 400 nm to about 1600 nm, about 500 nm to about 1600 nm, about 600 nm to about 1600 nm, or about 800 nm to about 1600 nm. In some aspects, the first wavelength is at least about 10% greater than the second wavelength, at least about 50% greater than the second wavelength, or at least about 100% greater than the second wavelength. In some aspects, the first wavelength and the second wavelength are related by the formula 1/λ₂≈2*1/λ₁, where λ₁ and λ₂ are the first wavelength and the second wavelength respectively. In another aspect, the bulk semiconductor can have a bandgap greater than the lowest triplet energy of the organic material. In some aspects, the bulk semiconductor can have an absorption coefficient at the first wavelength of about 10² cm⁻¹, about 10³ cm⁻¹, about 0.5.104 cm⁻¹, about 104 cm⁻¹, or greater. In one aspect, aspect, the organic material can have a lowest triplet state energy approximately equal to or less than the bandgap of the bulk semiconductor

### ASPECTS

The present disclosure can be described in accordance with the following numbered Aspects, which should not be confused with the claims.

Aspect 1. A method for upconversion of light in a solid-state optoelectronic device, the method comprising:

exposing a bulk semiconductor to a first light source comprising light of a first wavelength, wherein the bulk semiconductor is associated with an organic material capable of upconversion via triplet-triplet annihilation from triplet states in the organic material; and

observing light emitted from the organic material at a second wavelength, wherein the second wavelength is shorter than the first wavelength.

Aspect 2. The method according to aspect 1, wherein exposing the bulk semiconductor to the first light source creates free charge carriers by promoting electrons from a valence band of the bulk semiconductor to a conduction band of the bulk semiconductor.

Aspect 3. The method according to aspect 2, wherein the triplet states of the organic material are populated by charge transfer from the free charge carriers in the bulk semiconductor.

Aspect 4. The method according to any one of aspects 1-3, wherein the first wavelength is between about 400 nm and about 1600 nm.

Aspect 5. The method according to any one of aspects 1-4, wherein the organic material is a solid.

Aspect 6. The method according to any one of aspects 1-5, wherein the bulk semiconductor is a material that forms free charges upon irradiation in form of a film, a two-dimensional material or stack thereof, or a bulk semiconductor wafer.

Aspect 7. The method according to any one of aspects 1-6, wherein the bulk semiconductor is available in wafer form;

or wherein the bulk semiconductor is made by a process selected from the group consisting of spin coating, vacuum deposition, and a combination thereof.

Aspect 8. The method according to aspect 7, wherein vacuum deposition comprises thermal evaporation or atomic layer deposition of a thin film of the semiconductor onto a substrate or the organic material.

Aspect 9. The method according to any one of aspects 1-8, wherein the bulk semiconductor is a film having a thickness of about 10 nm to about 1000 nm, is a two-dimensional material or stack thereof, or is a bulk semiconductor wafer.

Aspect 10. The method according to any one of aspects 1-9, wherein the bulk semiconductor comprises an organic or inorganic metal halide perovskite, a cadmium telluride, an indium phosphide, an indium gallium arsenide, a cadmium indium gallium selenide, a transition metal dichalcogenide, or a combination thereof.

Aspect 11. The method according to aspect 10, wherein the organic or inorganic metal halide perovskite comprises a lead triiodide perovskite.

Aspect 12. The method according to aspect 10 or aspect 11, wherein the organic metal halide perovskite comprises a methylammonium-based metal halide perovskite, a formamidinium-based metal halide perovskite, or a combination thereof.

Aspect 13. The method according to aspect 10, wherein the transition metal dichalcogenide comprises molybdenum disulfide or tungsten disulfide.

Aspect 14. The method according to any one of aspects 1-13, wherein the bulk semiconductor comprises a bandgap of from about 0.8 eV to about 2.5 eV.

Aspect 15. The method according to any one of aspects 1-14, wherein the first wavelength is from about 10% to about 100% greater than the second wavelength.

Aspect 16. The method according to any one of aspects 1-14, wherein the first wavelength is about 50% greater than the second wavelength.

Aspect 17. The method according to any one of aspects 1-16, wherein the first wavelength and the second wavelength are related by the formula 1/λ₂≈2×1/λ₁, where λ₁ and λ₂ are the first wavelength and the second wavelength, respectively.

Aspect 18. The method according to any one of aspects 1-17, wherein the bulk semiconductor has a bandgap greater than a lowest triplet energy of the organic material.

Aspect 19. The method according to any one of aspects 1-18, wherein the bulk semiconductor has an absorption coefficient at the first wavelength of from about 10² cm⁻¹ to about 104 cm⁻¹.

Aspect 20. The method according to any one of aspects 1-18, wherein the bulk semiconductor has an absorption coefficient at the first wavelength of greater than about 104 cm⁻¹.

Aspect 21. The method according to any one of aspect 1-20, wherein the organic material is a film.

Aspect 22. The method according to any one of aspects 1-21, wherein the organic material has a lowest triplet state energy that is approximately equal to or less than a bandgap of the bulk semiconductor.

Aspect 23. The method according to any one of aspects 1-22, wherein the organic material comprises an oligoacene, a heteroacene, a perylene, a phthalocyanine, an oligothiophene, a furane, an anthracene, a rubrene, a pentacene, or a derivative thereof.

Aspect 24. The method according to any one of aspects 1-23, wherein the organic material comprises a host (annihilator) material and a guest (emitter) material.

Aspect 25. The method according to any one of aspects 1-24, wherein the organic material comprises

(i) an oligoacene, a heteroacene, a perylene, a phthalocyanine, an oligothiophene, a furane, an anthracene, a rubrene, a pentacene, or a derivative thereof, and
(ii) about 5% by weight or less of an emitter material based upon a total weight of the organic material.

Aspect 26. The method according to aspect 25, wherein the emitter material comprises dibenzotetraphenylperifianthene.

Aspect 27. The method according to any one of aspects 24-26, wherein the organic material comprises a rubrene and about 1% by weight of dibenzotetraphenylperifianthene.

Aspect 28. A system for upconversion of light in a solid-state optoelectronic device, the system comprising a bulk semiconductor layer capable of absorbing a first wavelength of light and an organic material in contact with the bulk semiconductor, wherein the organic material is capable of upconversion via triplet-triplet annihilation from triplet states in the organic material to produce light at a second wavelength.

Aspect 29. The system according to aspect 28, wherein exposing the bulk semiconductor to light at the first wavelength creates free charge carriers by promoting electrons from a valence band of the bulk semiconductor to a conduction band of the bulk semiconductor.

Aspect 30. The system according to aspect 29, wherein the triplet states of the organic material are capable of being populated by charge transfer from the free charge carriers in the bulk semiconductor.

Aspect 31. The system according to any one of aspects 28-30, wherein the first wavelength is between about 400 nm and about 1600 nm.

Aspect 32. The system according to any one of aspects 28-31, wherein the organic material is a solid.

Aspect 33. The system according to any one of aspects 28-32, wherein the bulk semiconductor is a film.

Aspect 34. The system according to any one of aspects 28-33, wherein the bulk semiconductor is available in wafer form or made by a process comprising spin coating, vacuum deposition, or a combination thereof.

Aspect 35. The system according to aspect 34, wherein vacuum deposition comprises thermal evaporation or atomic layer deposition of a thin film of the semiconductor onto a substrate or the organic material.

Aspect 36. The system according to any one of aspects 28-35, wherein the bulk semiconductor is a film having a thickness of from about 10-1000 nm, a two-dimensional material or stack thereof, or a bulk semiconductor wafer.

Aspect 37. The system according to any one of aspects 28-36, wherein the bulk semiconductor comprises an organic or inorganic metal halide perovskite, a cadmium telluride, an indium phosphide, an indium gallium arsenide, a cadmium indium gallium selenide, a transition metal dichalcogenide, or a combination thereof.

Aspect 38. The system according to aspect 37, wherein the organic or inorganic metal halide perovskite comprises a lead triiodide perovskite.

Aspect 39. The system according to aspect 37 or aspect 38, wherein the organic metal halide perovskite comprises a methylammonium-based metal halide perovskite, a formamidinium-based metal halide perovskite, or a combination thereof.

Aspect 40. The system of aspect 37, wherein the transition metal dichalcogenide comprises molybdenum disulfide or tungsten disulfide.

Aspect 41. The system according to any one of aspects 28-40, wherein the bulk semiconductor comprises a bandgap of from about 0.8 eV to about 2.5 eV.

Aspect 42. The system according to any one of aspects 28-41, wherein the first wavelength is from about 10% to about 100% greater than the second wavelength.

Aspect 43. The system according to any one of aspects 28-42, wherein the first wavelength is about 50% greater than the second wavelength.

Aspect 44. The system according to any one of aspects 28-43, wherein the first wavelength and the second wavelength are related by the formula 1/λ₂≈2×1/λ₁, where λ₁ and λ₂ are the first wavelength and the second wavelength, respectively.

Aspect 45. The system according to any one of aspects 28-44, wherein the bulk semiconductor has a bandgap greater than a lowest triplet energy of the organic material.

Aspect 46. The system according to any one of aspects 28-45, wherein the bulk semiconductor has an absorption coefficient at the first wavelength of from about 10² cm⁻¹ to about 104 cm⁻¹.

Aspect 47. The system according to any one of aspects 28-46, wherein the bulk semiconductor has an absorption coefficient at the first wavelength of greater than about 10⁴ cm⁻¹.

Aspect 48. The system according to any one of aspects 28-47, wherein the organic material is a film.

Aspect 49. The system according to any one of aspects 28-48, wherein the organic material has a lowest triplet state energy that is approximately equal to or less than a bandgap of the bulk semiconductor.

Aspect 50. The system according to any one of aspects 28-49, wherein the organic material comprises an oligoacene, a heteroacene, a perylene, a phthalocyanine, an oligothiophene, a furane, an anthracene, a rubrene, a pentacene, or a derivative thereof.

Aspect 51. The system according to any one of aspects 28-50, wherein the organic material comprises a host (annihilator) material and a guest (emitter) material.

Aspect 52. The system according to any one of aspects 28-51, wherein the organic material comprises

(i) an oligoacene, a heteroacene, a perylene, a phthalocyanine, an oligothiophene, a furane, an anthracene, a rubrene, a pentacene, or a derivative thereof, and
(ii) about 5% by weight or less of an emitter material based upon a total weight of the organic material.

Aspect 53. The system according to any one of aspects 28-52, wherein the emitter material comprises dibenzotetraphenylperifianthene.

Aspect 54. The system of aspect 28-53, wherein the organic material comprises a rubrene and about 1% by weight of dibenzotetraphenylperifianthene.

Aspect 55. A method for making a device for the upconversion of light, the method comprising:

(i) optionally spin-coating a base layer of a first bulk semiconductor solution on a substrate and annealing the base layer;
(ii) spin-coating a top layer of a second bulk semiconductor solution on the base layer, wherein the second bulk semiconductor solution further comprises an organic material;
(iii) annealing the top layer to form a film comprising a bulk semiconductor and an organic material; and
(iv) sealing the film in an oxygen-free environment;
wherein the bulk semiconductor is capable of absorbing a first wavelength of light and wherein the organic material is capable of upconversion via triplet-triplet annihilation from triplet states in the organic material to produce light at a second wavelength.

Aspect 56. The method according to aspect 55, wherein step (i) is conducted at about 1000 rpm for about 10 s and 5000 rpm for 30 s.

Aspect 57. The method according to any one of aspects 55-56, wherein step (iii) is conducted at about 6000 rpm for about 20 s.

Aspect 58. The method according to any one of aspects 55-57, wherein the organic material comprises an oligoacene, a heteroacene, a perylene, a phthalocyanine, an oligothiophene, a furane, an anthracene, a rubrene, a pentacene, or a derivative thereof.

Aspect 59. The method according to any one of aspects 55-58, wherein the second bulk semiconductor solution further comprises about 5% by weight or less of an emitter material based upon a total weight of the organic material.

Aspect 60. The method according to aspect 59, wherein the emitter material comprises dibenzotetraphenylperifianthene.

Aspect 61. The method according to any one of aspects 55-60, wherein the organic material comprises rubrene and about 1% by weight of dibenzotetraphenylperifianthene.

Aspect 62. The method according to any one of aspects 55-61, wherein the first bulk semiconductor solution, the second bulk semiconductor solution, or both, further comprise an antisolvent.

Aspect 63. The method according to aspect 62, wherein the antisolvent comprises chlorobenzene.

Aspect 64. The method according to any one of aspects 62-63, wherein the second bulk semiconductor solution comprises from about 1 to about 10 mg/mL of the organic material in the antisolvent.

Aspect 65. The method according to any one of aspects 55-64, wherein annealing is conducted at about 100° C. for about 10 min.

Aspect 66. The method according to any one of aspects 55-65, wherein annealing is conducted under oxygen-free conditions.

Aspect 67. The method according to any one of aspects 55-66, wherein the bulk semiconductor comprises an organic or inorganic metal halide perovskite, a cadmium telluride, an indium phosphide, an indium gallium arsenide, a cadmium indium gallium selenide, a transition metal dichalcogenide, or a combination thereof.

Aspect 68. The method according to aspect 67, wherein the organic or inorganic metal halide perovskite comprises lead triiodide perovskite.

Aspect 69. The method according to aspect 67 or aspect 68, wherein the organic metal halide perovskite comprises a methylammonium-based metal halide perovskite, a formamidinium-based metal halide perovskite, or a combination thereof.

Aspect 70. The method according to aspect 67, wherein the transition metal dichalcogenide comprises molybdenum disulfide or tungsten disulfide.

Aspect 71. The method according to any one of aspects 55-70, wherein the film is sealed using a 2-part epoxy.

Aspect 72. The method according to any one of aspects 55-71, wherein the film is sealed under nitrogen.

Aspect 73. A device synthesized according to the method of any one of aspects 55-72.

Aspect 74. The device according to aspect 73, wherein the bulk semiconductor comprises a bandgap of from about 0.8 eV to about 2.5 eV.

Aspect 75. The device according to any one of aspects 73-74, wherein the first wavelength is from about 10% to about 100% greater than the second wavelength.

Aspect 76. The device according to any one of aspects 73-74, wherein the first wavelength is about 50% greater than the second wavelength.

Aspect 77. The device according to any one of aspects 73-76, wherein the first wavelength and the second wavelength are related by the formula 1/λ₂≈2×1/λ₁, where λ₁ and λ₂ are the first wavelength and the second wavelength, respectively.

Aspect 78. The device according to any one of aspects 73-77, wherein the bulk semiconductor has a bandgap greater than a lowest triplet energy of the organic material.

Aspect 79. The device according to any one of aspects 73-78, wherein the bulk semiconductor has an absorption coefficient at the first wavelength of from about 10² cm⁻¹ to about 104 cm⁻¹.

Aspect 80. The device according to any one of aspects 73-79, wherein the bulk semiconductor has an absorption coefficient at the first wavelength of greater than about 104 cm⁻¹.

Aspect 81. The device according to any one of aspects 73-80, wherein the organic material has a lowest triplet state energy that is approximately equal to or less than a bandgap of the bulk semiconductor.

### EXAMPLES

Now having described the embodiments of the present disclosure, in general, the following Examples describe some additional embodiments of the present disclosure. While embodiments of the present disclosure are described in connection with the following examples and the corresponding text and figures, there is no intent to limit embodiments of the present disclosure to this description. On the contrary, the intent is to cover all alternatives, modifications, and equivalents included within the spirit and scope of embodiments of the present disclosure.

### Example 1: Triplet Sensitization by Lead Halide Perovskite Thin Films for Efficient Solid-State Photon Upconversion at Sub-Solar Fluxes

This example demonstrates the rubrene triplet sensitization by perovskite thin films based on methylammonium formamidinium lead triiodide (MAFA) of varying thicknesses. The power-law dependence of both the MAFA photoluminescence (PL) intensity and upconverted emission is tracked as a function of the incident power density. Bimolecular triplet-triplet annihilation (TTA) exhibits a unique power-law dependence with a slope change from quadratic-to-linear at the threshold Iₜₕ. The underlying MAFA PL power-law dependence dictates the power-law of the upconverted PL: i) below Iₜₕ, the slope is twice the value of the MAFA PL, ii) above Iₜₕ, the upconverted PL follows the same power-law as the underlying recombination of mobile electrons and holes in the MAFA films. It is demonstrated that Iₜₕ shifts to sub-solar incident powers when increasing the MAFA thickness above 30 nm. For the thickest MAFA film of 380 nm the results demonstrate an upconversion threshold of Iₜₕ=7.1 mW/cm².

### EXPERIMENTAL PROCEDURES

Device Fabrication.

Glass substrates were cleaned with acetone and then placed in a UV ozone plasma cleaner (Ossila) for 10 min. The perovskite films were prepared using PbI₂ (1.2 M, 99.99% Sigma Aldrich) and MAI (1.2 M, Dyenamo), in a 1:1 molar ratio, and PbI₂ (1.2 M, 99.99% Sigma Aldrich) and FAI (1.2 M, Dyenamo), in a 1:1 molar ratio, both dissolved in anhydrous DMF:DMSO 9:1 (v:v, Acros). The perovskite precursor solutions were then diluted to 0.6, 0.24, and 0.12 M by adding DMF:DMSO 9:1 (v:v) to fabricate the different film thicknesses. The following two-step program was used to spin-coat the perovskite; first at 1000 rpm for 10 s and then at 4000 rpm for 30 s. During the second spin coating step, 100 μL of anhydrous chlorobenzene (Sigma Aldrich) were dropped on the substrate 20 seconds before the end of the program. The substrates were then annealed at 100° C. for 10 min under nitrogen atmosphere.

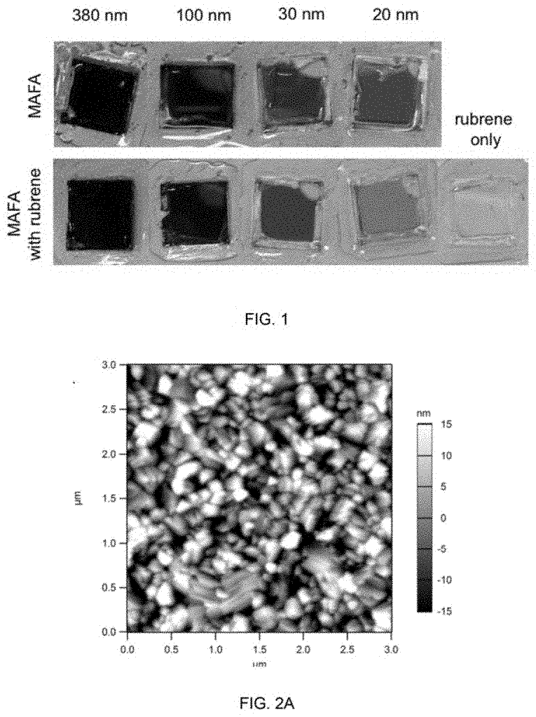

Rubrene (99.99%) and DBP (98% HPLC) were purchased from Sigma Aldrich and used without further purification. The rubrene/DBP solution was prepared in anhydrous toluene (Sigma Aldrich) at 10 mg/mL under nitrogen atmosphere. The rubrene solution was doped with DBP at a 1% molar ratio from a 1 mg/mL stock solution. The solution was deposited by spin coating on the perovskite layers at 6000 rpm for 20 seconds under nitrogen atmosphere. In order to avoid contact with oxygen and moisture with the device, the upconversion devices were sealed using a 2-part epoxy inside the glovebox. A photograph of the fabricated devices is depicted in FIG. 1.

Morphology Characterization.

Cross-sectional scanning electron microscopy (SEM) images were measured with a low vacuum Schottky field emission SEM (FEG-SEM, FEI Nova 400 NanoSEM) at a voltage of 2 kV. AFM images were taken using an Asylum MFP-3D ambient AFM in tapping mode, with a silicon cantilever (300 kHz, spring constant: 26 N/m). AFM images of the 380 nm MAFA films with and without rubrene are depicted in FIG. 2.

Steady-State Optical Spectroscopy.

Absorption spectra were measured using a UV-Vis spectrometer (Shimadzu UV-2450). Steady-state PL was measured using an OceanOptics spectrometer (HR2000+ES) with an excitation wavelength of 405 nm and 780 nm for the UC PL.

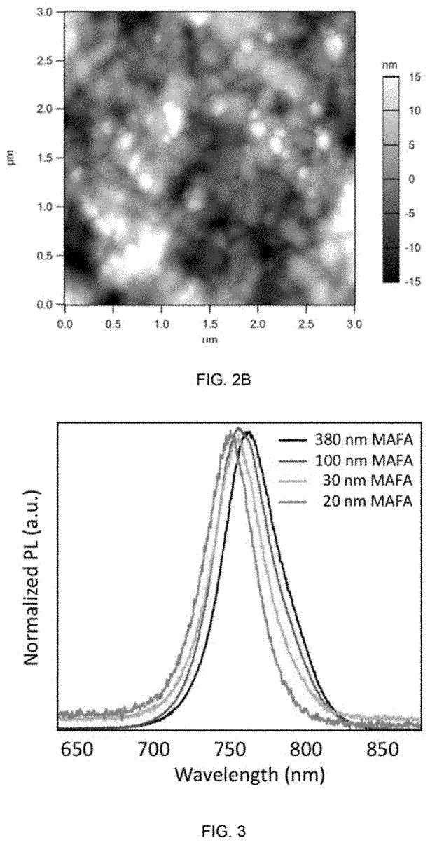

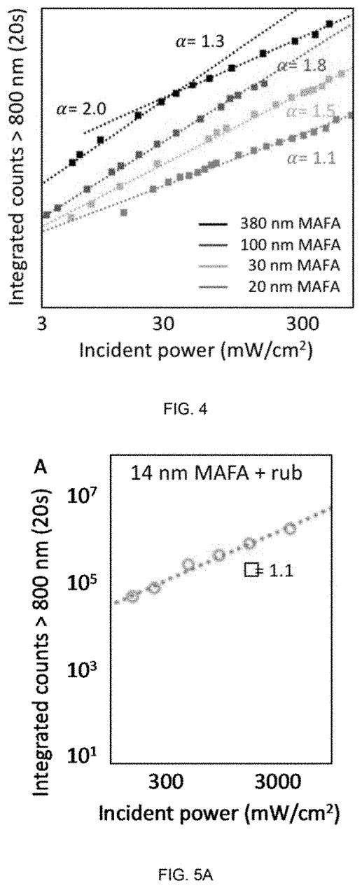

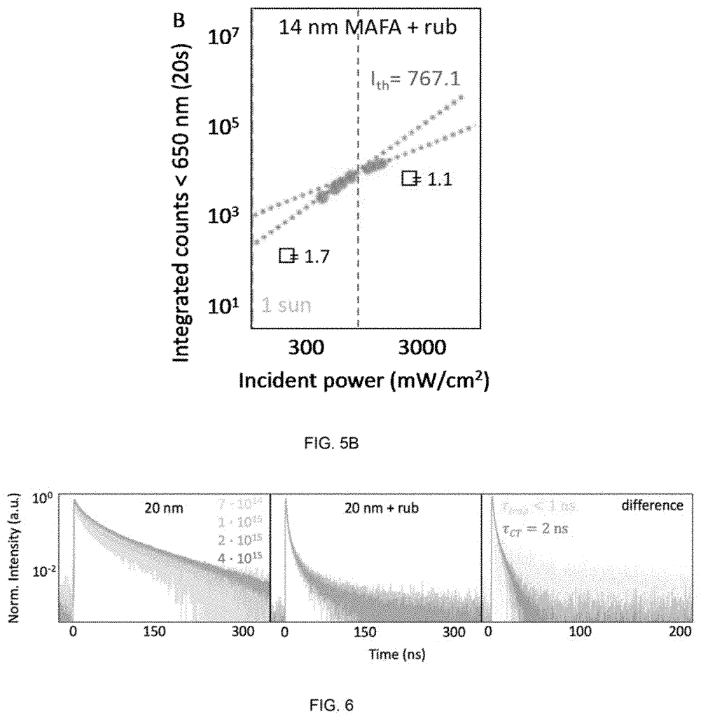

The steady state PL of the MAFA films (FIG. 3), log-log plot of the MAFA film PL (FIG. 4), log-log plot of the MAFA PL and UC PL of the 14 nm MAFA+rubrene bilayer device (FIGS. 5A-5B),

Time-Resolved Photoluminescence Spectroscopy.

Time-resolved photoluminescent (TRPL) lifetimes were obtained by time-correlated single photon counting (TCSPC). All samples were excited by a picosecond pulsed diode laser (PicoQuant LDH-D-C-780) connected to a PicoQuant Laser Driver (PDL 800-D). Excitation powers were measured using a silicon power meter (ThorLabs PM100-D). Lifetimes of the upconverted emission were obtained by removing MAFA PL and excess laser scatter by 650 nm and 700 nm shortpass filters (ThorLabs). To monitor the perovskite emission, PL decay dynamics were obtained at various excitation power densities at a repetition rate of 2.5 MHz. Laser scatter was removed with an 800 nm longpass filter (ThorLabs). For the power dependent PL intensities, a 780 nm laser was used in CW-mode for a 20 s histogram time. In all cases, the resulting emission was focused onto a single photon counting avalanche photodiode (Micro Photon Devices). A HydraHarp 400 (PicoQuant) was used to record the photon arrival times. The laser spot size was determined by the razor blade method, yielding a spot size of 125 μm based on the 1/e² distance.

To extract the characteristic time of charge transfer, a scaled copy of the MAFA PL decay dynamics were subtracted from the MAFA+rubrene decay dynamics. Due to highly multiexponential decays likely resulting from a distribution of transfer rates, the time it takes for the population to decay to 1/e is reported as the characteristic time of charge transfer.

To account for slightly different absorption of the MAFA films and the MAFA+rubrene bilayer devices, the optical absorption of the incident laser was measured directly at the sample location. A power meter (ThorLabs) was used to measure the incident laser power, as well as the transmitted and reflected laser powers.

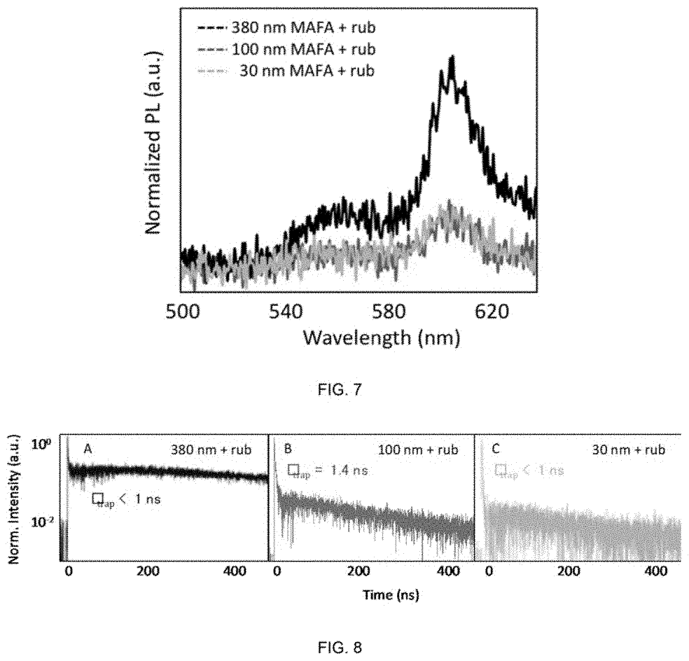

TRPL for the 20 nm MAFA+rubrene bilayer devices (FIG. 6 steady-state UC PL spectra (FIG. 7).

Back Transfer Model.

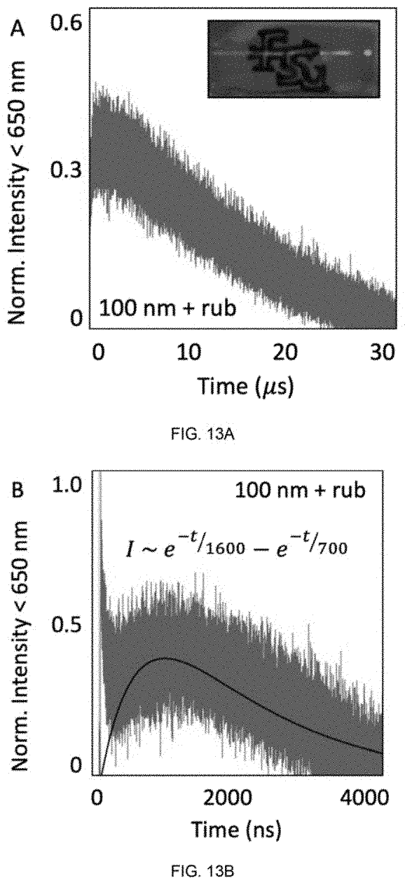

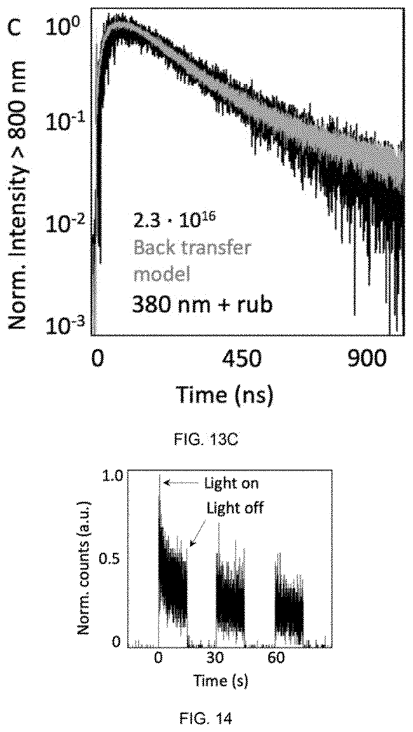

The exciton back transfer was approximated by multiplying the measured MAFA PL dynamics with the fit of the UC PL dynamics. To account for the inherent trap filling occurring, the extracted trap filling lifetime (FIG. 8) was added to the resulting convoluted lifetime, yielding the modeled extraction lifetimes in FIG. 13C.

Results and Discussion

Thickness-Dependent Morphology and Absorption.

As demonstrated herein, the excitonic sensitizer is replaced with a bulk perovskite thin film capable of creating long-lived free carriers upon irradiation, effectively using a PV to create highly mobile free charges which can electronically stimulate rubrene. A major benefit of this approach is the possibility of a higher absorption of the NIR excitation, potentially boosting the UC quantum yield (QY) beyond the limitations of current excitonic UC devices and thus, enabling sub-solar applications. Since free carrier lifetimes can be highly dependent on the trap state density, MA_{0.85}FA_{0.15}PbI₃ (MAFA) perovskite thin films with different thicknesses were fabricated by varying the molar precursor concentration

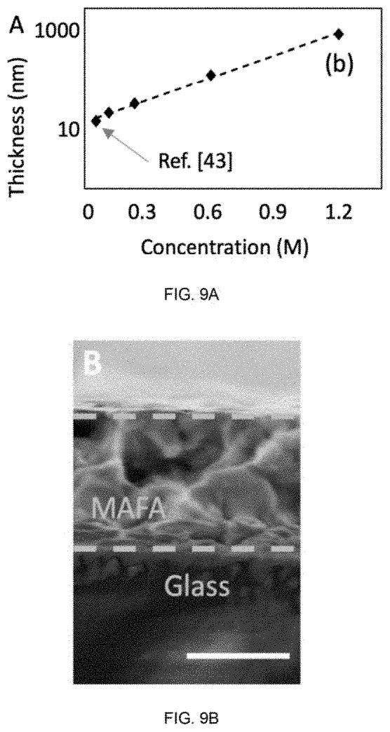

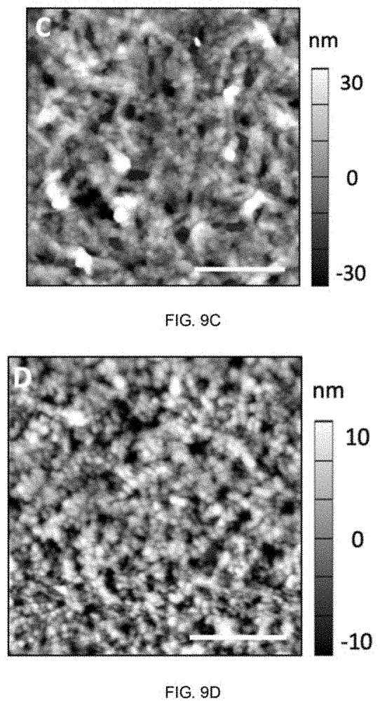

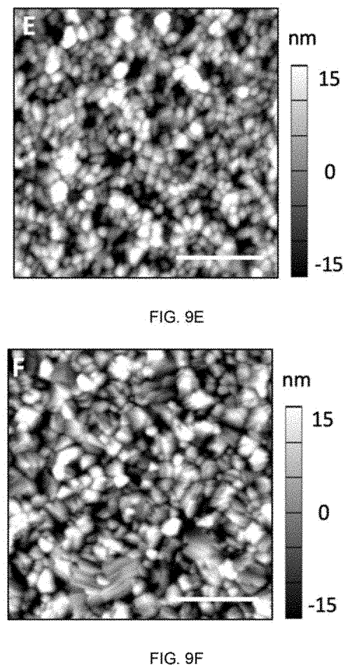

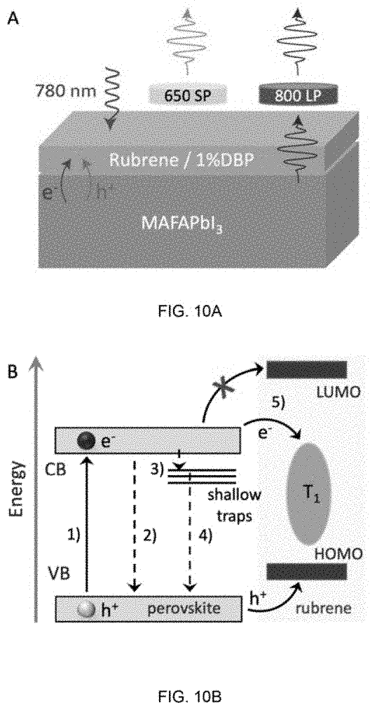

Film thicknesses of 20, 30, 100, and 380 nm are obtained for the 0.12, 0.24, 0.6, and 1.2 M molar precursor concentrations (see FIG. 9A), respectively. FIG. 9B shows the cross-sectional SEM image of the 1.2 M thick MAFA film where a film thickness of 380 nm can be approximated. A 0.06 M MAFA precursor concentration yields a film thickness of approx. 14 nm. Hence, the film thicknesses of the other samples can be estimated based on their precursor concentrations as shown in the graph in FIG. 9A. The thickness approximations agree well with reported literature values. To investigate the surface morphology of the different MAFA film thicknesses, atomic force microscopy (AFM) images of the surfaces were obtained. FIGS. 9C-9F detail the film morphologies obtained for the 20, 30, 100, and 380 nm thick MAFA films, respectively. A clear change in the morphology is observed based on the different thicknesses. The 20 and 30 nm MAFA films (FIGS. 9C-9D) show a very rough surface with large agglomerates. By further increasing the film thickness to 100 nm (FIG. 9E), the MAFA film shows distinct, yet discontinuous grains. Further increasing the thickness, yields a smooth, thin film structure for the 380 nm MAFA film (FIG. 9F).

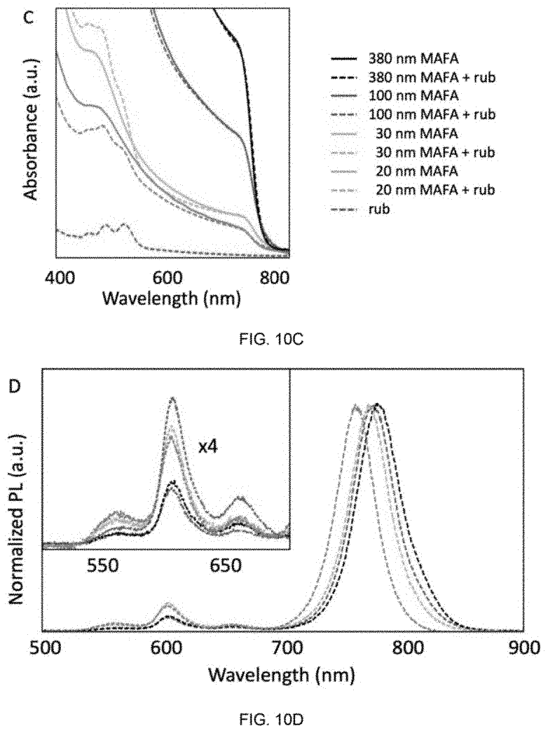

To investigate the UC behavior, bilayer devices were fabricated composed of the MAFA film (different film thicknesses) and rubrene/1% DBP. In the following rubrene/1% DBP will be referred to as “rubrene” (or “rub”) for simplicity through-out this application. FIG. 28 shows an AFM image of the 380 nm MAFA film with rubrene, which shows the amorphous rubrene layer conforming to the polycrystalline nature of the underlying perovskite film. FIG. 10A shows the investigated UC device structure. See also FIG. 1 for photographs of the fabricated devices. Due to the favorable band alignment of rubrene and the MAFA perovskite thin films, holes can easily be injected into the upconverting rubrene film by the underlying MAFA film (valence band (VB) of MAFA ˜5.8 eV, highest occupied molecular orbital (HOMO) of rubrene ˜5.4 eV). FIG. 10B details a schematic of the underlying charge extraction to rubrene. The large energy mismatch on the order of ˜1 eV between the MAFA perovskite conduction band (CB) and the lowest unoccupied molecular orbital (LUMO) creates a barrier for the direct injection of electrons into the singlet excited state of rubrene. However, the bound triplet state T₁ can be directly populated by electron transfer. For charge extraction to the rubrene triplet state to occur efficiently, the charge transfer must either outcompete the inherent trap-filling process or a sufficient charge carrier density must be created in the MAFA films to saturate the surface traps. For the case of a low incident fluence, there will be a distribution, i.e. a probability density function of the carriers trapped vs. transferred to rubrene based on the respective rates.

FIG. 10C shows the film thickness-dependent absorbance spectra of the MAFA films as solid lines. As expected, the observed optical density increases with the MAFA film thickness, and all films show broadband absorption with an absorption onset at ˜800 nm, in line with the expected optical bandgap of 1.55 eV for this perovskite composition. To investigate the influence of rubrene, bilayer devices were fabricated composed of MAFA and rubrene/1% DBP. The corresponding absorbance spectra are shown in FIG. 10C as dashed lines for all MAFA thicknesses. The overall MAFA absorption slightly varies in the presence of rubrene, which indicates the solution-based rubrene deposition may slightly affect the underlying MAFA film. The characteristic absorption features of the spin-cast rubrene on top of the MAFA films can be clearly seen in the range 430-530 nm confirming the non-oxidized species of rubrene. Oxidized rubrene is known to have a blue-shifted absorption compared to the non-oxidized species. FIG. 10D shows the steady-state photoluminescence (PL) of the MAFA+rubrene bilayer devices for all four film thicknesses. The emission of MAFA peaks between 760 and 780 nm and is slightly red-shifted with increasing film thickness (also compare FIG. 3 for the PL spectra of the MAFA only films). This effect has been observed previously and can be explained by a differential incorporation of the MA⁺/FA⁺ cations as a function of the precursor concentration. The visible emission from the rubrene layer is observed at 605 nm (emission wavelength of DBP). This is the result of FRET from rubrene to the emitter dye DBP (see the inset in FIG. 10D).

Power-Dependence Under CW Excitation.

PL spectroscopy was used to study the change in recombination behavior in the perovskite upon increasing the MAFA film thickness. First, the power dependency of the NIR MAFA PL intensity was investigated under continuous wave (CW) excitation at 780 nm (compare the schematic in FIG. 10A, 800 nm LP, NIR MAFA PL). In the MAFA films presented here, the PL originates from radiative recombination of mobile electrons and holes. A power-law dependence of the PL intensity I_{MAFA} on the incident photon flux F is expected for a bulk MAFA film (380 nm): I_{MAFA}˜F^{α}, and two regimes should be observed: i) a quadratic dependence on F at low fluences resulting in the slope of α=2 which is typical for non-geminate bimolecular recombination (carrier densities below n₀˜10¹⁷), and ii) a slope reduction at higher fluences due to a photoluminescence quantum yield (PLQY) decrease due to non-radiative Auger recombination, as well as a PL saturation resulting from band filling. As the film thickness is reduced below 100 nm, the relative role of surface recombination (i.e. surface trapping) increases, which competes with the bulk trapping of carriers. As a result, the inherent slope of the power-law dependence of the PL intensity on F is expected to shift to lower values. FIG. 4 shows the power-law dependencies of the NIR MAFA PL of the 380, 100, 30, and 20 nm thick films on a log-log scale. A change in the slope was observed from α=1.1 for the thinnest 20 nm film to a slope α=2 for the thickest 380 nm film.

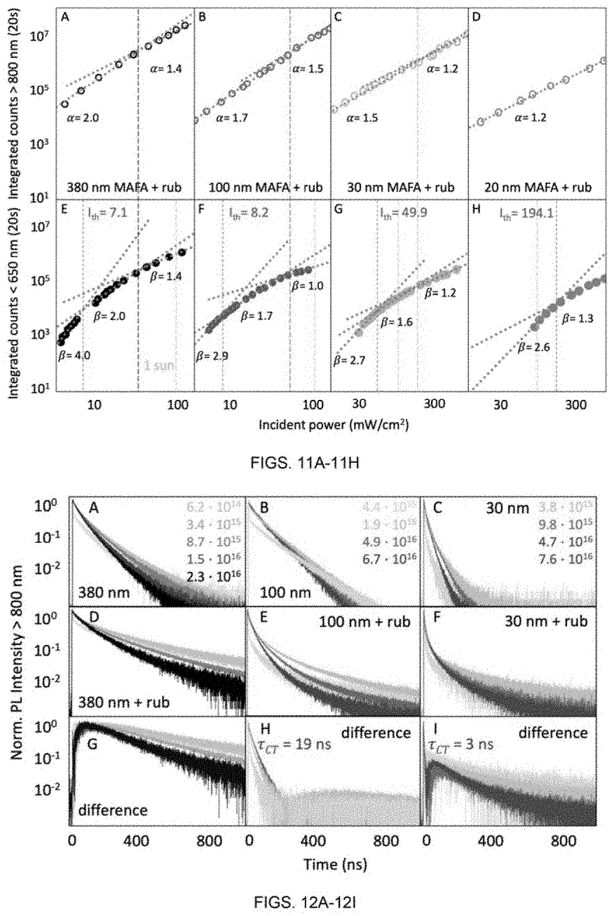

It was previously reported that the addition of rubrene passivates shallow traps at the perovskite surface due to non-covalent cation-n interactions between the MA⁺ cations and the extended delocalized x-system in rubrene. The chelation-like interaction is able to immobilize the otherwise mobile organic cations in the perovskite. This results in a reduction of defect sites during device fabrication, as well as a passivation effect on existing defect sites such as dangling bonds, thus increasing the overall device performance. To confirm this effect, the power dependencies of the NIR PL of the MAFA+rubrene bilayer UC devices were investigated. Indeed, the results demonstrate higher slopes compared to the MAFA only films. FIGS. 11A-11D show the power-law dependencies of the 380, 100, 30 and 20 nm thick MAFA+rubrene devices. The addition of rubrene increases the slope to α=1.2 for the 20 nm MAFA+rubrene device. For the 30 nm MAFA+rubrene device a slope change of α=1.5 to α=1.2 can be seen at higher incident fluxes, further confirming a reduction in surface recombination in the bilayer device due to passivation. The slopes of the thick MAFA+rubrene films (380 nm, 100 nm) are only marginally impacted by the addition of rubrene at low incident photon fluxes, highlighting their inherent bulk free-carrier recombination-dominated behavior. For comparison with previous work (Nienhaus, L., et al., ACS Energy Left., 4, 888-895, 2019), the power-law dependence of the MAFA PL of a 14 nm thick MAFA+rubrene device under CW excitation is shown in FIG. 5A.

In a second step, the UC process was investigated for all four bilayer devices. The blue-shifted emission resulting from the UC process is measured under 780 nm excitation under various incident power densities (compare schematic in FIG. 10A, 650 nm SP, UC PL). The obtained UC emission herein relies on three steps: i) charge transfer to the rubrene triplet state, ii) diffusion-mediated TTA in rubrene, and iii) FRET from the rubrene singlet state to DBP resulting in emission. Hence, if TTA-UC is occurring, emission is expected at a wavelength of λ≈605 nm.

The intensity of bimolecular TTA exhibits a unique power-law dependency on the incident photon flux F, with a slope change from 2 at low excitation powers to 1 above the threshold (Iₜₕ) at which TTA becomes efficient: I_{UC PL}˜F²< for F<Iₜₕ and I_{UC PL}˜F for F>Iₜₕ. This is due to a change in the underlying kinetics of the TTA process: at low excitation powers, triplets decay via quasi first-order kinetics and the UC PL intensity increases quadratically with excitation power (weak annihilation regime). Above the Iₜₕ value, triplets decay primarily through bimolecular TTA, yielding a linear dependence of the UC PL based on the incident power (strong annihilation regime).

However, as the triplet sensitization is thought to occur via independent charge transfer of mobile carriers from MAFA to rubrene, the underlying power-law slope α of the MAFA PL will influence the power-law slope of the UC PL. As described previously, the MAFA PL shows a thickness-dependent power-law dependence of the MAFA PL intensity on the fluence: I_{MAFA}˜F^{α}. As a result, in the weak annihilation regime (below Iₜₕ), where a slope of 2 is expected for the UC process, the results demonstrate the following relationship for the UC PL: I_{UC PL}˜F^{β}=(I_{MAFA})²=F^{2α}.

In the strong annihilation regime (above Iₜₕ), the slope of TTA becomes 1. Hence, the extracted slope of the UC PL is expected to simply follow the slope of the MAFA PL: I_{UCPL}˜F^{β}=F^{α}.

FIGS. 11E-11H show the power dependency of the UC process for the bilayer devices with different MAFA thicknesses. All devices exhibit the power-dependent PL slope changes expected of TTA, indicating that the detected visible UC PL indeed stems from triplet sensitization of the rubrene layer followed by TTA. Furthermore, the results demonstrate that above the Iₜₕ value, the slope of the UC PL simply follows the power-law dependence of the MAFA PL. This observation highlights the underlying mechanism of independent transfer of electrons and holes to the rubrene triplet state. The Il value shifts to lower incident powers with increasing MAFA thickness, which is in line with the mechanism proposed herein: charge transfer to the triplet state competes with non-radiative trap filling. Sub-solar Iₜₕ values of 7.1, 8.2, 49.9 mW/cm² can be extracted for the 380, 100 and 30 nm thick MAFA+rubrene devices, respectively. The 20 nm thick MAFA+rubrene device exhibits an Iₜₕ value just below 2 suns at Iₜₕ=194.1 mW/cm² (compare also FIG. 5B for a 14 nm thick MAFA+rubrene device with an extracted value of Iₜₕ=767.1 mW/cm² under 780 nm CW excitation). A clearly visible shift of the Iₜₕ value to lower powers is observed as the MAFA film thickness is increased, highlighting the importance of the underlying thickness-dependent recombination dynamics governed by the role of surface recombination vs. bulk trapping in the charge transfer process to rubrene.

Time-Resolved PL Spectroscopy.

Time-resolved PL (TRPL) spectroscopy is able to yield additional insight on the rate of trap filling, as well as give a qualitative view of the availability of trap states at a given excitation fluence. At low excitation fluences, the light intensity is not sufficient to create enough carriers in the material to fill all existing traps. As a result, the lifetimes show two components under these conditions: a fast component attributed to rapid non-radiative quenching into trap states, as well as a longer component which is then assigned to the free carrier recombination and reflects the carrier lifetime.

With increasing incident power intensity, the number of initially empty trap states is reduced, which is reflected in a decreased amplitude of the early time PL quenching component of the lifetime. An increase in free carriers created at higher fluences will manifest as a reduction in the free carrier lifetime, as the likelihood of recombination increases with increasing carrier density. Turning the TRPL of the three film thicknesses which yield sub-solar UC thresholds. FIGS. 12A-12C show the power dependent lifetimes of the 380, 100 and 30 nm MAFA films under varying excitation densities at an excitation wavelength of 780 nm (see FIG. 6 for the 20 nm MAFA film). For each film thickness, the results demonstrate a highly multiexponential slow decay at a low excitation power (or at low carrier densities), while a faster decay is found at high excitation powers. As expected, the overall free carrier lifetime increases with increasing film thickness, which can be attributed to an increased grain size and grain orientation. For facile comparison, similar average excitation intensities were used for all three film thicknesses. Due to the low absorption of the thinner films and the expected higher trap density, it may not be possible to fully saturate the existing trap states with the laser power available at the time and early time quenching was observed resulting from trap filling even at the highest fluences available in the thinner films.

The power dependent MAFA PL lifetimes of the 380, 100 and 30 nm MAFA+rubrene devices are shown in FIGS. 12D-12F (see FIG. 6 for additional data for 20 nm MAFA+rubrene device). The same general trend as in the MAFA only films can be seen, where the amount of early time quenching is reduced at higher incident power and the free carrier lifetime is reduced with increasing carrier density. This indicates that the underlying native trap-filling processes still occur in the presence of rubrene, and that the charge extraction to rubrene at the interface is likely a competing mechanism which becomes efficient at fluences high enough to saturate the trap states.

The subtraction approach developed by Wu et al. was used (Nat. Photonics 10, 31-34, 2016). for extracting the difference in the lifetimes of the MAFA films and the MAFA+rubrene bilayer devices, seen in FIGS. 12G-12I. This approach is based on the assumption of an active population which is quenched by charge transfer to rubrene, as well as an inactive population which is unaffected by the presence of rubrene. As the inactive population is asserted to be independent of the addition of rubrene, the additional quenching component which corresponds to the characteristic time of charge transfer can be obtained by subtracting a scaled copy of the sensitizer lifetime (i.e. MAFA PL) from the lifetime of the sensitizer in presence of the annihilator (i.e. MAFA+rubrene). By critically reviewing the extraction approach, the results demonstrate that one of the underlying assumptions is that the inherent sensitizer decay dynamics are not affected by the addition of rubrene. However, due to the passivating effect of rubrene, the MAFA+rubrene bilayer device may saturate its trap states at a different excitation fluence than the MAFA device. Charge transfer to rubrene will also reduce the number of carriers available at a given fluence.

Hence, this extraction approach must be met with some degree of skepticism. In this particular case, the fluence-dependent changes in the extracted difference in the lifetimes (FIGS. 12G-12I) show that the required assumptions do not always hold in the case of the MAFA+rubrene devices. Rather, the extraction yields a superposition of quenching resulting from non-radiative trap filling (compare FIG. 8), charge transfer to rubrene, and a delayed rising and falling component, which can be attributed to back transfer (or reabsorption) of singlets created by TTA. Charge extraction to rubrene should not show a power dependent change in the transfer rate, unless the energy levels involved in the charge transfer, the wavefunction overlap or the attempt frequency are changing, which is not anticipated. Hence, this is attributed to a change in the ratio of carrier trapping vs. charge transfer to rubrene and the results demonstrate that a meaningful charge transfer rate can only be extracted at high fluences, when traps are saturated upon excitation. Under these conditions, the results demonstrate a characteristic time of transfer of τ_{CT}=19 ns and τ_{CT}=3 ns for the 100 nm and 30 nm MAFA+rubrene devices (FIGS. 12H-12I), respectively (compare also FIG. 6 for the 20 nm device). For the thickest device (380 nm, FIG. 12G), no meaningful rate of charge transfer can be extracted due to parasitic reabsorption overshadowing the quenching dynamics. As the underlying charge transfer mechanism is not expected to change as a function of the MAFA film thickness, it is attributed to the thickness-dependent change of the extracted transfer rate to an increase in the driving force for charge transfer due to the slightly larger bandgap of the thinner films (compare FIG. 10D).

To further elucidate the TRPL dynamics in the MAFA+rubrene system presented here, the TRPL lifetime of the UC PL (<650 nm) stemming from the 100 nm thick MAFA+rubrene device in FIG. 13A. Since triplets are spin-forbidden and therefore only weakly radiatively couple to the ground state, they exhibit very long lifetimes with reported values up to 100 μs. However, the available TRPL system was limited to a minimal repetition rate of 31.25 kHz, or a detectable time frame of ˜33 μs. It has been shown previously, that a too high repetition rate results in an apparent reduction of the triplet lifetime, which leads us to be able to only extract a lower bound of the triplet lifetime of ˜15 μs in the disclosed MAFA+rubrene bilayer devices. The lifetime shows the rise and fall characteristic of the UC process, as the observed visible PL is a result of the delayed triplet population by charge transfer and subsequent diffusion-mediated TTA. The upconverted population peaks after ˜1.5 μs, which highlights the underlying slow diffusion-mediated process. The initial fast decay observed in the first ˜100 ns can be attributed to a small amount of residual MAFA emission not fully removed by the 700 and 650 short-pass filters. The inset of FIG. 13A shows the visible orange emission from DBP of the 100 nm thick MAFA+rubrene device under 780 nm illumination. The steady-state UC PL spectra under 780 nm excitation can be found in FIG. 7. To verify that the cause of the rise and fall of the extracted MAFA PL seen in FIGS. 12G-12H is indeed caused by exciton recycling by exciton back transfer or photon reabsorption, the UC PL was investigated under the same conditions as the MAFA PL lifetimes. FIG. 138 shows the UC PL (<650 nm) for the 100 nm MAFA+rubrene device at a repetition rate of 250 kHz. An increase in the repetition rate results in a build-up of a triplet population that does not decay between pulses, effectively reducing the diffusion time in TTA, as well as the triplet lifetime. The upconverted PL is well fit by two exponentials, with a rise time of τᵣᵢₛₑ=700 ns corresponding to the characteristic time of diffusion-mediated TTA, and a decay τₜᵣᵢₚₗₑₜ=1600 ns, which amounts to the triplet lifetime at this repetition rate.

FIG. 13C shows the extracted difference in the lifetime for the 380 nm bilayer device, shown in FIG. 12G, overlaid with dynamics created by a simple exciton back transfer model. In this model, the UC PL is assumed to follow the dynamics fit in FIG. 13B, and convolve this lifetime the native MAFA PL lifetime, and further add the trap filling dynamics seen in FIG. 8. The results demonstrate that the resulting model fits the observed data very well, highlighting that the extracted difference in the MAFA and MAFA+rubrene PL here is caused by strong exciton back transfer or reabsorption and that the decay dynamics are indeed overshadowed by strong parasitic photon reabsorption.

In conclusion, the results demonstrate the triplet sensitization of rubrene by bulk MAFA films of different thicknesses, indicating that the UC process becomes efficient at sub-solar incident fluxes when increasing the MAFA film thickness beyond 30 nm. This indicates that the longer carrier lifetimes, combined with the higher absorption cross sections and lower trap densities of the thicker MAFA films allow for more efficient charge transfer to rubrene, enabling efficient UC at lower incident power densities.

Inherent non-radiative decay into traps competes with charge transfer to rubrene until the incident power is high enough to fill all existing traps. Based on the passivating effect of rubrene caused by cation-n interactions, care must be taken when attempting to extract an accurate rate for the triplet sensitization process as the underlying PL lifetimes are strongly affected by trap states. Only at high fluences, when existing traps are already filled, can a meaningful rate of charge transfer to the rubrene triplet state be extracted: τ_{CT}≈19 ns and τ_{CT}≈3 ns for the 100 nm and 30 nm devices, respectively. This change in the extracted charge transfer rate is not attributed to a difference in the underlying charge transfer mechanism, but rather results from a varying energetic driving force for charge transfer. The extracted lifetimes show that the UC PL is strongly reabsorbed by the MAFA films, indicating a tradeoff between the Iₜₕ value and the overall UC PL output of the MAFA+rubrene devices. Further investigation of the charge transfer to rubrene by other spectroscopic means, e.g. transient absorption spectroscopy, will be of interest for future studies. Optimization of the charge extraction by tuning the energetic band alignment through dopants in the MAFA film, MAFA defect reduction, and device structure improvements provide a means to further increase the UC device performance to enable solar applications.

### Example 2. Influence of Triplet Diffusion on Lead Halide Perovskite-Sensitized Solid-State Upconversion

By rapidly transferring single charge carriers instead of bound triplet states, perovskites enable a high triplet population in rubrene, yielding low Iₜₕ values. In this example, the results demonstrate the role of the triplet population on the upconverted emission. Interestingly, two independent rates of TTA can be observed, as well as a sharp drop in the visible emission intensity over several seconds. This effect can be attributed to the triplet-density-based diffusion length: i) at low triplet populations slow diffusion-mediated TTA yields singlets far from the interface, ii) higher triplet populations lead to rapid TTA close to the perovskite/rubrene interface. Due to the proximity of the strongly absorbing perovskite, the singlet states created closer to the interface undergo stronger back-transfer to the perovskite film and therefore appear to exhibit a lower photoluminescence quantum yield.

### EXPERIMENTAL METHODS

Device Fabrication.

Glass substrates were first cleaned by sonication in 2% Hellmanex solution, followed by sonication in deionized water, and in ethanol. The substrates were then wiped down with acetone and placed in a UV ozone plasma cleaner (Ossila) for 15 min. The perovskite sensitizer films were prepared by using PbI₂ (1.2 M, 99.99% Sigma Aldrich) and MAI (1.2 M, Dyenamo), in a 1:1 molar ratio, and PbI₂ (1.2 M, 99.99% Sigma Aldrich) and FAI (1.2 M, Dyenamo), in a 1:1 molar ratio, both dissolved in anhydrous DMF:DMSO 9:1 (v:v, Sigma Aldrich). The perovskite precursor solution was then diluted two-fold by adding DMF:DMSO 9:1 (v:v) to obtain the final precursor solution. A two-step program was used to fabricate the perovskite film: 1000 rpm for 10 s and 4000 rpm for 30 s. After the initial 10 s of the second step, 100 μL of anhydrous chlorobenzene (Sigma Aldrich) were added on the substrate. The perovskite films were annealed at 100° C. for 10 min under air-free conditions.

Rubrene (99.99%) and DBP (98% HPLC) were purchased from Sigma Aldrich and used without further purification. A 10 mg/mL rubrene solution was prepared in anhydrous toluene (Sigma Aldrich) and doped with DBP at a 1% ratio. The rubrene layer was deposited by spin coating the stock solution on the previously prepared perovskite layer at 6000 rpm for 20 seconds under nitrogen atmosphere. The upconversion devices were sealed using a 2-part epoxy (Devcon) under nitrogen.

Morphology Characterization.

AFM images were taken using an Asylum MFP-3D ambient AFM in tapping mode, with a silicon cantilever (300 kHz, spring constant: 26 N/m). An AFM image of the perovskite film is shown in FIG. 9E.

Steady-State Optical Spectroscopy.

Absorption spectra were measured on a UV-Vis spectrometer (Shimadzu UV-2450). PL spectra were measured using an OceanOptics spectrometer (HR2000+ES) with a CW excitation wavelength of 405 nm (PicoQuant LDH-D-C-405) and 780 nm (PicoQuant LDH-D-C-780).

Time-Resolved Photoluminescence Spectroscopy.

Time-resolved photoluminescence lifetimes were obtained by time-correlated single photon counting (TCSPC). The samples were excited by a picosecond pulsed diode laser (PicoQuant LDH-D-C-780) at a repetition rate of 31.25 kHz. The incident excitation power was determined by a silicon power meter (ThorLabs PM100-D). To obtain the NIR MAFA PL lifetimes, laser scatter was removed by an 800 longpass filter (ThorLabs). To detect the UC PL dynamics, the NIR MAFA PL and excess laser scatter were removed by a 600 bandpass filter (ThorLabs). In all cases, the resulting emission was focused onto a single photon counting avalanche photodiode (Micro Photon Devices) using reflective optics. A HydraHarp 400 (PicoQuant) was used to record the photon arrival times. The T2 mode of the HydraHarp was applied to investigate the long-term PL intensity over 15 s, and the resulting photon arrival times plotted in a histogram. To modulate the triplet population by modulating the excitation laser, an additional mechanical chopper (ThorLabs) was added to the existing (time-resolved) PL setup. The chopper was set to 20 Hz and a duty cycle of 50%.

Results and Discussion

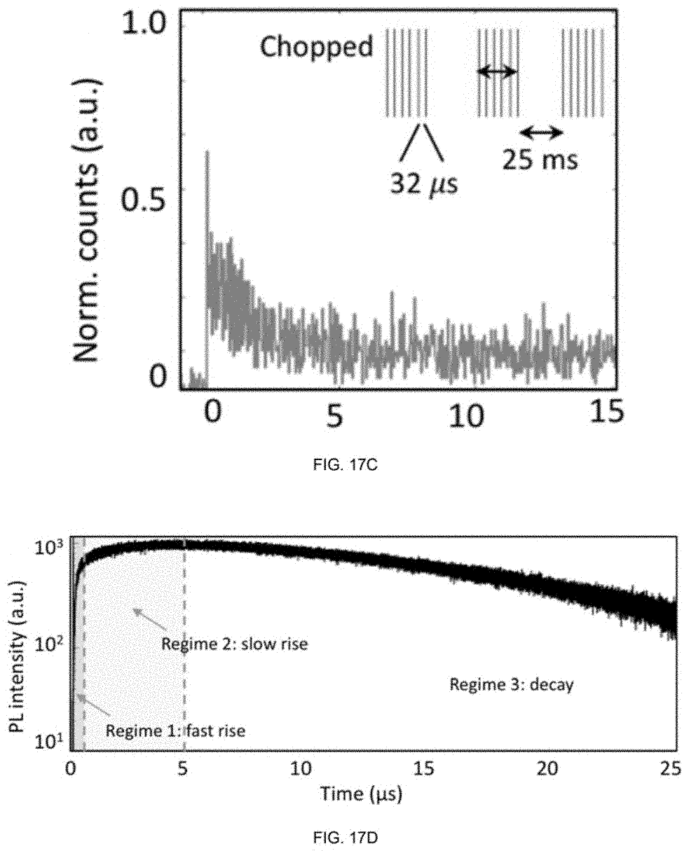

A schematic of the bilayer UC device is shown in FIG. 10A: a 100 nm methylammonium formamidinium lead iodide (MAFA) perovskite thin film is used as the sensitizer; the annihilator layer consists of solution-cast rubrene doped with 1% dibenzotetraphenylperiflanthene (DBP). Rubrene was chosen due to the favorable band alignment with the underlying MAFA film allowing for hole extraction. Under 780 nm excitation, the device emits both: NIR MAFA PL peaking at 780 nm, and UC PL at ˜605 nm. The MAFA film is characterized by atomic force microscopy (FIG. 9E). FIG. 17A highlights the absorbance spectrum (black), the steady-state PL spectrum under 405 nm excitation (blue) and the UC emission spectrum resulting from 780 nm excitation (orange) of the bilayer device. The MAFA absorption onset can be seen at ˜800 nm (optical bandgap of 1.55 eV) whereas the absorption features of rubrene appear at 430-530 nm confirming the non-oxidized species of rubrene.

Two unusual effects can be observed in MAFA+rubrene devices: i) a slow reduction or reversible “photobleach” in the UC PL intensity on a timescale of multiple seconds (FIG. 17B), and ii) two rising components (regimes 1 and 2) in the UC PL dynamics followed by a slow decay (regime 3) (FIG. 17D).

FIG. 17B shows the normalized PL intensity of the MAFA+rubrene UC device under pulsed 780 nm excitation. The results demonstrate a reduction in the UC PLQY over the first ˜5 s after laser illumination, followed by a plateauing of the UC emission intensity. As this effect occurs repeatably, and reappears after several seconds of sample recovery in the dark (FIG. 14), a photobleaching mechanism based on a physical decomposition of the MAFA film or rubrene can be ruled out. It is known that the long-lived rubrene triplets do not fully decay between subsequent laser pulses, which causes a build-up of triplet excitons. It appears surprising that an increase of triplet excitons may result in a decrease of the UC PLQY, as this should increase the rate of diffusion-mediated TTA. To investigate this usual observation, the built-up triplet population was modified by allowing the system to fully relax to the ground state. To achieve this, an additional slow modulation of the incident pulsed laser is introduced by means of a mechanical chopper wheel (20 Hz). The 25 ms “off time” is sufficiently long to allow both the full relaxation of all triplets to the ground state and any trapped carriers to equilibrate within the perovskite film. FIG. 17C shows the normalized PL intensity of the MAFA+rubrene UC device under chopped excitation. Unsurprisingly, due to the duty cycle of 50%, the initial peak PL intensity is roughly halved. However, the results demonstrate that the UC PL plateaus at the same value under chopped and constant pulsed excitation.

It has been reported that both the rate of diffusion-mediated TTA and the triplet lifetime are modulated by the existing triplet population. Hence, the UC dynamics are dependent on both the average excitation power and the repetition rate of the excitation source. However, as UC devices would be used under constant solar illumination, the UC properties under continuous wave (CW) operation are of great interest.

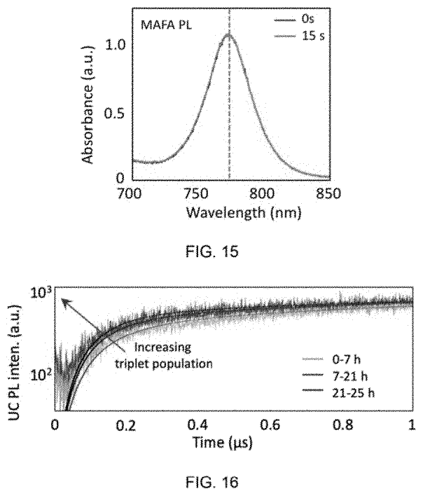

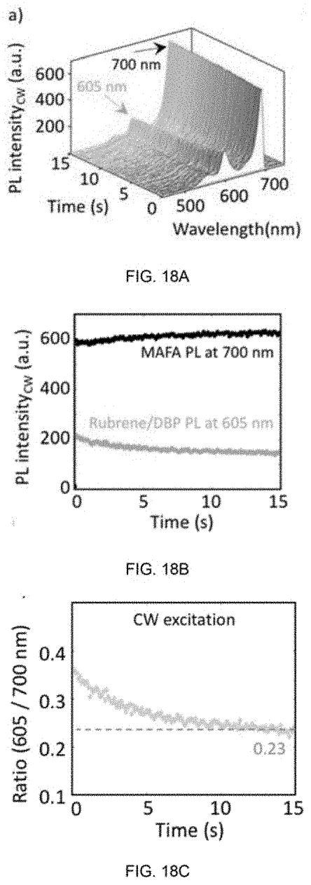

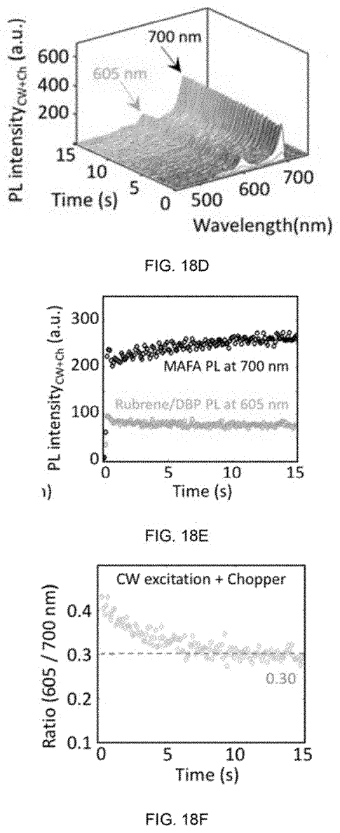

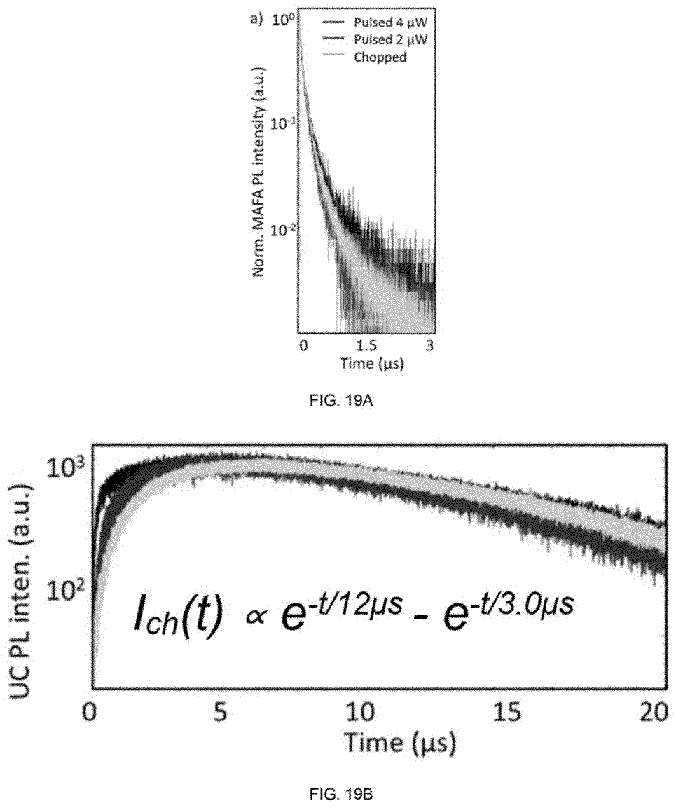

To investigate the effect of CW excitation on the UC PLQY, the PL intensity of the MAFA+rubrene device was recorded under 780 nm CW excitation (FIG. 18A) over 15 s. Since the MAFA PL peaks at the same wavelength as the excitation source, the PL spectrum was only recorded between 450 and 700 nm to avoid artifacts due to laser scatter. To ensure that the PL intensity changes at 700 nm are not simply due to a shift in the emission wavelength, but correctly reflect variations in the peak PL intensity, the time-dependent MAFA PL spectra was also recorded under 405 nm illumination (FIG. 15). FIG. 18B depicts the MAFA PL detected at 700 nm (black circles) and the UC PL at 605 nm (orange circles) over 15 s. Initially, both PL intensities drop. At later times (t>1 s), the results demonstrate an opposite trend in the PL intensities: the MAFA PL increases, while the UC PL decreases. The ratio of the PL intensity at 605 nm vs. 700 nm (FIG. 18C) is related to the UC efficiency (η_{UC}) of the device, defined as the number of absorbed photons which are converted to emissive singlet excitons in the annihilator. η_{UC} is the product of the energy transfer efficiency from sensitizer to annihilator (η_{ET}) and the TTA efficiency of the annihilator (η_{TTA}), where η_{rub} is the PLQY of the rubrene/DBP film.

η_{UC}=η_{ET}·η_{TTA}·η_{rub} eq. 1

An initial ratio reduction of the PL intensity at 605 nm vs. 700 nm followed by a plateau at 0.23 can be seen over 15 s. This indicates a time-dependent change in η_{UC}, and therefore, a change in either η_{ET} or η_{TTA} over time. To investigate the role of the triplet population, the 780 nm CW excitation source was modulated at 20 Hz. FIG. 18D shows the time-dependent evolution of the PL spectrum. In FIG. 18E the intensities at 605 nm (orange) and at 700 nm (black) are plotted, corresponding to the UC and MAFA PL, respectively. The results demonstrate a similar trend in the behavior, an initial dip in the PL intensity of both traces, followed by an anti-correlated increase in the MAFA PL and a decrease in the UC PL. The ratio of the UC PL vs. MAFA PL is plotted in FIG. 18F. A similar trend is observed as in the constant CW excitation: an initial reduction in the ratio, followed by a plateau. Here, the plateau is at a higher value of 0.3, indicating an overall higher UC efficiency of the device under the modulated illumination.

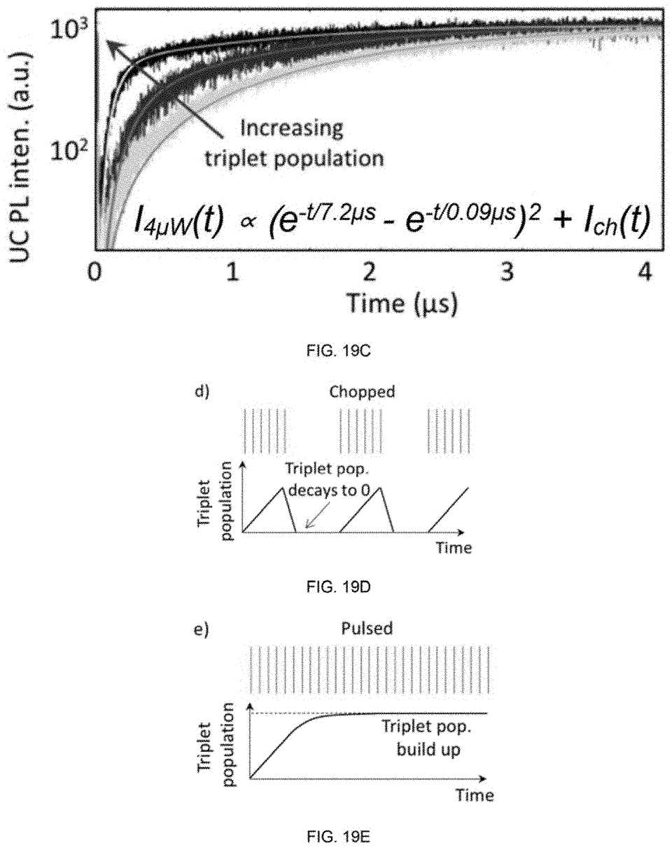

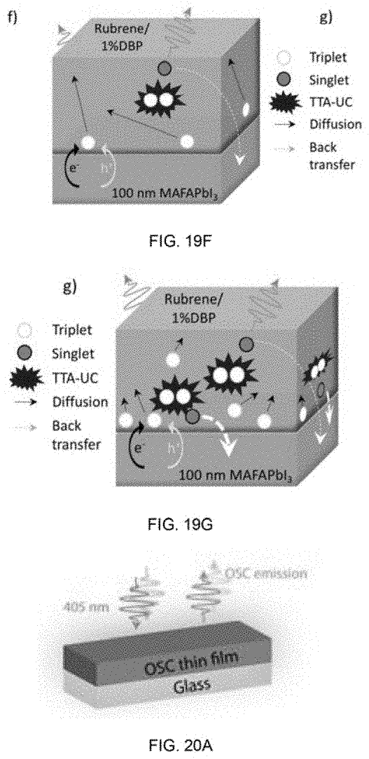

Time-resolved PL spectroscopy (TRPL) was employed to infer the role of energy transfer to the triplet state and the TTA efficiencies on the overall UC efficiency. Changes in the rate or efficiency of energy transfer to the rubrene triplet state will manifest as changes in the quenching dynamics of the sensitizer (MAFA) PL. Changes in η_{TTA} or the TTA process itself will change the UC PL dynamics. The results have established that modulating the triplet population by allowing it to fully relax to the ground state increases the UC PLQY. As a result, the responsible part for the UC PLQY changes can be extracted by comparing the PL dynamics under pulsed and pulsed illumination modulated by the chopper. FIG. 19A shows the MAFA PL decay dynamics under pulsed (black) and chopped illumination (gray) at an incident power of 4 μW. As it is known that perovskites have power-dependent lifetimes and the peak power is not as relevant as the average incident power, the results also show the PL dynamics under pulsed excitation at half the incident power (2 μW, purple). All MAFA PL dynamics show very similar behavior, and therefore the results show that neither the energy transfer efficiency η_{ET} nor the related transfer rate is responsible for the time-dependent change in the UC PLQY.

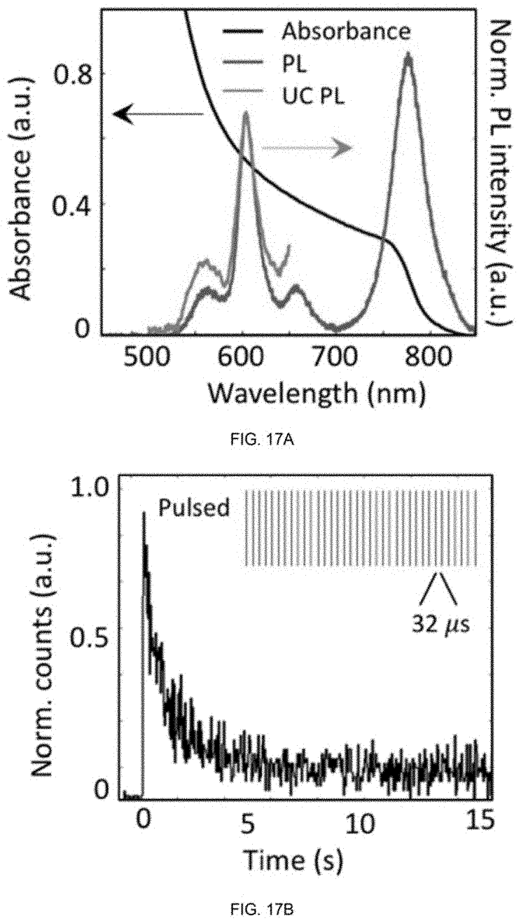

The UC PL dynamics on the other hand (FIG. 19B-19C) paint a very different picture. Again, three cases are highlighted: i) illumination at a pulsed power of 4 μW (black), ii) 2 μW average incident power of the pulsed laser (purple), and iii) modulated pulsed illumination with a duty cycle of 50% (gray) at an incident power of 4 μW (“on time”). In contrast to the MAFA PL (FIG. 18A) which stems from direct optical excitation of the MAFA perovskite, the UC PL emission relies on the creation of triplet excitons, and reflects the population of the triplet state over time. At the time of the first laser pulse, the population of triplets is zero and increases due to triplet sensitization. Hence, the rise time reflects the combined rate of charge transfer from the MAFA perovskite to the triplet state of rubrene, triplet diffusion prior to TTA, Förster resonance energy transfer (FRET) from rubrene to DBP, and the respective emission rate. The slowest of these steps will be rate-limiting and dictate the overall observed rise time. Commonly, this will be the rate of triplet diffusion in solid-state UC devices. The slow decay reflects a lower bound of the long-lived triplet state (τₜᵣᵢₚₗₑₜ>12 μs), limited by the resolution of the available TRPL setup. FIG. 19B shows the long-term dynamics highlighting both the rise of the triplet population and the long-lived decay, while FIG. 19C shows a zoom-in on the early time PL dynamics. Clearly visible is a change in the UC PL dynamics based on the incident excitation: i) at 4 μW two distinguishable rise times can be observed, corresponding to a fast and slow rising component, followed by a slow decay. ii) At 2 μW: two rising regimes are found. However, the initial fast rise is slower and the magnitude of the fast component is less, which indicates a power dependency of the fast-rising regime 1. iii) Under chopped excitation, a small amount of a fast early-time rise can be observed, the main component however, corresponds to the slow rise dictated by triplet diffusion through rubrene. The UC PL dynamics under chopped excitation are well fit by a simple exponential rise τ₂, followed by a monoexponential decay τ₁: I_{ch}(t)∝(e^{-t/τ}^{₁}−e^{-t/τ}^{₂}). Due to the duty cycle of 50% of the chopped excitation, the average incident power is 2 μW. However, during the “on time” the incident power is 4 μW. As there are differences between all three conditions, the results demonstrate that neither the average power, nor the peak power are the underlying cause. Rather, an increase in the rate and magnitude of the fast-rising regime 1 is observed if the triplet population builds up over time (FIG. 16). This is further supported by the faster rise in regime 1 at a higher incident power.

The results demonstrate that the decay traces can be deconvolved into two components, one of which corresponds to the dynamics extracted in the case of the mechanically chopped excitation I_{ch}(t), with an additional component corresponding to a quadratic exponential rise τ₄ and decay τ₃: I_{plused}(t)∝(e^{-t/τ}^{₃}−e^{-t/τ}^{₄})²+I_{ch}(t). Since TTA is a process involving two triplet states, bimolecular recombination dynamics are expected.⁴³ In the case of slow triplet diffusion, this quadratic dependency is often not observed, as the rate-limiting step is the long diffusion time. If diffusion is fast, the rate-limiting step will be triplet sensitization. Here, bimolecular recombination dynamics are expected, and the rise time will amount to an upper bound of the triplet sensitization time. As a result, the two rising regimes in the triplet dynamics are believed to be due to two distinct processes: 1) rapid UC close to the interface, and 2) slow diffusion-mediated TTA.

TABLE 1
UC PL dynamics under pulsed and chopped pulsed excitation.

| | e^{-t/τ}^{₁} − e^{-t/τ}^{₂} | | (e^{-t/τ}^{₃} − e^{-t/τ}^{₄})² | |
|---|---|---|---|---|
| | τ₁ | τ₂ | τ₃ | τ₄ |
| I_{Ch} | 12 μs | 3 μs | — | — |
| I_{4μW} | 12 μs | 3 μs | 7.2 μs | 0.09 μs |
| I_{2μW} | 12 μs | 3 μs | 9.8 μs | 0.21 μs |

The schematics in FIGS. 19D-19E create a link between the hypothesis of rapid TTA-UC close to the interface, slow diffusion-mediated TTA and the change in the UC PLQY. Under modulated illumination (FIG. 19), the triplet population increases until the excitation source is turned off. The triplets will decay with their inherent rate until all triplets have relaxed to the ground state. Steady-state or fast pulsed excitation results in an increase of the triplet population until it becomes saturated (FIG. 19E). In the case of a low triplet population, i.e. all triplets relax to the ground state between pulses, triplets are able to diffuse far from the interface prior to finding a “partner” to undergo TTA (FIG. 19F). As the number of triplets is increased, the time required for two triplets to collide via diffusion is decreased, with the lower limit being no diffusion occurring. Consequently, a fraction of TTA will occur more rapidly and closer to the interface (FIG. 19G). However, as both processes have the same underlying mechanism, it is unexpected to anticipate a difference in η_{TTA}.

Not wishing to be bound by any theory, it is believed that the change in the observed UC PL intensity is not a result of the inherent TTA efficiency, which is being reduced, rather only the observed η_{TTA} is reduced due to parasitic back-transfer of the created emissive singlet states. Back-transfer of singlet excitons has been shown to be detrimental in solid-state UC devices. The schematics in FIGS. 19F-19G highlight the differences in rapid TTA close to the interface and slow-diffusion mediated TTA. The limit of the rapid TTA process is interface-mediated TTA. Emissive singlets created at the interface will rapidly undergo back-transfer by weak far-field reabsorption, but also highly efficient near-field processes such as FRET. Triplet diffusion lengths above a typical FRET radius of ˜10 nm result in singlet excitons which are only able to be weakly far-field reabsorbed, and emission created by this pathway will exhibit a higher observed UC PLQY.

In conclusion, the UC emission properties of MAFA+rubrene bilayer devices have been examined in detail. Modulating the triplet population by means of a mechanical chopper wheel results in an increase in the UC PLQY. A decrease in the UC efficiency is observed in the first ˜5 s after illumination, and two distinct rise times are observed in the UC PL dynamics. TTA close to the interface results in strong parasitic back-transfer of the emissive singlet states created and reduces the observed UC efficiency. This result indicates that there is a tradeoff in the triplet sensitization rate, the triplet diffusion lengths and the achieved UC efficiency, and highlights the importance of the measurement conditions on reported UC efficiencies. Previous reports have shown that the underlying power-dependent recombination kinetics of the perovskite sensitizer also influence the UC emission. As a result, UC PLQYs in perovskite-sensitized UC devices are highly sensitive to both the time after illumination the measurement is taken, and the incident power.

### Example 3: The Role of Dlbenzotetraphenylperiflanthene (DBP) Doping in Rubrene

To date, the direct role of the DBP dopant concentration in the rubrene annihilator layer on the UC efficiency has not been investigated in solution-processed perovskite-sensitized devices. Previous reports have shown a ˜19-fold increase in the upconverted emission intensity upon the addition of 0.5 wt % DBP to the rubrene layer as well as complete quenching of the rubrene emission at the cost of a red-shift of the emission of ˜40 nm or 0.15 eV. Interestingly, in contrast to these previous thermally evaporated bilayer UC devices, the disclosed solution-processed devices with ˜1 wt % DBP doping still often show strong emission at ˜565 nm, the wavelength of emission from the first vibronic feature of rubrene. This indicates that the desired Förster resonance energy transfer (FRET) step from rubrene to the dopant dye DBP is not occurring to completion, allowing for a potential further improvement of the UC efficiency.

### EXPERIMENTAL PROCEDURES

Device Fabrication.

Glass substrates were first cleaned in 2% Hellmanex solution and sonicated for 15 min. Afterwards, the substrates were cleaned in water and ethanol and sonicated for 15 min in the respective solutions. The substrates were then placed in a UV ozone plasma cleaner (Ossila) for 15 min.

MAFA perovskite thin films were prepared as described previously. Briefly, a 1.2 M PbI₂ stock solution was prepared in anhydrous DMF:DMSO 9:1 (v:v, Sigma Aldrich). PbI₂ (1.2 M, 99.99% Sigma Aldrich) and MAI (1.2 M, Dyenamo) were mixed in a 1:1.09 molar ratio, PbI₂ (1.2 M, 99.99% Sigma Aldrich) and FAI (1.2 M, Dyenamo) were mixed in a 1:1.09 molar ratio. To achieve an approx. 100 nm thick MAFA film, the final precursor concentration was diluted two-fold in DMF:DMSO 9:1 (v:v). For perovskite film deposition, a two-step spin-coating program was used: 1000 rpm for 10 s and 4000 rpm for 30 s. Anhydrous chlorobenzene (Sigma Aldrich) were dropped onto the substrate as anti-solvent. Afterwards, the films were annealed at 100° C. for 10 min in the glovebox.

Rubrene (99.99%) and DBP (98% HPLC) were purchased from Sigma Aldrich and used as received. A 10 mg/mL rubrene solution was prepared in anhydrous toluene and doped with DBP (10 mg/mL in anhydrous toluene) at different ratios: 0.5%, 1.4%, 2.2%, 3.3%, 4.4% and 5.5%. The rubrene/DBP solutions were then spin coated onto a bare glass substrate or onto the MAFA perovskite layer at 6000 rpm for 20 s. To prevent rubrene oxidation, the films were sealed with a coverslip using a 2-part epoxy (Devcon) under a nitrogen atmosphere.

Optical Characterization.

Steady-state. A UV-vis spectrometer (Shimadzu UV-2450) was used to measure the absorption of the films and bilayer devices. Steady-state PL was measured with an OceanOptics spectrometer (HR2000+ES) under continuous wave excitation at 405 nm (PicoQuant LDH-D-C-405) and 780 nm (PicoQuant LDH-D-C-780). For comparison with the solid bilayer devices, the absorption and PL of 10 mg/mL rubrene in toluene and 10 mg/mL DBP in toluene were also measured.

Time-resolved. Time-resolved PL lifetimes were measured by means of time-correlated single photon counting (TCSPC) using an single-photon avalanche photodiode (Micro Photon Devices) and a HydraHarp 400 or a MultiHarp 150 (PicoQuant). The photon arrival times were measured by focusing the emission onto the detector using reflective optics. The lifetimes of rubrene/DBP with varying ratios in solution or supported on the bare glass substrate were measured under 405 nm excitation equipped with a 425 nm long-pass filter (Chroma Tech.) to remove excess laser scatter. The MAFA decay dynamics were measured under pulsed 780 nm excitation at a repetition rate of 31.25 kHz (4.1 μW) using a 800 nm long-pass filter (Thorlabs). The upconverted dynamics were measured under 780 nm excitation at a repetition rate of 31.25 kHz (4.1 μW) and an average power using a 600/40 nm (center/width) band-pass filter (Thorlabs). To measure the incident laser beam power, a silicon power meter (Thorlabs PM100-D) was used.

Time-resolved emission spectra. Time resolved emission spectra were collected using a Gemini interferometer (NIREOS). For the OSC thin films, the time resolved emission spectra (TRES) were recorded over 175 steps with a collection time of 5001 ms at each step. For the MAFA/rubDBP devices, the time resolution was set to 128 μs. The TRES were recorded over 250 steps with a collection time of 10001 ms at each step. A 405 nm picosecond pulsed laser diode (PicoQuant LDH-D-C-405) was used as an excitation source at 10 MHz, power density 2.7 W/cm²) for the OSC thin films and at 250 kHz, power density (36 mW/cm²) for the MAFA/rubDBP devices. A 425 nm long pass filter (Chroma Tech.) was used to remove excess laser scatter. Photon arrival times were collected via a HydraHarp 400 (PicoQuant) event timer connected to a silicon single-photon avalanche photodiode (Micro Photon Devices).

Calculations and Supplemental Measurements.

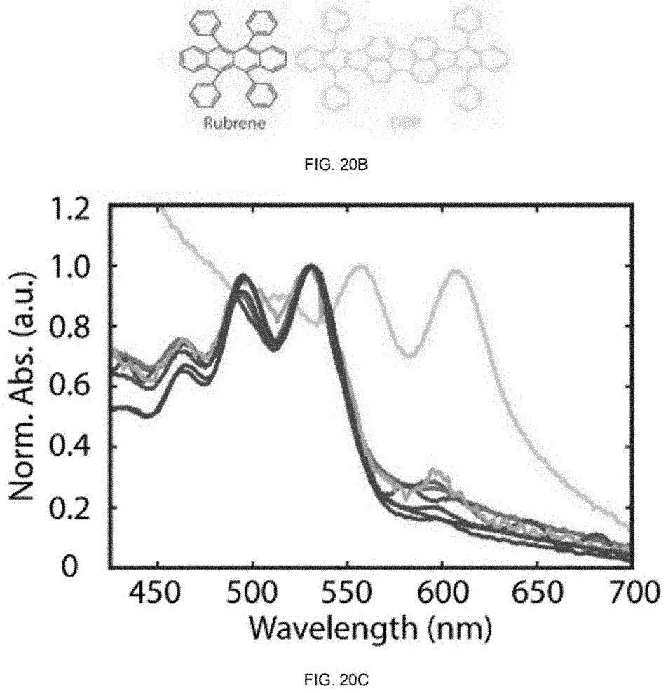

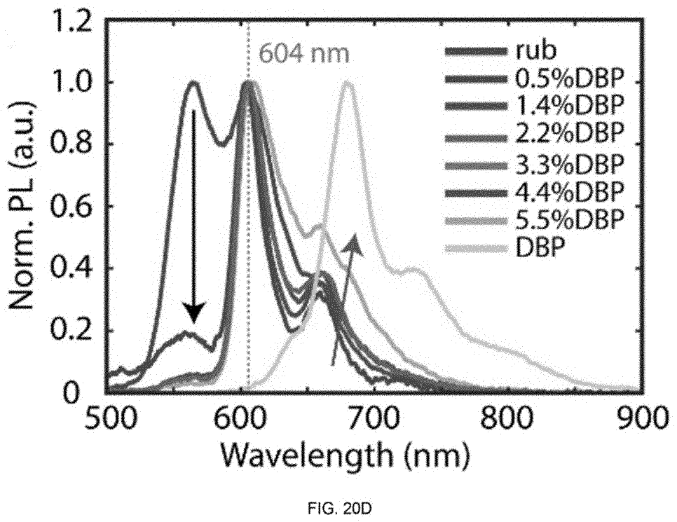

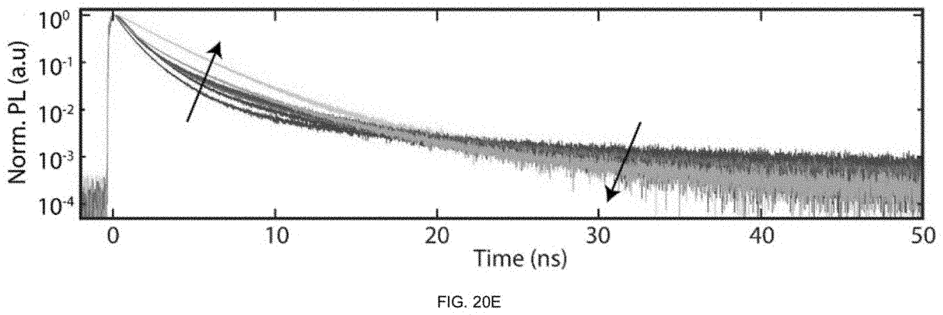

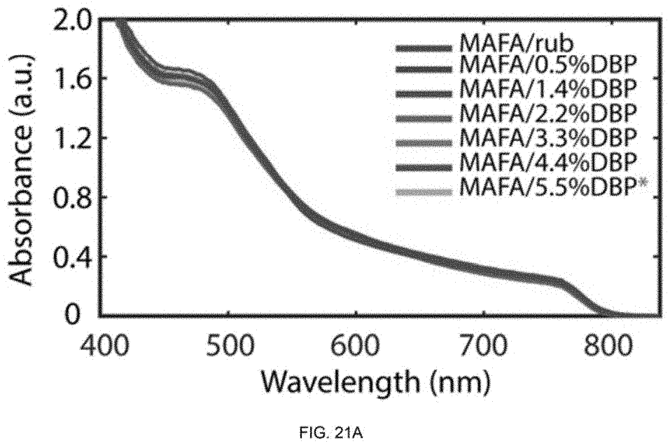

The PL decay lifetimes for the OSC-only films (see FIG. 20E) were fit using a triexponential decay function. Amplitudes (A) and lifetimes (t) were extracted for each exponential component (Table 2). Additionally, the amplitude-weighted average lifetime (τ_{amp av}) was calculated using equation 2:

$${τ}_{amp av} = \frac{{Σ}_{i} {A}_{i} {τ}_{i}}{{Σ}_{i} {A}_{i}} \qquad eq . 2$$

where Aᵢ and τᵢ correspond to the amplitudes and lifetimes extracted from each exponential component, respectively.

TABLE 2
Calculated amplitudes, lifetimes, and amplitude-weighted
average lifetimes for the OSC-only films shown in FIG. 20 E

| Film | | τ₁ | | τ₂ | | τ₃ | τ_{amp av} |
|---|---|---|---|---|---|---|---|
| composition | A₁ | (ns) | A₂ | (ns) | A₃ | (ns) | (ns) |
| Rub only | 0.88 | 0.84 | 0.20 | 2.2 | 0.0063 | 21 | 1.2 |
| DBP only | 1.0 | 2.4 | 0.057 | 4.3 | 0.012 | 12 | 2.6 |
| 0.5% DBP | 1.1 | 1.2 | 0.061 | 4.5 | 0.0029 | 26 | 1.4 |
| 1.4% DBP | 1.1 | 1.1 | 0.11 | 3.9 | 0.0051 | 17 | 1.5 |
| 2.2% DBP | 0.96 | 1.0 | 0.17 | 3.6 | 0.0071 | 15 | 1.5 |
| 3.3% DBP | 1.09 | 1.0 | 0.13 | 3.7 | 0.0050 | 18 | 1.4 |
| 4.4% DBP | 0.96 | 0.93 | 0.20 | 3.1 | 0.0098 | 12 | 1.4 |
| 5.5% DBP | 0.64 | 0.87 | 0.41 | 2.6 | 0.019 | 9 | 1.7 |

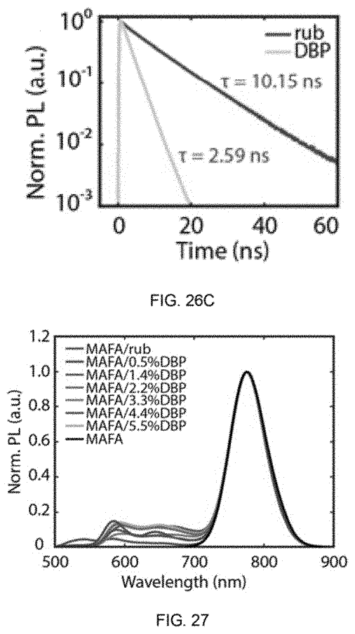

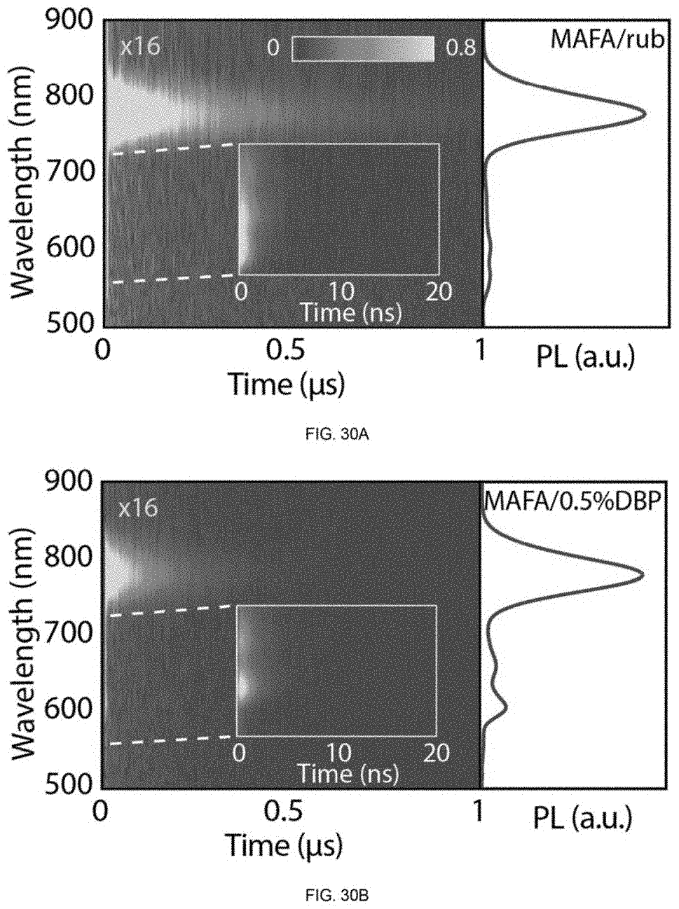

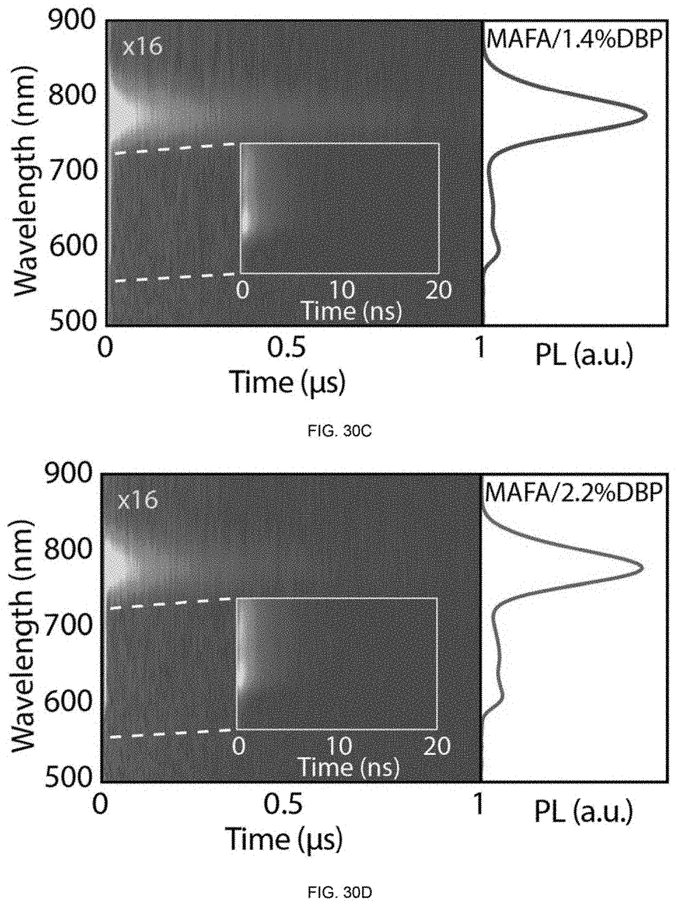

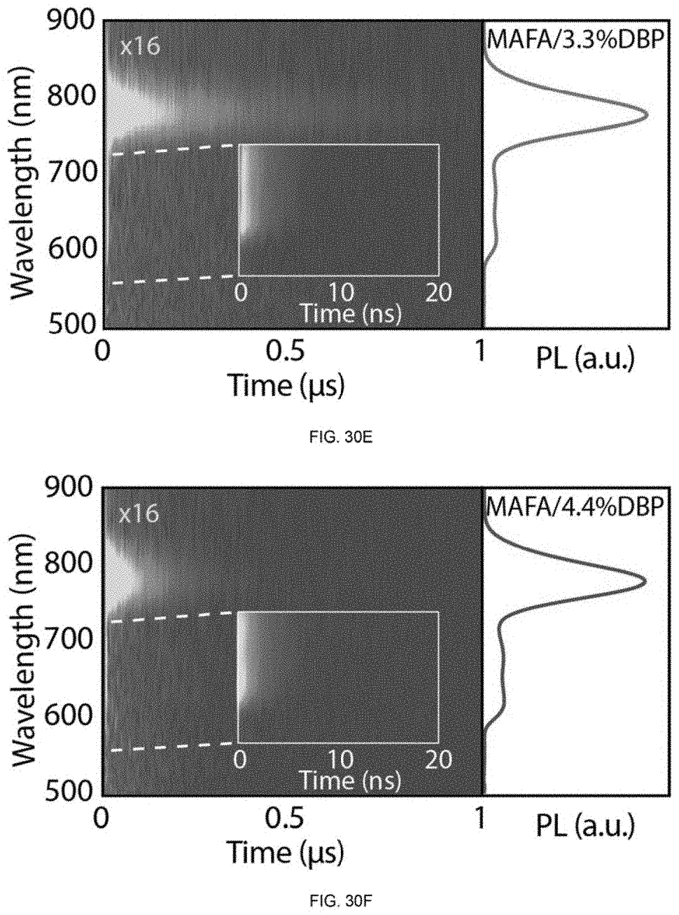

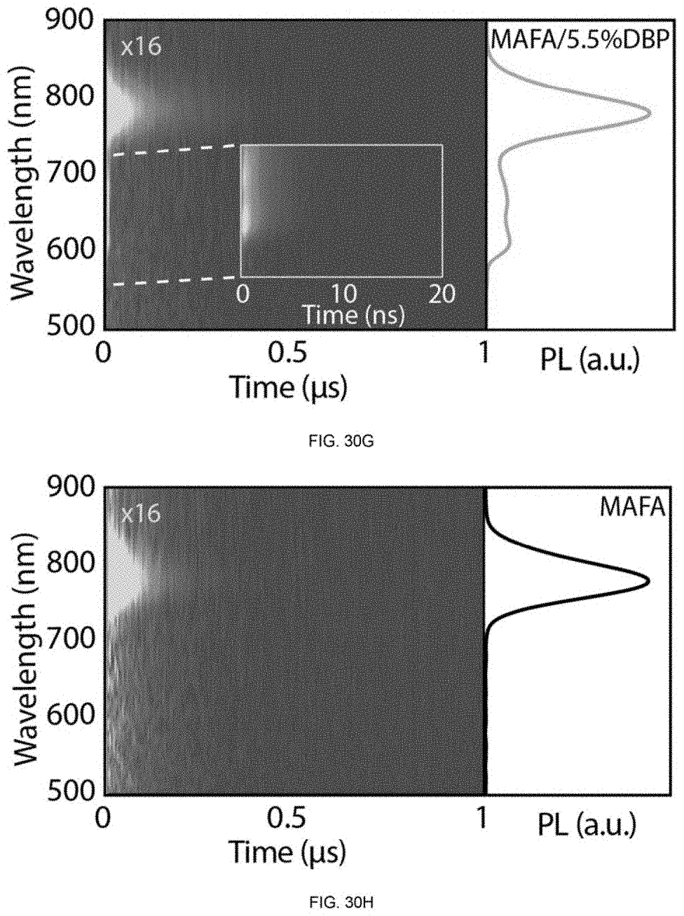

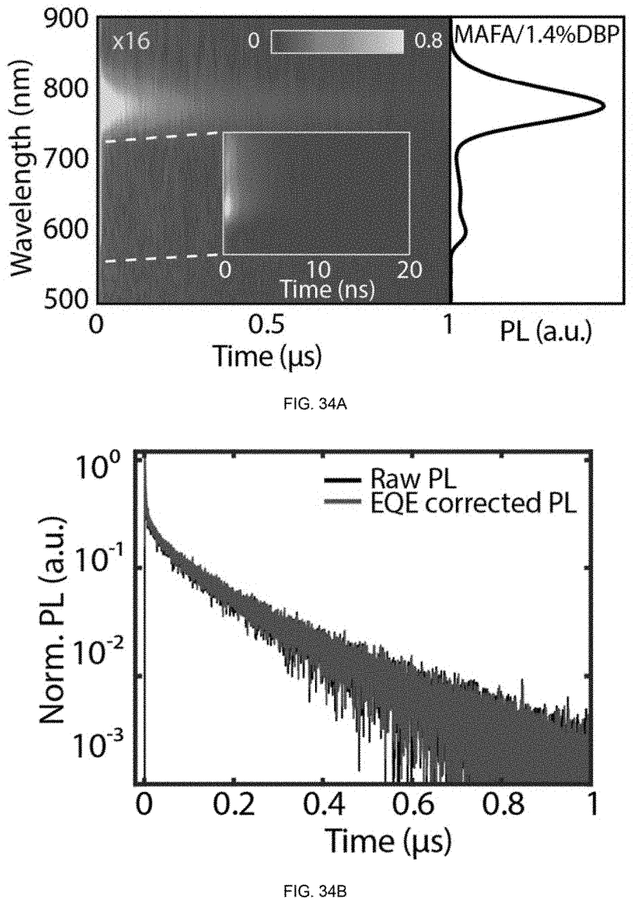

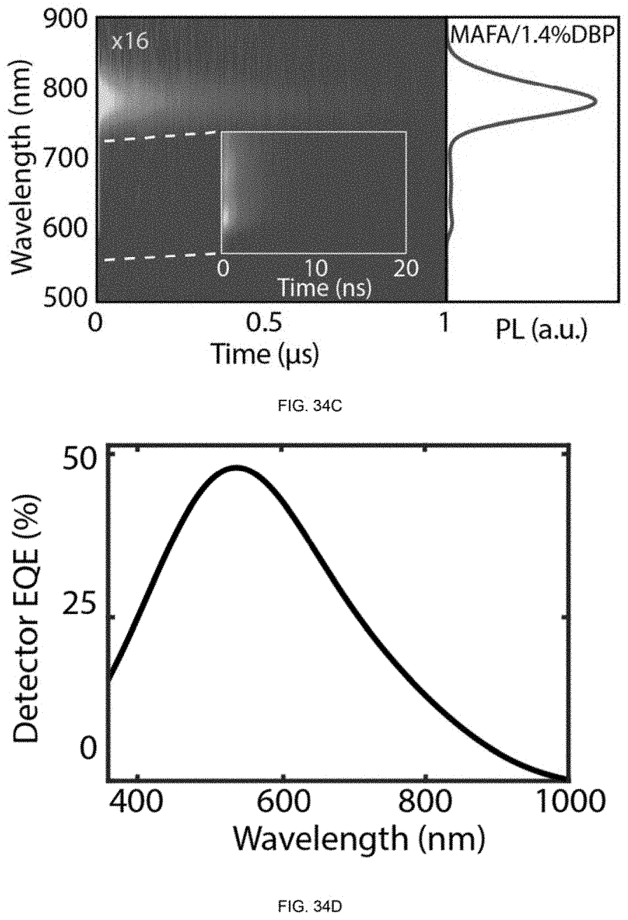

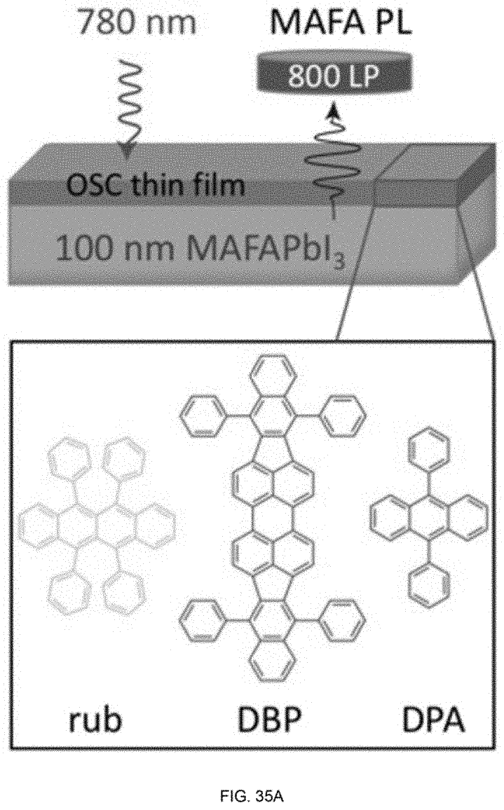

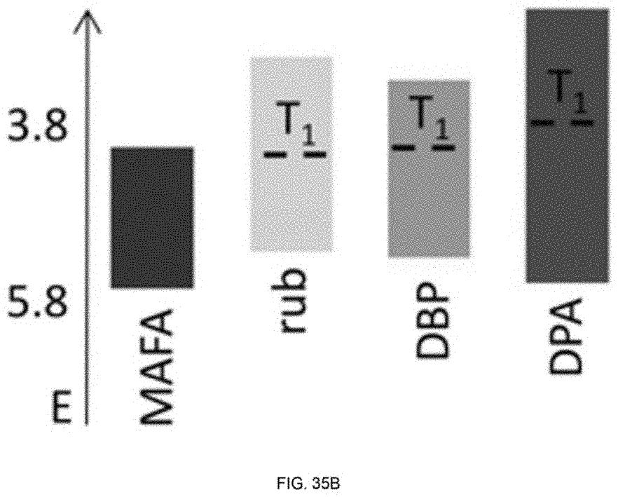

OSC solution characterization is shown in FIG. 26A-C. Integrated PL spectra and TRES of the MAFA/OSC thin films are shown in FIGS. 30A-H. Finally, detector external quantum efficiency influence is presented in FIGS. 34A-D.

Integrated PL Calculation.

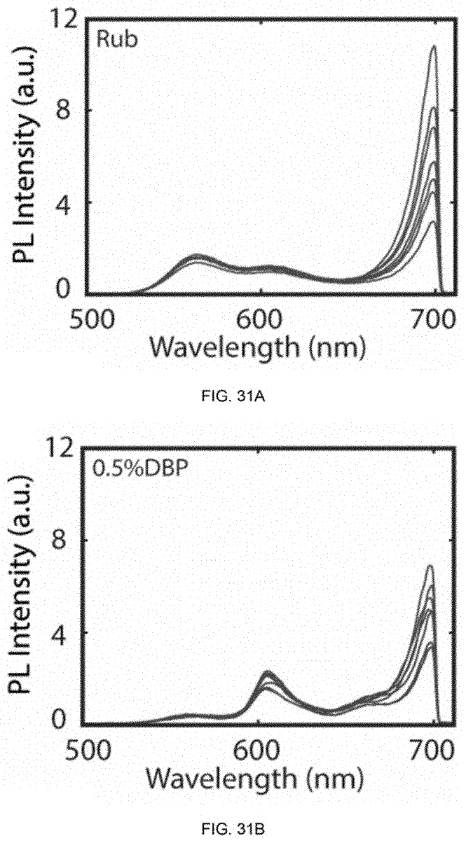

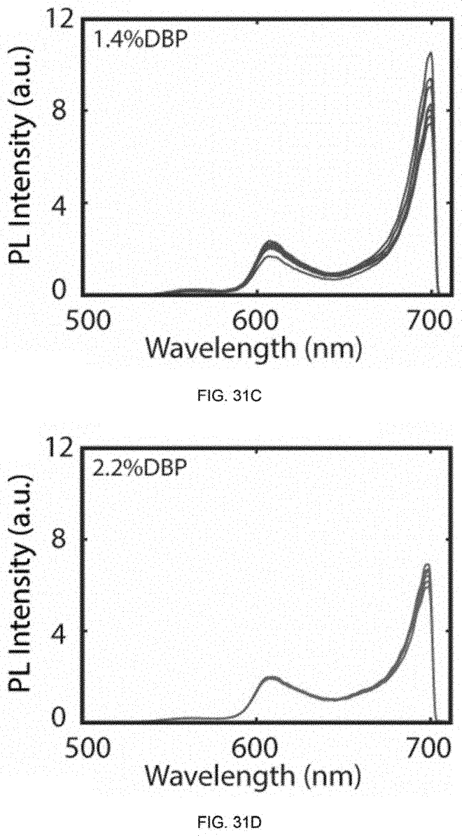

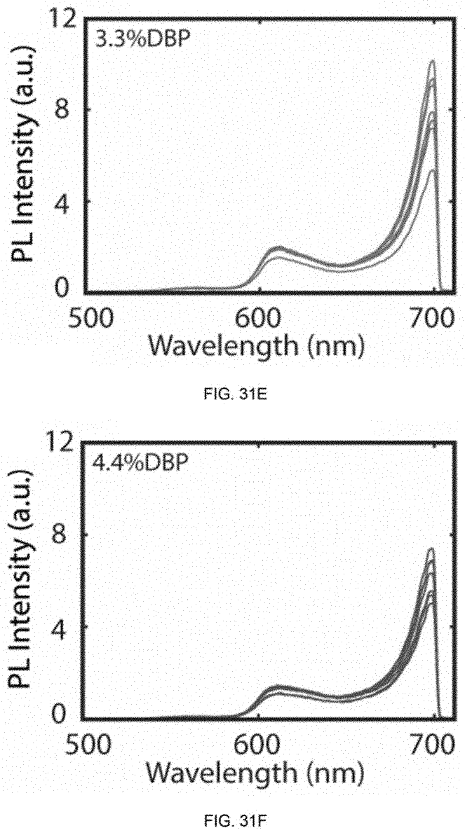

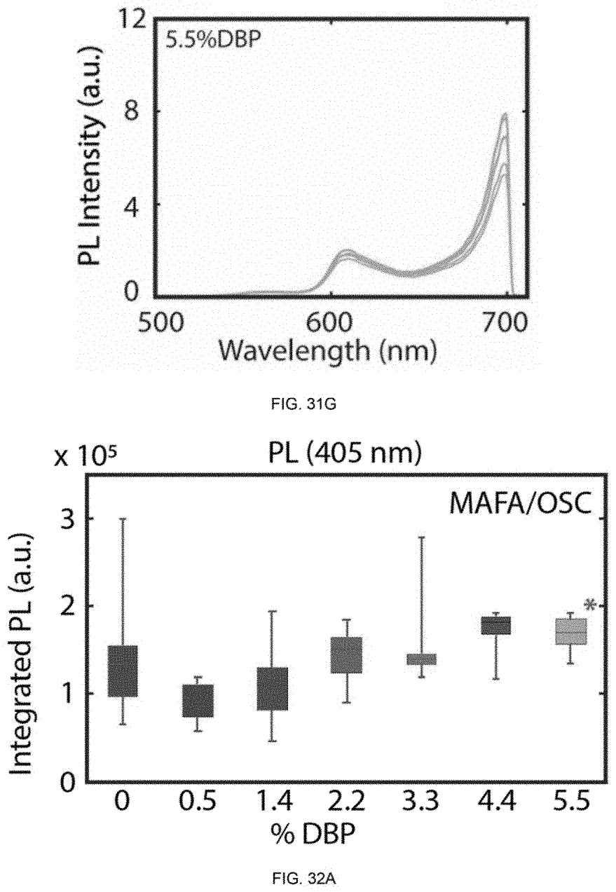

The PL emission of OSC-only films under 405 nm excitation, as well as MAFA/OSC films under both 405 nm and 780 nm excitation were measured for 7 different spots across each film (FIGS. 31A-G). These spectra were integrated from 500-700 nm for the box plots (FIGS. 22 and 32A-B). However, to avoid the emission onset of the MAFA PL, the MAFA/OSC PL was integrated only from 500-650 nm, and further normalized by the OSC-only emission.

Detector External Quantum Efficiency.

The detector external quantum efficiency (EQE) from visible to NIR wavelengths was obtained from PicoQuant. The detector response was fit to a Gaussian curve and the wavelength axis of the time resolved emission spectra was input to the Gaussian fit equation. The corresponding values output by the equation give the corresponding detector EQE values for the spectral region covered. The TRES was then normalized by the output EQE values.

Results and Discussion

Properties of OSC Thin Films.

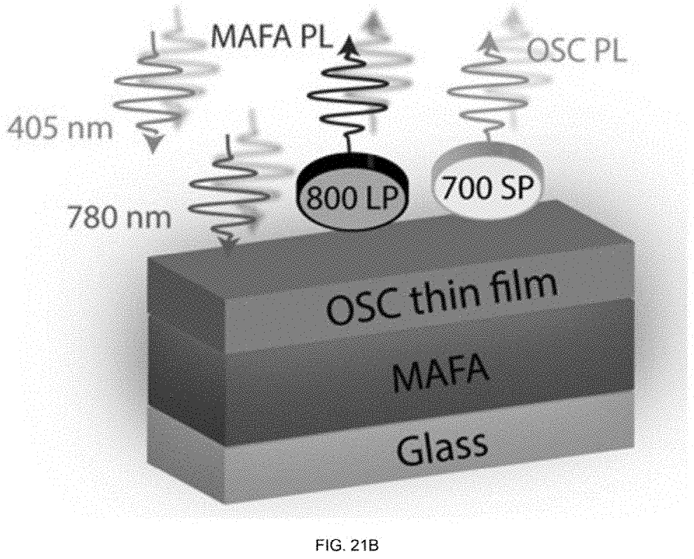

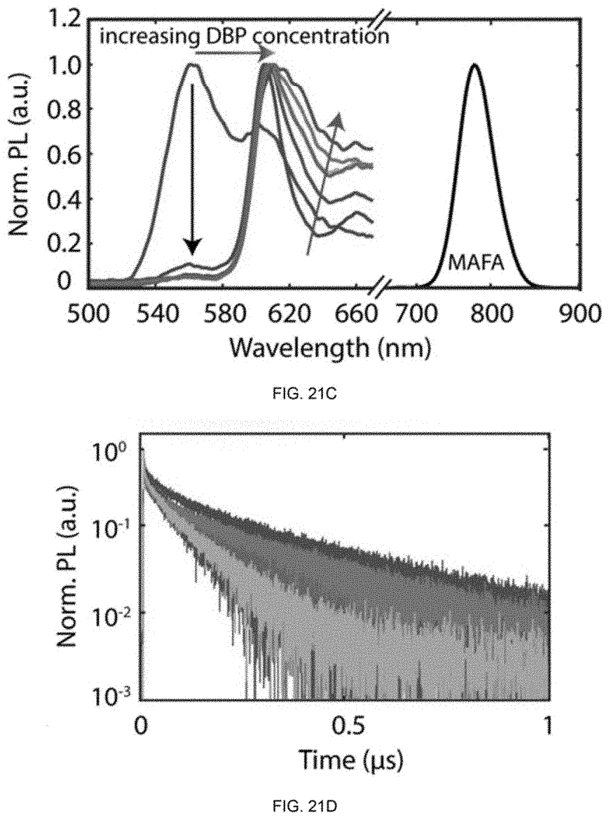

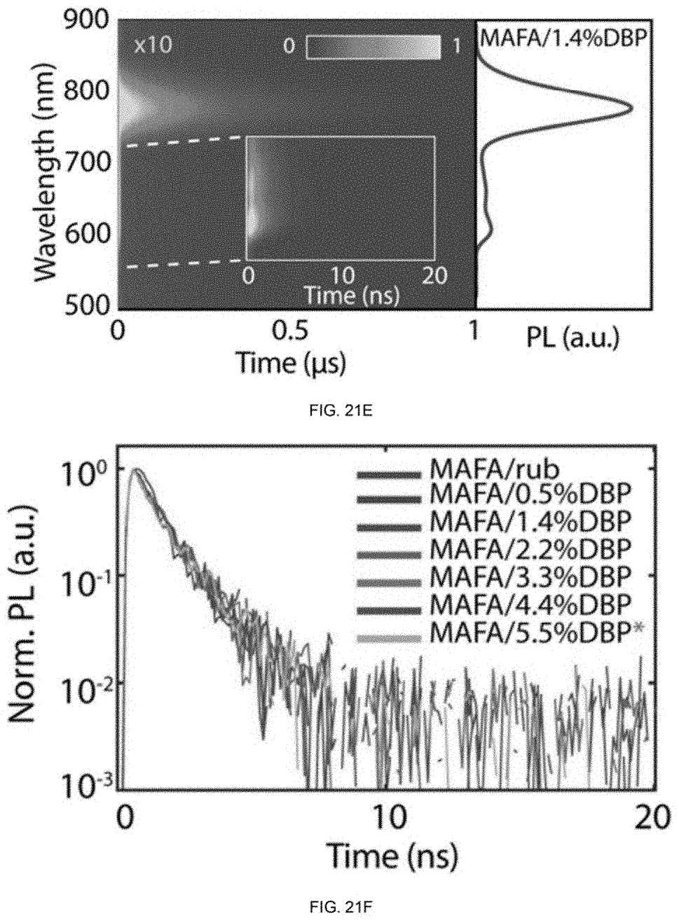

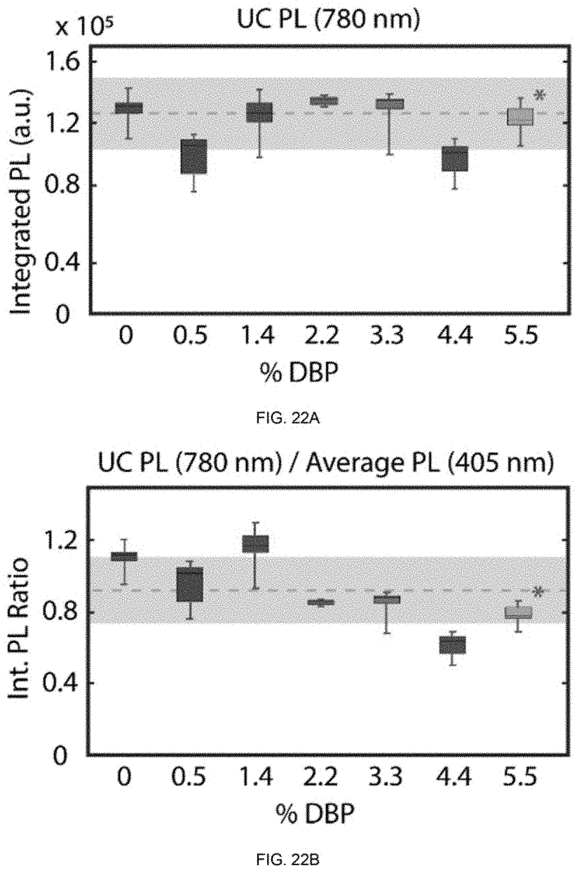

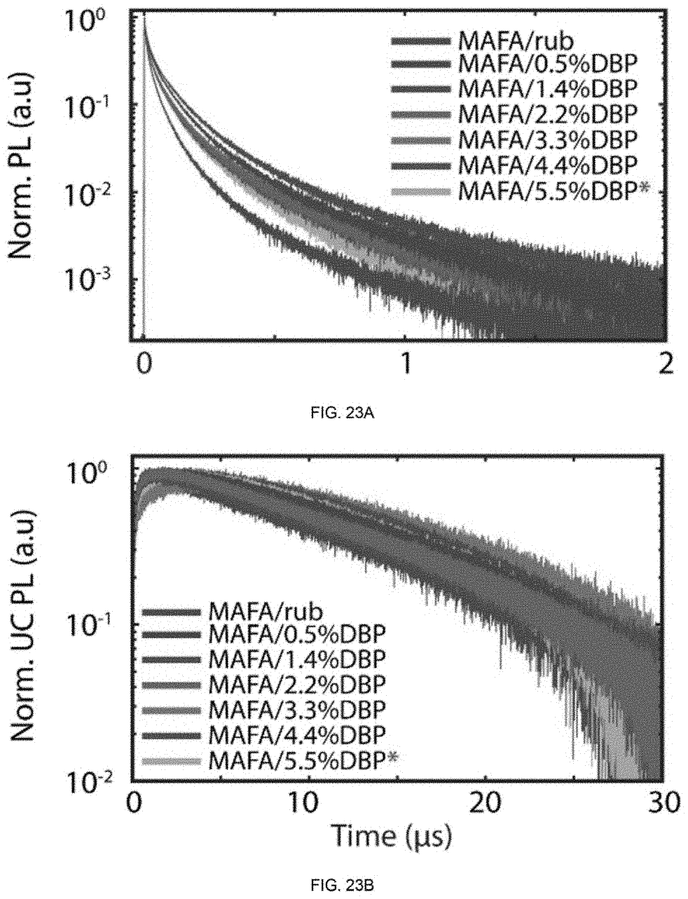

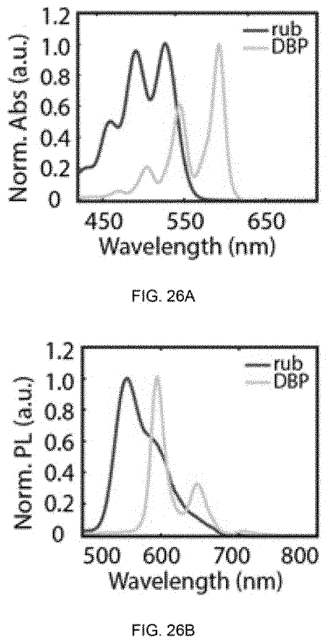

The properties of thin films prepared by the organic semiconductor (OSC) alone composed of rubrene and DBP was investigated to establish the effect of doping on the organic layer. FIG. 20A is a schematic of the OSC thin film on glass; FIG. 20B highlights the chemical structures of both the annihilator dye rubrene, as well as the dopant dye DBP. In FIG. 20C, the absorbance of the films is shown, which is dominated by the rubrene absorption highlighting the low doping concentration of DBP investigated: 0-5.5%. The absolute absorbance of the DBP-only film is fairly low, which can be attributed to the low solubility of DBP in toluene, and a resulting thinner film (compare FIG. 25), as well as poor adhesion to the glass substrate. FIG. 20D highlights the change of the emission profile of the OSC films. The rubrene only film shows the expected emission feature at ˜565 nm, as well as a further strong vibronic feature at ˜604 nm, a clear indication of the existence of (crystalline) aggregates. With increasing DBP doping, the trend is as expected. The peak at 565 nm attributed to the emission of the first vibronic feature of rubrene decreases and then becomes negligible at higher DBP doping concentrations. An increasing emission stemming from isolated DBP molecules centered at 605 nm is observed, with a slight red shift of the peak with increasing DBP concentration (compare FIGS. 21A-C for characterization of the organic dyes in solution). The DBP-only film shows even further red-shifted emission, indicating that close packing of the DBP molecules disfavors certain vibronic transitions and the interactions influence the emission wavelength. The increasing low-energy shoulder observed in the photoluminescence (PL) (gray arrow) of high DBP doping concentration in the rubrene films therefore indicates that there is phase segregation occurring in the films. A homogenous film is not found at high DBP concentrations of 5.5%, rather there are DBP islands within the doped rubrene film. Therefore, this concentration is annotated with a red asterisk, as its behavior is often comparable to a lower DBP concentration. FIG. 20E shows the PL decay dynamics of the OSC films under pulsed 405 nm excitation at a repetition rate of 2.5 MHz. As expected, the solid-state rubrene films show a fast decay attributed to rapid SF and spontaneous PL, followed by a longer tail due to delayed fluorescence stemming from TTA-UC. As the concentration of DBP is increased the amount of FRET is increased, and the early time component is elongated which is consistent with an increased singlet lifetime due to a reduced amount of SF. The delayed component is concurrently reduced, as less long-lived triplet states are created by the undesired SF process (compare Table 2).

It is observed that the OSC layer behaves as expected, and that only a minimal amount of emission from the first vibronic feature of rubrene can be observed at optimum doping levels close to 1% (compare Table 3). However, in previous reports of perovskite/OSC bilayer devices, relatively strong emission was observed at 565 nm, despite the addition of ˜1% DBP.

Properties of Bilayer Devices.

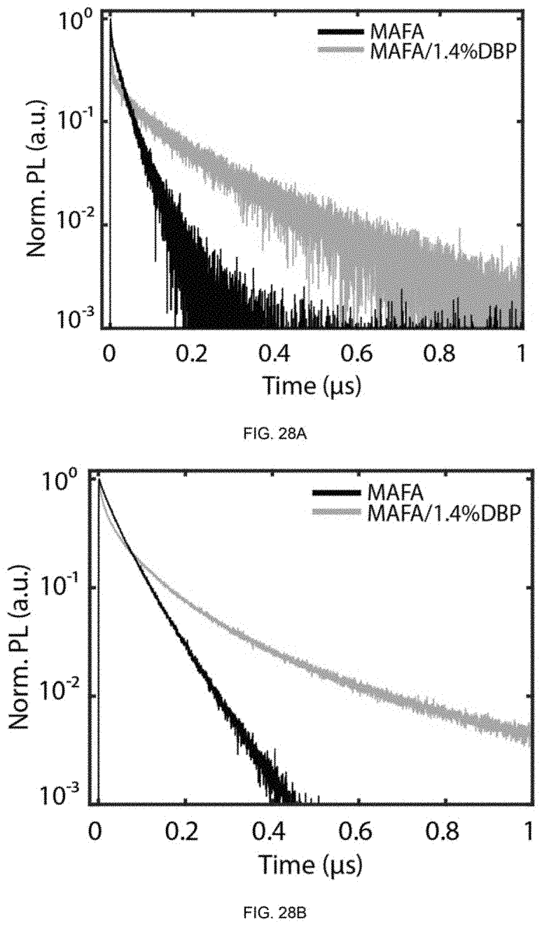

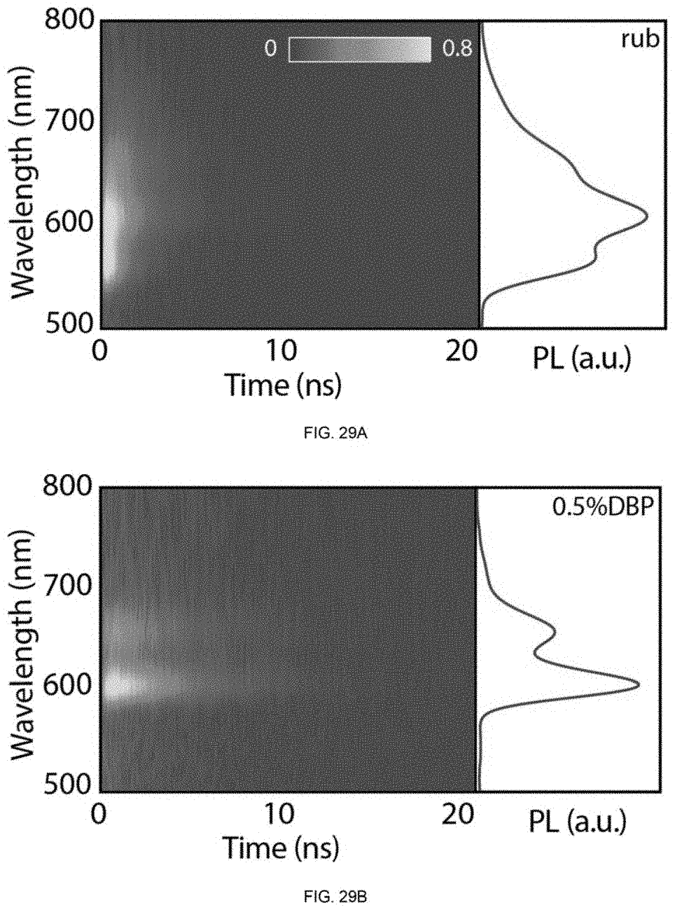

Several UC devices were fabricated based on methylammonium formamidinium lead triiodide perovskite (MA_{0.85}FA_{0.15}PbI₃, MAFA) thin films and a subsequent layer of the differently doped rubrene layers ranging between 0-5.5% DBP. The UC devices (MAFA/rubDBP) with varying DBP concentrations are specifically referred to as MAFArub (0% DBP) and MAFA/x % DBP (x=0.5−5.5). The absorbance of the bilayer films is highlighted in FIG. 21A, showing the expected sharp absorption onset at ˜780 nm, corresponding to the optical bandgap of this MAFA composition (˜1.6 eV). The bilayer device structure is shown in the schematic in FIG. 21B. As previously observed, the absorbance spectrum is dominated by the MAFA absorption and the distinct vibronic features of the thin organic layer are not distinguishable. The emission spectra of the bilayer devices with different DBP dopant concentrations under direct 405 nm excitation are shown in FIG. 21C. The MAFA emission at 780 nm is independent of the addition of the organic layer (compare FIG. 27). Similar to the OSC layers, under 405 nm excitation a reduction of the rubrene vibronic feature is observed at 565 nm, and a slight red shift of the DBP emission peak with increasing DBP concentration, as well as a broadening of the second vibronic feature due to molecular aggregation. However, in contrast to the OSC-only films, the increase of the red-shifted PL is more pronounced (gray arrow). Interestingly, an obvious difference in the shape of the PL spectrum is also seen for the undoped rubrene layer deposited on the MAFA thin film compared to the OSC-only film: the intensity of the second vibronic feature is reduced in comparison to the OSC-only film, possibly indicating a more disordered film with less crystalline regions. On the hydrophilic glass substrate used in the OSC-only films, the tetracene backbone of rubrene is expected to arrange upright at an angle to the surface, while the strong π-cation interactions between MA⁺ and rubrene will result in rubrene laying nearly flat on the perovskite surface. As a result, the solution-cast OSC layers will likely form in a different fashion based on the underlying substrate and the varying intermolecular interactions will yield different allowed transitions.

FIG. 21D shows the perovskite PL dynamics of the varying bilayer devices under 405 nm pulsed excitation obtained in the spectral range of 760-810 nm (compare FIGS. 28A-B for the MAFA only lifetime). The decay shows the typical behavior of perovskite films at low fluences: a rapid early-time quenching attributed to trap state filling or hot-carrier cooling, as well as a long-lived decay due to non-geminate carrier recombination. A decrease in the PL lifetime is observed with increasing DBP concentration (compare FIGS. 28A-B for the MAFA only lifetime under 405 nm excitation). The underlying cause is not clear, several possibilities include: i) energetically allowed hole extraction to DBP, ii) reduced passivation by rubrene, or iii) less optical absorption by the overlying OSC layer due to the red-shifted absorption of DBP, resulting in a higher effective fluence absorbed by the perovskite.

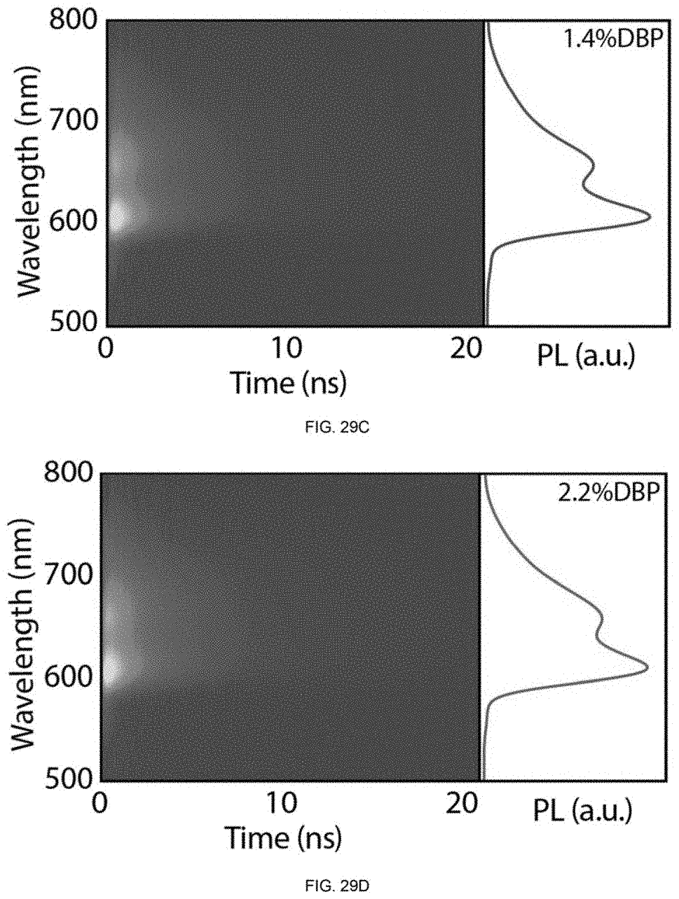

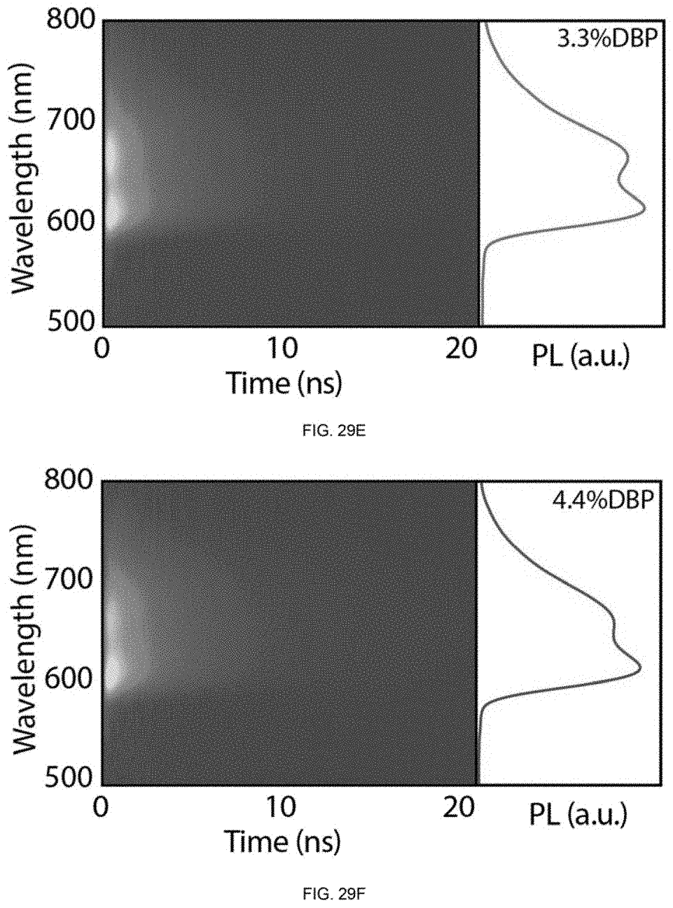

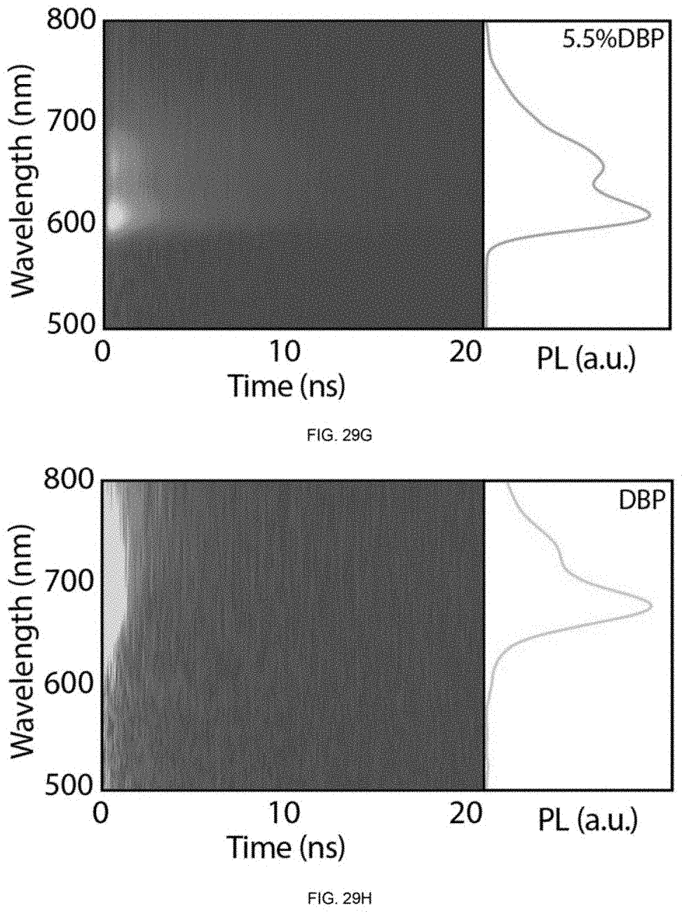

The time-resolved emission spectrum (TRES) of a representative bilayer device (1.4% DBP) is shown in FIG. 21E (compare FIGS. 29A-H for the other TRES maps and integrated spectra). The slow emission dynamics of the MAFA component is clearly seen in comparison to the rapid emission of the organic layer, which is fully decayed after ˜10 ns (compare inset). The time-integrated wavelength-resolved spectrum is shown on the right. Within the measurement uncertainty of the extracted lifetimes, no differences in the decay dynamics are observed, rather all OSC compositions exhibit similar lifetimes (FIG. 21F).

Fret Efficiency.

By comparing the residual intensity of the first vibronic emission feature of rubrene at 565 nm in the doped films I_{doped} to the undoped rubrene emission intensity I_{rub} under direct excitation at 405 nm, the FRET efficiency between rubrene and DBP of the fabricated OSC films can be estimated (FIG. 20D) and the disclosed MAFA-based UC devices (FIG. 21C). Table 2 indicates the relative quenching ratio

$$\frac{{I}_{rub}}{{I}_{doped}}$$

which reflects the quality of the FRET process in the disclosed OSC films and MAFA/rubDBP bilayer devices at different doping concentrations. As expected, a decrease in the relative intensity of rubrene's first vibronic feature is observed with increasing DBP doping concentration, and therefore an overall increase in the FRET efficiency

$${η}_{F R E T} = 1 - \frac{{I}_{rub}}{{I}_{doped}}$$

from rubrene to DBP. FRET can only occur if rubrene and DBP are within several nanometers of each other and oriented favorably, hence it is believed that the addition of more DBP reduces the average rubrene-DBP distance and therefore more efficient FRET can occur under direct 405 nm excitation.

TABLE 3
Relative quenching ratio of the rubrene emission at
565 nm under direct excitation of the OSC in the OSC-only and
MAFArub bilayer devices at 405 nm and the FRET efficiency η_{FRET}

| DBP | OSC: PL at 565 nm | | Bilayer: PL at 565 nm | |
|---|---|---|---|---|
| doping (%) | I_{rub}/I_{doped} | η_{FRET} | I_{rub}/I_{doped} | η_{FRET} |
| 0 | — | 0% | — | 0% |
| 0.5 | 0.16 | 84% | 0.16 | 84% |
| 1.4 | 0.083 | 92% | 0.071 | 93% |
| 2.2 | 0.069 | 93% | 0.081 | 92% |
| 3.3 | 0.068 | 93% | 0.069 | 93% |
| 4.4 | 0.049 | 95% | 0.065 | 93% |
| 5.5 | 0.025* | 98%* | 0.095 * | 90% * |

Upconverted Emission Intensities.

As the main goal of this study was to elucidate the effect of the DBP concentration on the overall performance of the MAFA/rubDBP UC devices, the upconverted emission intensities for all DBP doping concentrations were investigated. FIG. 22A depicts a box plot of the obtained UC PL intensity integrated from 500-700 nm to account for changes in the spectral shape for DBP doping percentages of 0-5.5% under 780 nm excitation (UC PL intensity was taken at 7 different spots across the films for statistics, compare FIGS. 31A-G for the single emission spectra). The UC efficiency η_{UC} (eq. 3) is defined as the product of intersystem crossing (ISC) η_{ISC}, the triplet energy transfer from the sensitizer to the annihilator η_{TET} and the TTA efficiency η_{TTA}. It is often normalized by the annihilator QY ηₐₙₙ. In bulk perovskite-sensitized UC, the triplet sensitization mechanism involves transfer of rapidly spin-mixing free carriers and removes the requirement of ISC. As a result, the UC efficiency simplifies to:

η_{UC}=η_{TET}η_{TTA}ηₐₙₙ. eq. 3

To remove the influence of the potentially underlying annihilator QY, in FIG. 22B the integrated UC intensity is shown normalized by the average integrated rubrene/DBP PL intensity under 405 nm excitation (compare also FIGS. 32A-B).

As mentioned previously, the DBP addition has previously been shown to result in a 19-fold increase in the observed upconverted emission for vapor-deposited UC devices. Interestingly, the same strong influence of the disclosed UC PL is not observed. Within measurement error, the DBP concentration does not appear to affect the upconverted PL intensity.

Time-Resolved PL Dynamics.

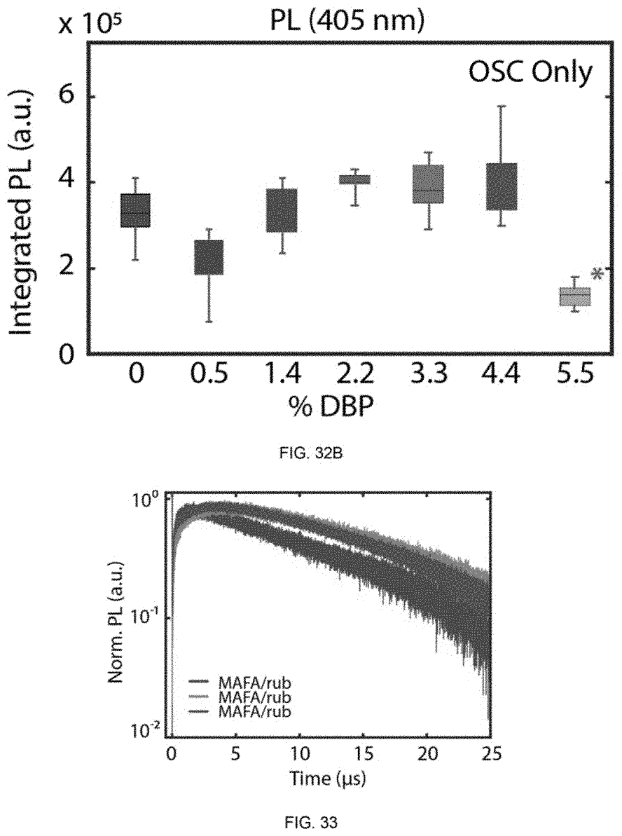

To further investigate the role of DBP on the UC PL intensity, the time-resolved PL dynamics of both the MAFA sensitizer (FIG. 23A) are examined, as well as the obtained UC dynamics (FIG. 23B). Typical behavior for the MAFA PL is observed in these bilayer devices: rapid quenching followed by an elongation of the PL dynamics at later times due to singlet back-transfer after successful TTA-UC. The UC PL dynamics are very similar across all doping concentrations investigated. Within sample-to-sample and spot-to-spot variations stemming from slight inhomogeneities across the sample (compare FIG. 33 for a variation of UC PL dynamics found for MAFArub. The variation in dynamics observed spans the range of dynamics found here for all dopant concentrations) leading to the conclusion that DBP plays no role in the carrier transfer, triplet sensitization or TTA process. This result is not unexpected, as the rubrene/DBP system is meant to simply be an annihilator/emitter system: as a result, rubrene dictates the TTA-UC properties, and DBP simply emits the singlets created in rubrene.

Upconverted Emission Under Steady-State Illumination Conditions.

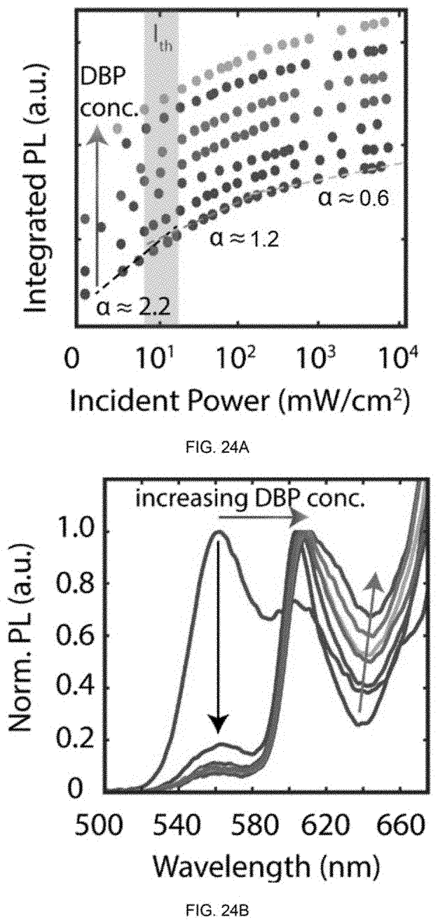

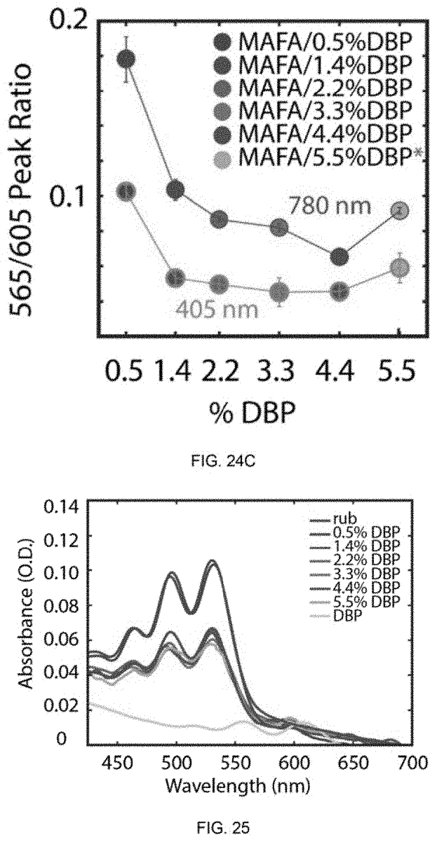

Lastly, the upconverted emission under steady-state illumination conditions is investigated. FIG. 24A shows the upconverted emission as a function of the incident power density. The resulting curves are offset for visualization purposes, and therefore not directly correlated to the brightness of a sample (also compare FIG. 22A). The power dependence of TTA-UC is unique: at low power, TTA is inefficient, and therefore, the triplet decay is dominated by other decay pathways, leading to a quadratic dependency of the UC PL on the incident power. At higher powers, above the so-called efficiency threshold Iₜₕ, this quadratic relationship gives way to a linear dependency. Above the intensity threshold, UC becomes efficient and the predominant triplet decay pathway becomes TTA, leading to the observed linear relationship. Non-geminate free carrier sensitization of the triplet state further complicates the relationship between the incident power and the upconverted PL intensity, as the perovskite exhibits a non-linear power dependency with a slope 1<β<2. It has previously been shown that this further influences the UC PL intensity dependence, resulting in an observed slope change from α=2β to α=β at the intensity threshold.

As expected, it is observed that the power dependence of the UC PL intensity is independent of the DBP doping concentration. In agreement with previous results, a value Il m 10 mW/cm² is obtained for all bilayer devices. FIG. 24B shows the normalized upconverted PL spectra under 780 nm excitation for the bilayer devices fabricated with the different DBP doping concentrations (compare FIG. 33). The same behavior is observed as under direct 405 nm excitation: a red shift of the PL peak intensity, as well as an increase in the emission intensity from the second vibronic feature indicating aggregation of DBP. For the DBP doped samples, one major difference becomes obvious: the quenching of the rubrene emission is not as pronounced as observed under direct 405 nm excitation. As the quenching of the rubrene emission feature in presence of the DBP acceptor cannot be directly compared across doping concentrations, the ratio of the rubrene and DBP emission can be instructive. In FIG. 24C, the ratio of the first vibronic feature of rubrene at 565 nm and the first vibronic feature of DBP at 605 nm under both direct 405 nm excitation are plotted, as well as the 780 nm excitation which results in the upconverted PL. The expected monotonic decrease of the ratio up to 4.4% DBP doping is found, indicating an increase in FRET efficiency, followed by a slight increase in the ratio due to the inhomogeneities resulting from DBP agglomeration in the highest doping concentration of 5.5%. This ratio is higher for the upconverted PL than for the direct emission, which indicates that the FRET efficiency η_{FRET} is lower under 780 nm excitation than under 405 nm excitation. This result is unexpected as the FRET efficiency between rubrene and DBP should not be influenced by the process resulting in the excited singlet state in rubrene. Therefore, a different sub-population of rubrene molecules must be undergoing TTA-UC and emitting the upconverted PL, than is emitting under direct 405 nm excitation.

TABLE 4
Relative quenching ratio of the rubrene
emission at 565 nm under 780 nm excitation
resulting in TTA-UC and the FRET efficiency η_{FRET}.

| DBP | UC PL at 565 nm | |
|---|---|---|
| doping (%) | I_{rub}/I_{doped} | η_{FRET} |
| 0 | — | 0% |
| 0.5 | 0.22 | 78% |
| 1.4 | 0.12 | 88% |
| 2.2 | 0.10 | 90% |
| 3.3 | 0.09 | 91% |
| 4.4 | 0.05 | 95% |
| 5.5 | 0.10 | 90% |

However, there is no indication that DBP significantly enhances the intensity of the upconverted emission in the solution-fabricated perovskite-sensitized UC devices. As expected, the time-resolved PL spectroscopy shows that DBP does not play a role in the triplet sensitization or UC mechanism, rather acts only as a singlet sink after TTA has occurred to avoid SF. Typical aggregation-induced effects can be observed for DBP concentrations above ˜1%, resulting in a visible red-shift of the DBP emission, thus further reducing the energy gained by UC. This would indicate that the addition of DBP especially at high concentrations and the resulting 0.15 eV energy loss due to FRET do more harm than good in these solution-fabricated devices.

Conclusions.

One of the major differences from previous work is the processing condition of the OSC layer. In previous PbS quantum dot-based UC devices, the doped organic layer was co-deposited by thermal evaporation, while in the disclosed processes, solution processing is being used to fabricate the OSC layer. Vapor deposition commonly results in crystalline rubrene films, where the individual rubrene molecules are aligned in an orthorhombic crystal structure and due to this long-range order allowing for the delocalization of the rubrene singlet state; these films are primed for rapid SF to occur. In these studies, it was shown that DBP is a requirement to harvest the singlets prior to rapid SF in rubrene.

As shown in previous studies, the solution-processing of the OSC layer results in a combination of both amorphous, as well as crystalline regions. Fully amorphous rubrene layers have been shown to exhibit no SF due to the lack of long-range order in the OSC film, and have a PL lifetime similar to rubrene in solution. Based on the collected emission spectra, time-resolved PL dynamics and surface morphologies, it is believed that both crystalline and amorphous regions of rubrene must be present in the disclosed films. A certain amount of molecular alignment within the rubrene layer will also be required for TTA-UC to occur. Changing the rubrene crystallinity from polycrystalline to amorphous has been shown to reduce the rate of SF 10-fold, as the excitons cannot delocalize in the same manner with lack of long-range order, thus slowing the SF process. However, due to their very long lifetimes (˜100 μs), triplets can diffuse over long distances throughout the amorphous rubrene film to find properly aligned molecules for TTA-UC. Employing fluorescence lifetime imaging microscopy (FLIM), it has previously been observed that the crystalline regions of rubrene are UC inactive, likely due to rapid SF—further supporting the hypothesis that the unusually high UC observed in rubrene-only UC devices in comparison to the DBP-doped counterparts is due to reduced amounts of SF.

It is noted that DBP is only poorly soluble in toluene, and it is therefore likely that small DBP aggregates form, which can act as nucleation centers for crystalline rubrene agglomerates. As a result, the overall properties of such an upconversion device is more similar to a lower concentration, as DBP agglomerates will reduce the amount of DBP dispersed throughout the OSC.

In summary, the dependence of the UC PL intensity, as well as the triplet sensitization and UC mechanism on the DBP doping concentration, has been investigated. In contrast to previous reports which show a ˜19-fold increase in the UC PL upon DBP addition, very little change in the observed UC PL intensity for the disclosed devices and processes. However, the addition of DBP red shifts the UC emission by ˜0.15 eV, thus reduces the energy gained in the UC process. The reduced influence of SF in the solution-processed devices can be attributed to the lack of long-range order in the created amorphous rubrene film, which reduces the rate of SF. Within measurement uncertainty, all of the solution-processed devices exhibit the same amount of UC emission, indicating that further work on film reproducibility, film homogeneity and a more controlled fabrication technique may be required to fully harvest the full potential of these devices.

### Example 4: Precharging Photon Upconversion—Interfacial Interactions in Solution-Processed Perovskite Upconversion Devices

Despite recent advances, many open questions must be addressed before the dominant mechanism in perovskite-sensitized upconversion can be considered confirmed. A lack of obvious quenching of the NIR MAFA PL has been reported, which is counterintuitive, as UC emission can clearly be observed, indicating that energy must have been transferred into the upconverting rubrene layer. Due to the low exciton-binding energy of the perovskite, initially bound excitons rapidly decay into free carries and recombine via non-geminate pathways. The exact role of free carries vs. possible excitons is not well understood in these bilayer devices. Questions arise whether an unexpected long-lived non-geminate bound electron-hole pair is transferring to the rubrene through e.g. an excitonic surface trap state or a bound charge-transfer state, or free carriers are transferring independently. Despite an expected high number of holes in the rubrene layer, triplet-charge annihilation (TCA) has not been observed, but this does not exclude triplet sensitization by direct carrier injection into the triplet state. Further, no optical signature of a bound charge-transfer state has been observed, however it cannot be ruled out at this time. There is no clear understanding of the role of potential long-lived surface trap states, as the native perovskite NIR PL dynamics in the presence of rubrene cannot be observed. Additionally, subsequent solution-processed fabrication steps have the potential to perturb the native perovskite properties, disallowing a direct comparison of the MAFA properties with those of the bilayer device.

Experimental Procedures

Device Fabrication.

Glass substrates were cleaned in 2% Hellmanex solution, water, and ethanol by sonication. The substrates were then placed in an UV ozone plasma cleaner (Ossila) for 15 min. The perovskite absorber layer was prepared by using PbI₂ (1.2 M, 99.99% Sigma Aldrich) and MAI (1.2 M, Dyenamo) in an overstoichiometric ratio, and PbI₂ (1.2 M, 99.99% Sigma Aldrich) and FAI (1.2 M, Dyenamo) in an overstoichiometric ratio. PbI₂ was dissolved in anhydrous DMF:DMSO 9:1 (v:v, Sigma Aldrich). The resulting perovskite solution was diluted to yield a 0.6 M concentration by adding DMF:DMSO 9:1 (v:v). A two-step program was used to fabricate the perovskite films: 1000 rpm for 10 s and 4000 rpm for 30 s. 130 μL of anhydrous chlorobenzene (Sigma Aldrich) were added as anti-solvent. The perovskite films were then annealed at 100° C. for 10 min under air-free conditions.

To fabricate UC bilayer devices, rubrene (99.99%) and dibenzotetraphenylperiflanthene (DBP 98% HPLC) were purchased from Sigma Aldrich. For comparison, diphenylanthracene (DPA>99.0%) was purchased from TCI. All chemicals were used without further purification. 10 mg/mL, 1 mg/mL and 10 mg/mL solutions for rubrene, DBP, and DPA, were prepared in anhydrous toluene (Sigma Aldrich), respectively. To study the influence of DBP, a 10 mg/mL rubrene solution in anhydrous toluene doped with 1.1% DBP (1 mg/mL) was prepared. 20 μL of each solution were then spin-coated on the perovskite thin film at 6000 rpm for 20 s. For comparison, only 20 μL of toluene were spin-coated onto the perovskite to study the influence of the solvent on the second spin-coating process. The films were then sealed using a 2-part epoxy (Devcon) under nitrogen.

Optical Characterization.

Absorption spectra were measured using a UV-vis spectrometer (Shimadzu UV-2450). Steady-state PL spectra were measured at an OceanOptics spectrometer (HR2000+ES) under continuous wave excitation using a 405 nm (PicoQuant LDH-D-C-405) and 780 nm (PicoQuant LDH-D-C-780) laser diode. Time-correlated single-photon counting (TCSPC) was used to measure time-resolved PL lifetimes by exciting the samples under 780 nm by a picosecond pulsed laser diode (PicoQuant LDH-D-C-780). A singe photon avalanche photodiode (Micro Photon Devices) and a HydraHarp 400 (PicoQuant) was used to measure the photon arrival times using reflective optics. The MAFA lifetimes were measured with an 800 nm long pass filter (Thorabs) to remove laser scatter at a repetition rate of 31.25 kHz with a 512 μs time resolution. A 600±40 nm bandpass filter was used to measure the upconverted dynamics. To obtain the power-dependent PL intensities, the 780 nm laser diode was used in continuous wave mode and the arriving photons were counted for 20 s with an 800 nm long pass filter under various incident excitation powers. The PL intensities over 30 s were measured in T2 mode of the HydraHarp for the MAFA PL under pulsed 780 nm equipped with an 800 nm long pass filter, and for the UC PL under pulsed 780 nm excitation with a 600±40 nm bandpass filter. The resulting photon arrival times were then plotted in a histogram. A silicon power meter (Thorabs PM100-D) was used to measure the power of the incident laser beam.

Results and Discussion

Film Properties.

To distinguish between effects caused by the second spin-coating step using toluene as the solvent for rubrene/DBP, and interactions between the deposited organic layer and the MAFA thin film, the properties of the as-fabricated MAFA film, the bilayer MAFA/rub/DBP UC device and the following control samples were investigated: i) MAFA with toluene spin-coated on top (MAFA/toluene), ii) MAFA with only rubrene (MAFA/rub), iii) MAFA with only DBP (MAFA/DBP), and iv) MAFA with 9,10-diphenylanthracene spin-coated on top (MAFA/DPA). The latter sample is an inert control not expected to be capable of efficient carrier extraction, as there is little driving force for hole transfer into the ground state of DPA and the triplet level is too high in energy for electron injection. These samples were chosen to unravel the independent role of each component of the fabricated UC devices and to elucidate the underlying transfer processes.

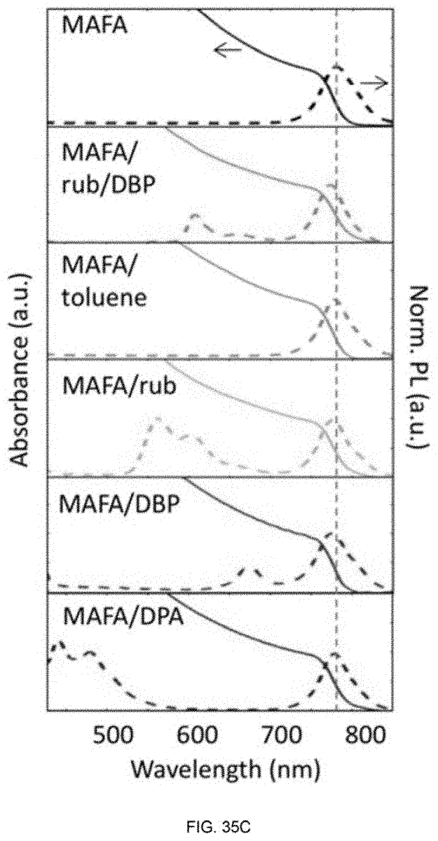

FIG. 35A highlights the bilayer architecture of the disclosed devices (top) and shows the molecular structures of the employed organic semiconductor (OSC) layers studied here: rubrene (pink), DBP (purple), and DPA (blue) (bottom). FIG. 35B depicts the expected absolute energy levels of the materials used. The devices are first characterized by absorbance and steady-state PL spectroscopy, as shown in FIG. 35C. The absorption onset of MAFA is found at ˜800 nm, corresponding to the expected optical bandgap of 1.55 eV for this composition.

While the additional fabrication step does not greatly influence the position of the perovskite absorption onset, it does appear to slightly affect the optical density of the films, indicating that the perovskite film may have been partially dissolved in the second spin-coating step. In addition, a less sharp absorption onset is observed, suggesting scattering in the bilayer devices with a high concentration of organics added. DBP is only poorly soluble in toluene thus, only a thin DBP layer is expected to form on top of the perovskite film, and the scattering effect is not as pronounced as in the rubrene and DPA-based bilayers. A slight blue-shift of the MAFA emission wavelength (λ=780 nm) of 2-3 nm can be observed upon secondary solution-processed deposition. This is in line with previous observations, and indicates a slight shift of the underlying perovskite composition to a higher methylammonium concentration, as quantum-confined effects can be excluded. To further investigate the influence of the solution-processing on the perovskite surface trap density and therefore the recombination dynamics, the power dependence of the MAFA emission was investigated.

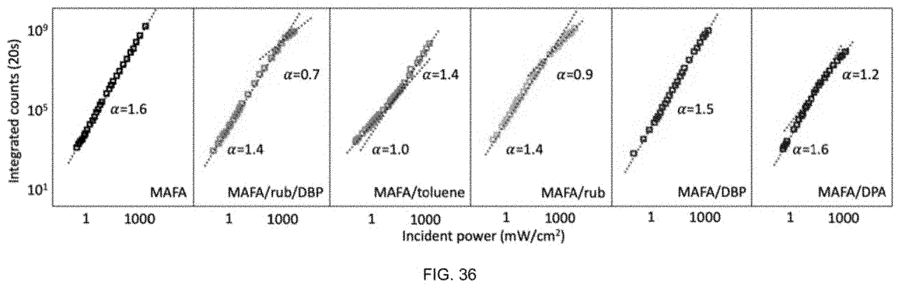

Due to the non-geminate nature of bimolecular free carrier recombination in perovskite thin films, a quadratic dependence of the NIR MAFA PL (λ>800 nm) vs. the incident power density is expected for carrier densities below n₀≅10¹⁷. As shown previously, this is only valid for thick perovskite films, which are only marginally influenced by surface properties due to the small surface-to-volume ratio. As the films become thinner, the effects of surface traps become relevant, reducing the slope below the expected value of α=2. FIG. 36 highlights the power dependence of the MAFA PL on the incident power dependency for all devices. For the unaltered MAFA film, a constant slope of α=1.6 is determined, consistent with previously reported data. Similar slopes in the range of α=1.4-1.6 are obtained for the organic semiconductor (DBP, DPA, rubrene and rub/DBP) coated MAFA films, with a saturation at higher incident power densities which has been attributed to band-filling and non-radiative Auger processes.

Interestingly, the toluene treated sample (MAFA/toluene) exhibits a different behavior. Here, a change from α=1.0 to α=1.4 can be observed. This has previously been observed in similar perovskite films and indicates a power-dependent PL intensity due to rapid trap filling at low incident power densities and an increase in the PL QY at higher densities, above a threshold intensity at which a sufficient number of traps are filled. Although toluene is a known antisolvent for perovskite film fabrication, it slightly reduces the perovskite film thickness and increases the trap density. By adding organic molecules such as rubrene, DBP or DPA in the second solution-processed step some of these traps can be passivated which in turn can be seen in a recovery of the PL power dependence. Others have reported a chelation-like interaction between the delocalized π-system in rubrene and the methylammonium cations in the perovskite as the underlying cause of the passivation effect. Since organic molecules can only passivate surface traps, the slightly lower slope compared to the unaltered perovskite film may indicate the creation of additional bulk traps in the fabrication process.

Time-Resolved PL Spectroscopy.

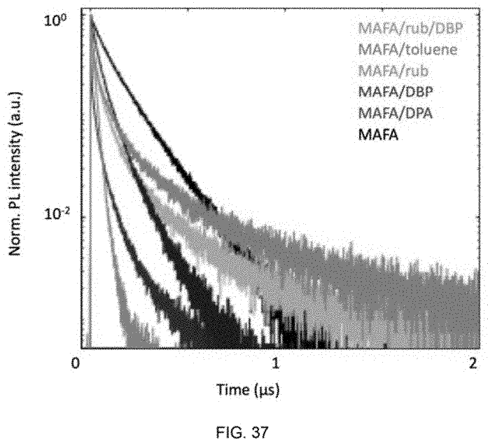

Time-resolved PL spectroscopy can be used to further confirm that the change in the PL power dependence is indeed due to rapid non-radiative recombination into perovskite surface trap states, which manifests in a reduction of the lifetime. FIG. 37 shows the recombination dynamics under 780 nm excitation for the different samples at an average incident power density of 3.2 mW/cm² at a repetition rate of 31.25 kHz.

The unaltered MAFA film shows a typical nearly monoexponential lifetime with a characteristic decay time of 100 ns. As expected for a sample with a higher trap density, a rapid quenching of the MAFA PL lifetime is seen for the MAFA/toluene sample. In contrast, the MAFA/DPA PL lifetime is longer, indicating that the addition of the organic layer indeed passivates surface trap states introduced in the second fabrication step. Since charge extraction is not energetically favored, predominately effects of surface passivation should be seen due to non-covalent cation-π interactions. The MAFA/rub/DBP bilayer shows the previously observed dynamics: initial quenching is followed by along-lived tail due to delayed PL stemming from singlet back-transfer after TTA. The MAFA/rub bilayer shows the same general dynamics, but exhibits less of the long-lived tail due to less singlet back-transfer. This agrees with a reduced excited state singlet lifetime in the rubrene layer due to rapid singlet fission, and therefore less likely resonant energy transfer. Lastly, MAFA/DBP exhibits a highly quenched lifetime. This can be explained by a combination of two effects: i) poor surface passivation due to the low solubility of DBP in toluene, and ii) favorable band alignment for hole extraction, yet a small energy barrier on the order of kT for the electron extraction to the DBP triplet state. As a result, both the hole and electron could potentially be extracted to the triplet state. However, since TTA is not known to occur in DBP, no high-energy singlets are created.

Table 5 depicts an overview of the extracted lifetimes for all devices. Due to the highly multiexponential behavior of the dynamics, the characteristic time T_{1/e} for the population to decay to 1/e is reported.

TABLE 5
Extracted NIR PL lifetimes τ_{1/e} for differently treated MAFA films

| | | MAFA/ | MAFA/ | MAFA/ | MAFA/ | MAFA/ |
|---|---|---|---|---|---|---|
| | MAFA | rub/DBP | toluene | rub | DBP | DPA |
| τ_{1/e} | 100 ns | 23 ns | 15 ns | 20 ns | 4 ns | 43 ns |

Thus far, it has been established that the organic semiconductor layers passivate the perovskite surface trap states induced by the additional fabrication step due to non-covalent interactions.

Effect of the Perovskite-Rubrene/DBP Interface on UC Properties.

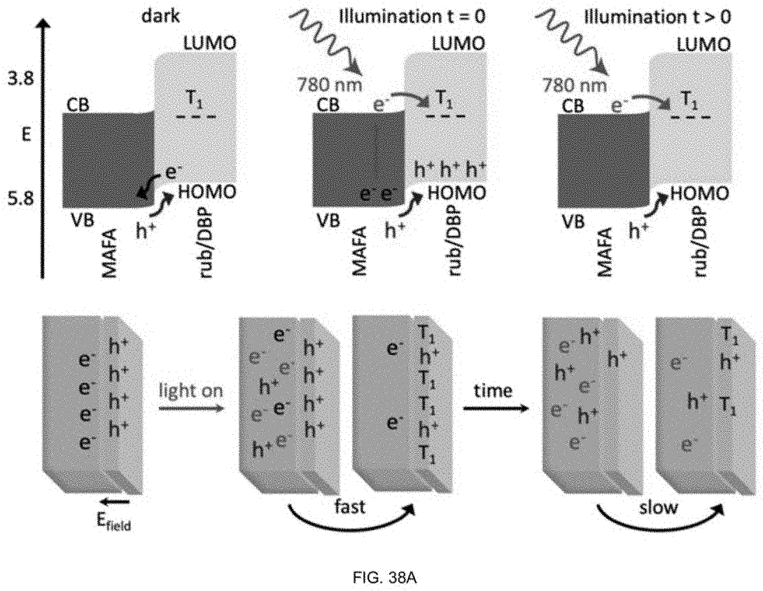

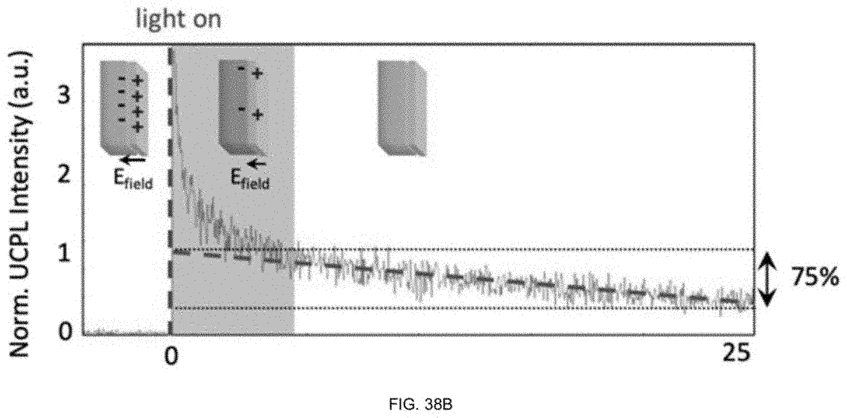

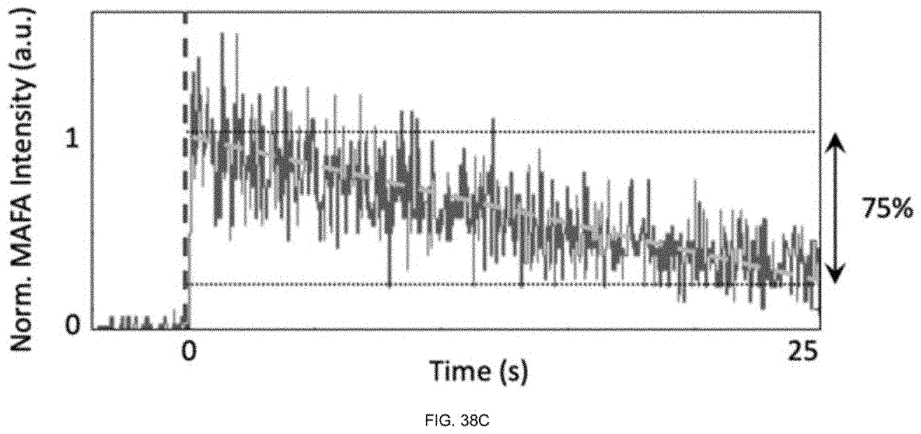

In the following, the perovskite-rubrene/DBP interface is examined in more detail, and the effect of the interface on the UC properties. In particular, the effects of free carriers and charge transfer at the interface to understand the consequences in the desired TTA-UC process are explored. Previous reports have employed rubrene as a hole transport layer and thus, scrutinized the perovskite-rubrene interface in detail. Their results aid in the further understanding of the UC system presented here. Interactions between the rubrene layer and the perovskite result in an upward bending of the perovskite valence and conduction bands, consequently a downward bending of the rubrene highest occupied molecular orbital (HOMO) and lowest unoccupied molecular orbital (LUMO). Charge transfer (hole transfer) slowly occurs at the interface in the dark to establish equilibrium conditions and results in the buildup of an electric potential at the interface creating a space charge region (FIG. 38A). The upward band bending of the perovskite bands facilitates hole transfer and can aid in the electron transfer processes required for triplet creation. The induced electric potential at the interface further explains the lack of TCA, as holes are attracted to the interface by electrostatic interactions and therefore are not likely to freely move through the rubrene layer (FIG. 38A). Electric field-effect passivation gives an additional cause for the lack of quenching observed in the MAFA/rub/DBP bilayer devices, even in presence of the triplet acceptor rubrene.

A rapid “photobleach” of the UC PL over the course of several seconds of illumination has been demonstrated (FIG. 38B, purple box), however, did not give a detailed reasoning for this effect and rather focused on the steady-state properties and the effect of the triplet population on the UC efficiency.

Based on an expected electric potential buildup in the space charge region, it is proposed that, prior to illumination, the rubrene at the interface is “precharged” with holes (FIG. 38A), with an accumulation of negative charges at the perovskite interface. For simplicity, charge accumulation at the interface of the inherently n-type MAFA is omitted in the associated schematics and only the holes and electrons that transfer at the interface are highlighted. Since only electron transfer is still required upon initial excitation to sensitize the rubrene triplet state, this results in a high density of triplets at the interface. Hence, very rapid TTA can occur initially as very little triplet diffusion is required for two triplets to collide, and a higher UC PLQY (despite higher back-transfer closer to the interface) is observed at early times after illumination. This high UC efficiency tapers off into a steady-state at long times as the triplet sensitization is limited by slow charge transport in the perovskite to the interface. Without an external driving force (e.g. the induced electric field), there is no incentive for both charge carriers to rapidly diffuse to the perovskite/rubrene interface. As reported previously, the UC PL intensity depends on the properties of the underlying MAFA PL. A reduction in the MAFA PL intensity of about 75% (FIG. 38C) is observed under the low average excitation fluence of 3.2 mW/cm², which is mirrored in the UC PL (FIG. 38B) at longer times after equilibrium has been achieved (purple dashed lines).

Time-Scale of Build-Up of Interfacial Electric Field.

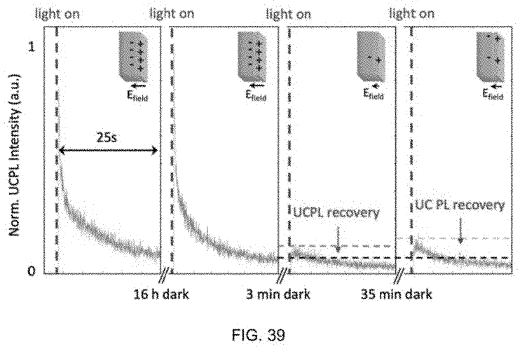

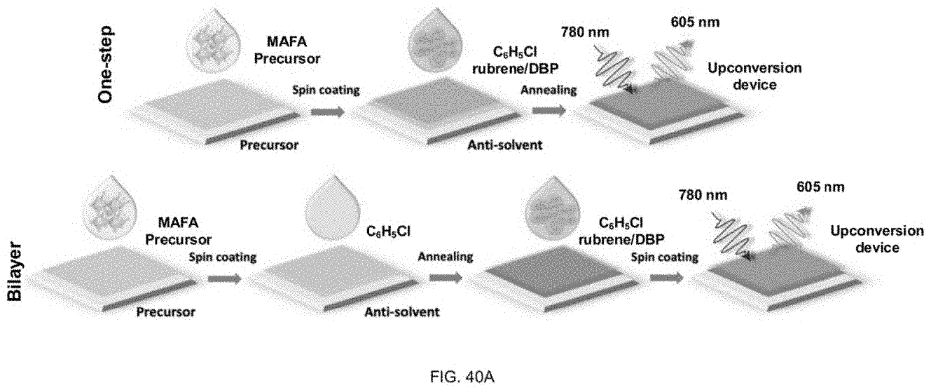

Lastly, the time-scale of the build-up of this interfacial electric field was investigated. After the first initial 25 s “on-time” of the laser (FIG. 39, left) the sample is left in the dark to recharge for 16 h. After the 16 h “off-time,” the same general trend is observed, a rapid “photobleach” of the UC PL occurs in the first few seconds under illumination (FIG. 39, middle left). To study the influence of the UC PL recovery and the corresponding buildup of the space charge region, the sample is repeatedly left in the dark. After only 3 min, a small amount of UC PL recovery is seen and after 35 min in the dark a larger amount of recovery. This indicates that the interfacial charge accumulation occurs only very slowly and requires several hours to recover.

Conclusions.

An investigation into the effect of solution-processed organic semiconductors on the PL dynamics of MAFA thin films and has found effects resulting from surface passivation and field-effect passivation. Due to the band alignment and band bending caused by interactions between the rubrene layer and the perovskite film, charge transfer can occur at the interface and induce an electric field. As a result, holes slowly transfer from the perovskite to the rubrene layer in the dark to establish equilibrium at the interface. It is proposed that the rubrene is therefore “precharged” with holes in the dark, resulting in rapid triplet sensitization upon initial illumination. A high UC PLQY is obtained at early times, which decreases as the interface reaches a new equilibrium state under illumination. The upward band-bending of the perovskite bands furthermore allow a participation of surface trap states in the triplet sensitization process and gives insight on the lack of strong TCA. Due to band bending and the resulting space charge region, holes are likely to remain localized close to the interface and are not expected to move away from the interface.

### Example 5: One-Step Fabrication of Perovskite-Based Upconversion Devices

The high diffusivity of charges in bulk perovskite films promises superior properties in comparison to QD-based systems. Additional benefits of employing bulk perovskites as triplet sensitizers include high absorption cross sections, long carrier lifetimes, strong-spin orbit coupling which scrambles the electron spin, defect tolerance and facile solution processability. Previous studies have shown that the properties of the underlying perovskite directly influence the properties of the upconverted emission, and that triplet sensitization competes with non-radiative trap filling.

Interesting effects are found in the present system including: i) rapid photobleaching of the UC emission upon initial illumination, which has been traced back to the band alignment in the system. Band bending at the rubrene-perovskite interface results in charge separation in the absence of light, which enables a high UC rate upon initial illumination. ii) Two rates of TTA are found, which have been associated with rapid TTA close to the interface and slow TTA far from the perovskite/rubrene interface. These two mechanisms show different observed UC efficiencies, defined as the fraction of absorbed photons which are converted into high energy photons, due to a varying fraction of back transfer of the singlet states created by TTA in rubrene to the perovskite sensitizer.

Interactions between the rubrene and the perovskite film result in a surface passivation effect caused by the additional solution-cast rubrene layer, reducing the negative effects of surface trap states. This effect has been attributed to a chelation-like interaction between the delocalized π-system in rubrene and the methylammonium cations. However, the exact nature of the change in the photoluminescence (PL) properties of the perovskite is difficult to trace, as the addition of rubrene enables charge transfer and thus, changes the underlying recombination dynamics. An additional effect is that the second solution processing step dissolves some of the underlying perovskite film, despite spin-coating from toluene, which has been used as an antisolvent for thin film fabrication.

In times where low cost, reproducibility and scalability are key to enabling real-world applications, a two-step fabrication technique, which may deteriorate the underlying sensitizer properties, is undesirable. To address this issue, a new device fabrication procedure was developed where the annihilator is added in situ and investigated the effect of the device fabrication procedure on the properties of the disclosed UC device.

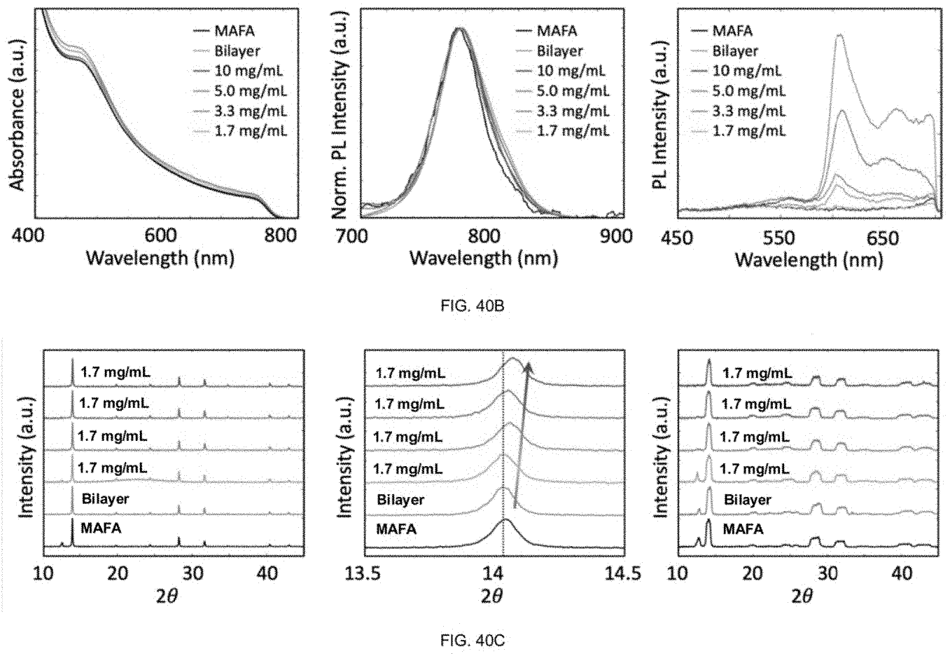

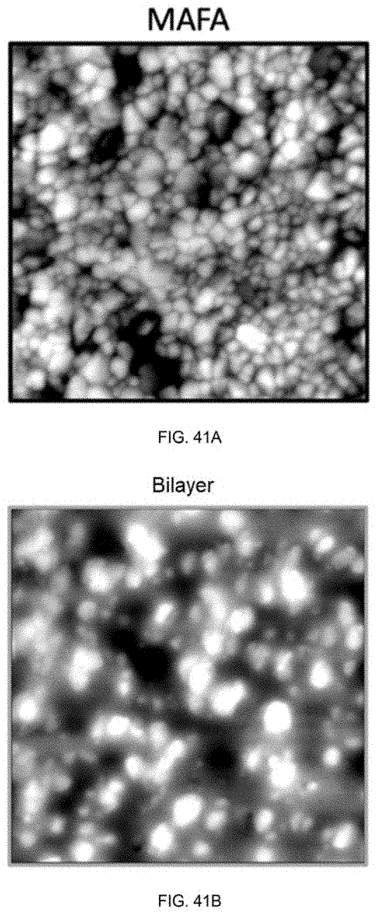

In particular, a one-step UC device fabrication procedure is introduced where the upconverter rubrene and the emitter dibenzotetraphenylperifianthene (DBP) doped at 1% into the antisolvent chlorobenzene (CB) used during the perovskite film fabrication process are directly integrated (FIG. 40A): while spin coating the perovskite precursor, the antisolvent CB containing rubrene/DBP is dropped onto the substrate. The resulting film is subsequently annealed, yielding the one-step UC device. This approach promises several advantages over previous two-step bilayer approaches: i) low-cost, easily scalable one-step fabrication. ii) No additional solution-processed steps which may dissolve or otherwise modify the underlying MAFA perovskite, and iii) the fabrication technique enables intercalation of the rubrene into the perovskite film prior to annealing, resulting in a larger interface and thus, more efficient charge extraction.

Experimental Procedures

Device Fabrication.

A 2% Hellmanex solution was used to clean the glass substrates by sonication for 15 min. Afterwards, deionized water and ethanol were used to clean the substrates by sonication for 15 min in each respective solvent. The substrates were then placed for 15 min in an UV ozone plasma cleaner (Ossila). All perovskite films were prepared by using PbI₂ (1.2 M, TCI), MAI (1.2 M, Dyenamo), and FAI (1.2 M, Dyenamo) in an overstoichiometric ratio of 1.09:1. PbI₂ was dissolved in anhydrous DMF:DMSO (9:1 v:v). To achieve a 100 nm thin film, the final perovskite precursor solution was diluted to a concentration of 0.6 M. For the bilayer architecture, the perovskite layers were spin-coated in a two-step program: 1000 rpm for 10 s and 5000 rpm for 30 s. 130 μL chlorobenzene were used as the antisolvent during the second spin-coating process. The films were annealed at 100° C. for 10 min under air-free conditions.

Bilayer.

For the upconversion layer, rubrene (99.99%) and dibenzotetraphenylperifianthene (DBP 98% HPLC) were purchased from Sigma Aldrich and used as received. A 10 mg/mL stock solution of rubrene in chlorobenzene was prepared and doped with 1% DBP. 20 μL of this stock solution were spin-coated onto the perovskite layer at 6000 rpm for 20 s. For comparison, previously published results were based on a solution of rubrene/DBP in toluene.

One-Step.

For the one-step fabrication process, the perovskite layers were spin-coated in a two-step program: at 1000 rpm for 10 s and the at 5000 rpm for 30 s. During the second part of the spin-coating program, varying rubrene concentrations in the antisolvent were used (10, 5, 3.3 and 1.7 mg/mL rubrene/DBP in 130 μL). The films were then annealed at 100° C. for 10 min under air-free conditions. All films were sealed using a 2-part epoxy (Devcon) under nitrogen.

Optical Spectroscopy.

A Shimadzu UV-2450 spectrometer was used to measure the absorption of the films. Steady state photoluminescent spectra were recorded with an OceanOptics spectrometer (HR2000+ES) under 405 nm (PicoQuant LDH-D-C-405) and 780 nm (PicoQuant LDH-D-C-780) continuous wave excitation. Excess laser scatter was removed by 425 long-pass (Chroma Tech.) and 700 short-pass filters (ThorLabs). Time-resolved photoluminescent measurements were performed using a home-built time-correlated single photon counting setup. A picosecond pulsed laser diode (PicoQuant LDH-D-C-780) was used as the excitation source at a repetition frequency of 31.25 kHz. The emission was focused onto a silicon single-photon avalanche photodiode (Micro Photon Devices SPD-100-C0C) with parabolic mirrors. A MultiHarp 150 (PicoQuant) event timer was used to record photon arrival times. A 600/40 nm (center/width) band-pass filter was used to study the upconversion dynamics and an 800 long-pass filter was used for the MAFA dynamics. To obtain power-dependent PL intensities, the emission was filtered through the 600/40 nm band-pass filters and integrated for 20 s. The 780 nm laser was used in continuous wave mode (PicoQuant LDH-D-C-780). The PL intensities over 30 s were measured in T2 mode of the MultiHarp under pulsed 780 nm excitation (31.25 kHz, 21 mW/cm with a 600/40 nm band-pass filter to selectively obtain the upconverted emission. The laser power was measured using a silicon power meter (Thorlabs PM100-D). The spot size was determined using the razor blade method.

Fluorescence Lifetime Imaging Microscopy.

Fluorescence Lifetime Imaging Microscopy (FLIM) measurements were carried out on a confocal microscope with fluorescence lifetime capability (MicroTime 200, PicoQuant, Berlin, Germany). In an inverted microscope (IX71, Olympus, Hamburg, Germany), light from a 488 and a 640 nm pulsed diode laser (LDH-D-C-485 and LDH-P-C-640B, respectively, PicoQuant) is focused on the sample by a high numerical aperture objective (UPanSApo 60×/1.2 W, Olympus). Fluorescence light is collected by the same objective and guided through a pinhole (150 μm). The light is split in two color channels by a 50:50 beamsplitter. In the yellow channel, there is a 585/65 nm (center/width) filter (Chroma, Bellows Falls, Vt., USA) and in the far-red channel, there is a long pass filter (700LP, Chroma). Photons are registered by two avalanche photodiodes (APD, SPCM-AQR-14, Perkin Elmer, Rodgau, Germany) with picosecond time resolution. Their absolute time of arrival (macrotime) and their delay with respect to the excitation pulse (microtime) are recorded by a single photon counting card (HydraHarp 400 picosecond event timer and TCSPC module, PicoQuant). Data are acquired with SymPhoTime software (PicoQuant). For the measurements, an area of 10×10 μm, divided into 50×50 pixels, was scanned with 60 ms per pixel. The sample was illuminated either with 488 nm or 640 nm light with a pulse frequency of 500 kHz; both emission channels were collected simultaneously. A neutral density filter (OD 1.3) was introduced into the far-red channel to roughly equalize the emission intensities of the two channels. The laser power was adjusted such that the detector count rate was kept below 5% of the laser pulse frequency to avoid pile-up. Typical laser powers were in the range of 0.1 μW over a diffraction limited spot (<1 mW/cm).

X-Ray Diffractometry.

Regular and grazing incidence X-ray diffraction measurements were taken using a Rigaku SmartLab X-ray diffractometer equipped with CBO-α optics and a D/teX Ultra 2 silicon strip detector. The measurements were taken using a Cu-K_{α} source (k=1.5406 Å) that was operated at 44 mA and 40 kV. For the grazing incidence, an out-of-plane incident angle of 0.5° was used. All scans were done with a step size of 0.05°, slit width of 0.5, and a scan rate of 2°/min.

Atomic Force Microscopy.

An Asylum Research MFP-3D AFM was used in tapping mode with a silicon cantilever (300 kHz, spring constant: 26 N/m) to measure the topography of the films.

Results and Discussion

Steady-State Optical Spectroscopy.

To investigate the effect of rubrene/DBP in the antisolvent on the MAFA perovskite growth, UC devices were fabricated with varying rubrene concentrations added directly to the antisolvent. A 10 mg/mL solution of rubrene in chlorobenzene was prepared and doped with 1% DBP. The following concentrations were obtained by further dilution in chlorobenzene: 5, 3.3 and 1.7 mg/mL. The results are compared with those from a device based on the previously-described two-step bilayer fabrication method (FIG. 40A). Here, during the spin-coating process of the perovskite film chlorobenzene is used as the antisolvent. After annealing of the perovskite film, 20 μL rubrene/1% DBP (10 mg/mL rubrene) in chlorobenzene is solution-cast onto the MAFA film, and spin-coated. A MAFA-only control sample is also included in the study.

As it is unknown if the perovskite can form in the same manner if the antisolvent contains additional organic components, the obtained films were first investigated by steady-state optical spectroscopy. All films exhibit the expected absorption onset at ˜800 nm indicative of the formation of MAFA which has an optical bandgap of 1.55 eV (FIG. 40B, left), as well as a similar optical density, suggesting that all films have the same thickness of optically active MAFA perovskite. Due to the strong absorption of MAFA in the region where the rubrene absorption is expected (λ=430-530 nm), it cannot be inferred how much or whether rubrene has been incorporated into the created films by absorption spectroscopy. PL spectra (FIG. 40B, middle) show the expected emission at ˜780 nm under 405 nm excitation, further confirming the formation of the disclosed perovskite composition. Investigation of the spectral region from 450-700 nm shows strong emission from rubrene/DBP for the bilayer film, and a reduction in the observed rubrene/DBP PL with decreasing concentration of rubrene/DBP in the antisolvent (FIG. 406, right). Thus, the bilayer device is expected to contain the highest amount of rubrene incorporated.

Crystallinity of the Perovskite Films.

To investigate the quality and crystallinity of the perovskite films, (grazing incidence [G]) X-ray diffraction (XRD) was used. The bulk XRD patterns in FIG. 40C (left) indicate that all films crystallize in the expected cubic crystal structure. Unsurprisingly, a feature at 2θ=12.5° is observed for the MAFA control sample, which can be attributed to the formation of unreacted lead iodide (PbI₂). For the bilayer and 10 mg/mL one-step films, no signature of PbI₂ is seen. The films created with a lower concentration of rubrene (5-1.7 mg/mL) show an increased amount of PbI₂, possibly indicating a reduced level of passivation due to less rubrene. Interestingly, a shift of all reflections to slightly higher 26 values is observed for an increasing rubrene concentration in the antisolvent (FIG. 40C, middle).

This suggests a slight contraction of the crystal structure upon the addition of increasing amounts of rubrene to the antisolvent, possibly due to compressive strain induced by the addition of rubrene. GIXRD shows a broadening of the reflections close to the surface, as expected due to the presence of inhomogeneous strain at the polycrystalline MAFA surface (FIG. 40C, right). However, no additional peaks which may correspond to crystalline rubrene are found. Therefore, it is concluded that the films fabricated by the one-step method do not have large crystalline regions of rubrene. Rather, evidence exists that rubrene can be incorporated into the perovskite film fabrication without disrupting the crystal lattice or the perovskite growth. Similarly, the bilayer film does not show a reflection corresponding to crystalline rubrene.

Surface Morphology Studies Using AFM.

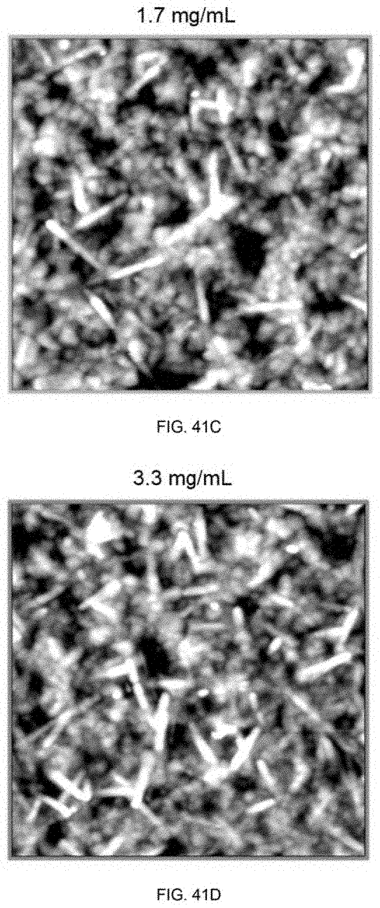

To further explore the properties of the one-step fabricated perovskite films, atomic force microscopy (AFM) was used to investigate the surface morphology. The MAFA control sample shows the expected polycrystalline film composed of small grains (FIG. 41A). As shown previously, the bilayer morphology is consistent with a soft amorphous layer of rubrene conforming to the underlying MAFA film, with larger agglomerates (FIG. 41B). In the one-step fabricated films (FIGS. 41C-F) at a low rubrene concentration of 1.7 or 3.3 mg/mL in the antisolvent the underlying MAFA grains are still clearly visible. Longer needles coat the underlying polycrystalline film, and are likely traceable to crystalline rubrene agglomerates. At even higher rubrene concentrations of 5 and 10 mg/mL, these larger agglomerates are still visible at the surface, however, the underlying polycrystallinity of the MAFA film is blurred, indicating the creation of an amorphous rubrene layer coating the surface of the MAFA film. The AFM images further confirm the previously made assumption: the bilayer device contains the largest amount of rubrene in both amorphous form and as aggregates.

Rubrene Location in One-Step Thin Films.

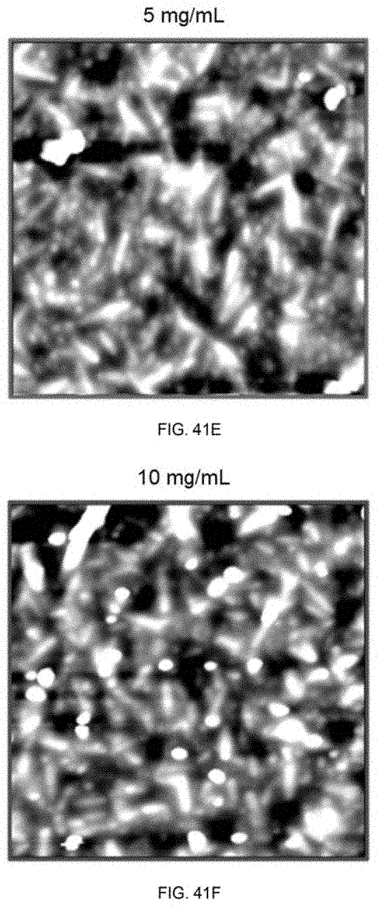

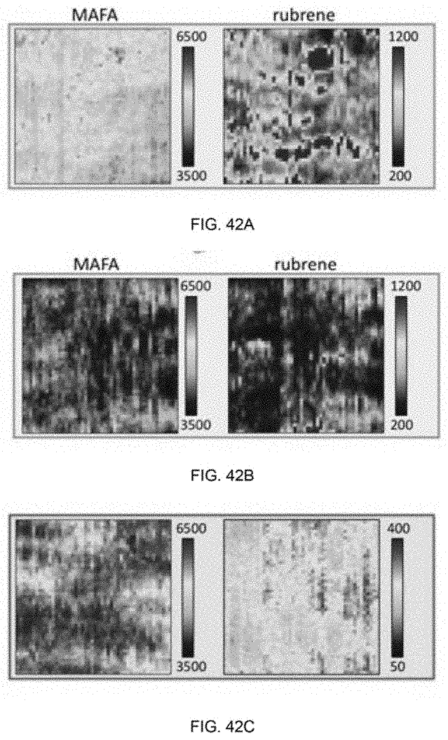

To investigate the location of rubrene in the created one-step thin films, fluorescence lifetime imaging microscopy (FLIM) was employed. Studies focused only on the 10 and 5 mg/mL samples, since the steady-state PL spectra in FIG. 40B (right) indicate the presence of a significant amount of rubrene. FIGS. 42A-B show the intensities of the near-infrared (NIR) MAFA and the visible rubrene/DBP emission of the 10 mg/mL and 5 mg/mL one-step fabricated films, respectively (λ_{exc}=488 nm). The spatially resolved MAFA emission intensity map shows the expected bright and dark regions typical of perovskite films, indicating regions with different optical properties. While the rubrene appears to generally be fairly evenly distributed, regions of high PL intensity were also found, suggesting strong rubrene/DBP emission under direct 488 nm from the needle-like structures visualized by AFM excitation. A correlation between the rubrene PL intensity and the MAFA PL intensity was observed, which further supports the expected surface passivation by the organic: areas of bright MAFA emission correlate to areas of brighter rubrene emission.

The observed rubrene PL intensity under direct 488 nm excitation is significantly higher for the 10 mg/mL film than the MAFA film fabricated with 5 mg/mL of rubrene/DBP in the antisolvent. This further confirms that the amount of rubrene incorporated into the film depends on the initial concentration. To investigate the local UC properties, the same areas were also subjected to 640 nm excitation (FIGS. 42C-D). The NIR MAFA PL under both conditions shows the same bright and dark microstructure, indicating that the emission properties are largely independent of the excitation wavelength. The rubrene channel, however, shows a different behavior. To a first approximation, one would expect to find the brightest UC in regions where the perovskite PL is quenched most, as the TTA process relies on the extraction of carriers. However, the passivating effect of the organic layer counteracts this effect and, as a result, observe bright UC was generally observed in regions where bright perovskite PL and bright rubrene signals were both found. Interestingly, a lower UC signal is generally seen in regions with large crystalline rubrene agglomerates indicating that there may be a balance between “too little” and “too much” rubrene in efficient TTA-UC, and that packing of the upconverting molecules may play an important role in the UC process.

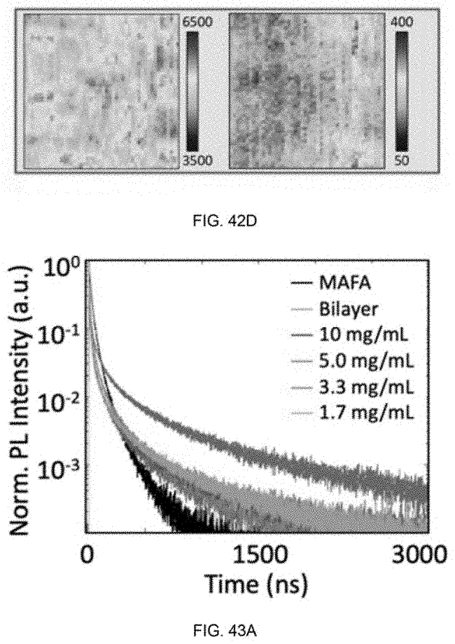

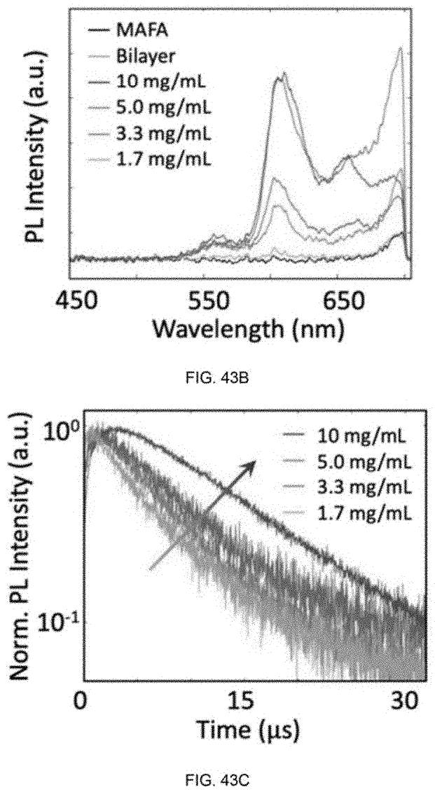

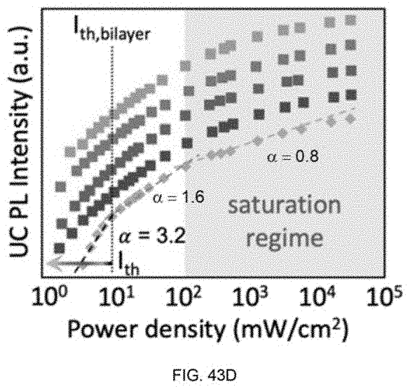

So far, it has been confirmed that the disclosed one-step fabricated devices are active in TTA-UC. In the following, the differences of their properties from a previous bilayer device structure are investigated, and in how far the device structure influences the TTA-UC properties. To gain more insight into the underlying dynamics and UC properties, time-resolved and steady-state PL spectroscopy under λ_{exc}=780 nm excitation were used. FIG. 43A highlights the MAFA PL decay dynamics for the MAFA control (black), bilayer device (gray) and the one-step fabricated films (blue). As shown previously, the addition of rubrene in the bilayer device structure results in early-time quenching due to charge transfer to rubrene. In addition, an elongation of the lifetime at later times due to a combination of both singlet back transfer and a decreased rate of recombination due to a lower carrier density was observed. The films created with rubrene in the antisolvent all show similarly quenched decays, highlighting their similar recombination dynamics and remaining carrier densities. Interestingly, the PL dynamics are quenched much more drastically than in the bilayer film, indicating a more efficient charge extraction and a lower residual carrier density.

FIG. 43B shows the steady-state UC PL spectra for the bilayer device and the respective one-step fabricated films. Clearly visible is that the intensity of the UC PL is similar for the 10 mg/mL one-step fabricated film and the bilayer structure, indicating a similar observed efficiency of the TTA-UC process for both device structures, despite their differences in the rubrene emission intensity under direct excitation (FIG. 40, middle). By decreasing the rubrene concentration in the antisolvent the UC PL intensity decreases, which is expected based on the decrease in the PL intensity obtained for direct rubrene excitation under 405 nm excitation. In general, the UC efficiency η_{UC} is defined as the fraction of absorbed low energy photons which are converted to high energy singlet states and can be calculated as:

η_{UC}=η_{TET}η_{TTA}ηₐₙₙ(1−η_{bt}), eq. 4

where η_{TET} is defined as the product of energy transfer from the sensitizer to the annihilator, η_{TTA} is the TTA efficiency, ηₐₙₙ is the annihilator quantum yield (QY) and η_{bt} is the efficiency of parasitic singlet back transfer via resonance energy transfer.

With this, the main findings this far for all one-step films can be summarized. i) All one-step films absorb the same amount of incident NIR light and are quenched to a similar extent indicating that the overall observed η_{UC} decreases with decreasing amounts of rubrene. ii) All films exhibit a similar MAFA PL lifetime, indicating a constant η_{TET}. iii) The annihilator is the same in all cases, therefore ηₐₙₙ is assumed to be constant. iv) Both η_{TTA} and η_{bt} are expected to be dependent on the UC efficiency and the annihilator concentration, and therefore on the resulting triplet population.

Upconverted PL Dynamics.

To investigate the dynamics of the UC emission, the upconverted PL dynamics (FIG. 43C) were studied. A gradual increase in the rise time was observed, as well as in the long-lived decay with increasing rubrene concentration. This indicates a change in the rate of triplet creation and annihilation, as well as the triplet lifetime based on the rubrene concentration. The dynamics of the highest concentration 10 mg/mL one-step device closely follow the previously reported dynamics for the bilayer UC device. It has previously been postulated that there are two different types of UC depending on the triplet population level: interface-mediated UC and diffusion-mediated UC far from the interface. Due to varying amounts of singlet back transfer, the latter has a higher observed QY. These two independent types of UC can be distinguished by their different PL dynamics: interface-mediated UC shows a rapid rise of the triplet population and corresponding “rapid” decay corresponding to a reduced triplet lifetime, while diffusion-mediated UC shows a slower rise of the triplet population and a longer-lived decay. Based on the steady-state PL spectra, PL mapping and AFM results, the thickness of the rubrene/DBP layer is expected to decrease with decreasing rubrene concentration in the antisolvent for the disclosed one-step fabricated UC devices. Hence, in a thinner rubrene layer, creating the same number of triplets will result in a higher triplet population, thus a rapid interface-mediated UC. On the contrary, a thicker rubrene layer enables more efficient triplet diffusion prior to TTA and results in a lower triplet population density within the layer and a higher observed UC efficiency. However, in the bilayer device which shows both the highest amount of directly excited rubrene emission and the largest amount of rubrene overall, a large number of crystalline agglomerates, which exhibit little to no observable upconverted emission, are obtained, likely due to rapid singlet fission.

Efficiency Threshold.

Lastly, the efficiency threshold Iₜₕ, which denotes the incident power at which TTA becomes the predominant triplet relaxation pathway, commonly observed as a slope change from quadratic (α=2) to linear (α=1) in the UC PL as a function of incident power, was investigated. It has previously been shown that in the case of non-geminate carrier transfer creating the triplet states, the underlying power dependency of the perovskite influences the upconverted emission directly. Rather than a slope change from quadratic-to-linear, a slope change from α=2β to α=β is observed, where β is the slope of power dependence of the underlying MAFA recombination (here: β=1.6).

The resulting UC PL intensity vs. incident power curves in FIG. 43D are offset for clarity, therefore, the y-axis values do not reflect absolute intensities. I_{th,bilayer}=10 mW/cm² is obtained, while the one-step fabricated devices exhibit a lower Iₜₕ value. As the rubrene concentration is decreased, the Iₜₕ value continuously shifts to lower incident power densities, and becomes undetectable within the background noise. This can be attributed to the fact that the same number of interfacial triplets are generated in a smaller volume of rubrene, thus enabling a high enough triplet density at very low power to enable efficient TTA. However, due the observed reduced UC efficiency resulting from strong singlet back transfer in thinner rubrene films, there is a clear trade-off between the Iₜₕ value and the observed UC intensity. Counterintuitively, a higher observed UC PL intensity is obtained in the films created with a higher rubrene concentration, yet find a higher Iₜₕ value. Therefore, care must be taken to not directly correlate the Iₜₕ with the resulting brightness of the device.

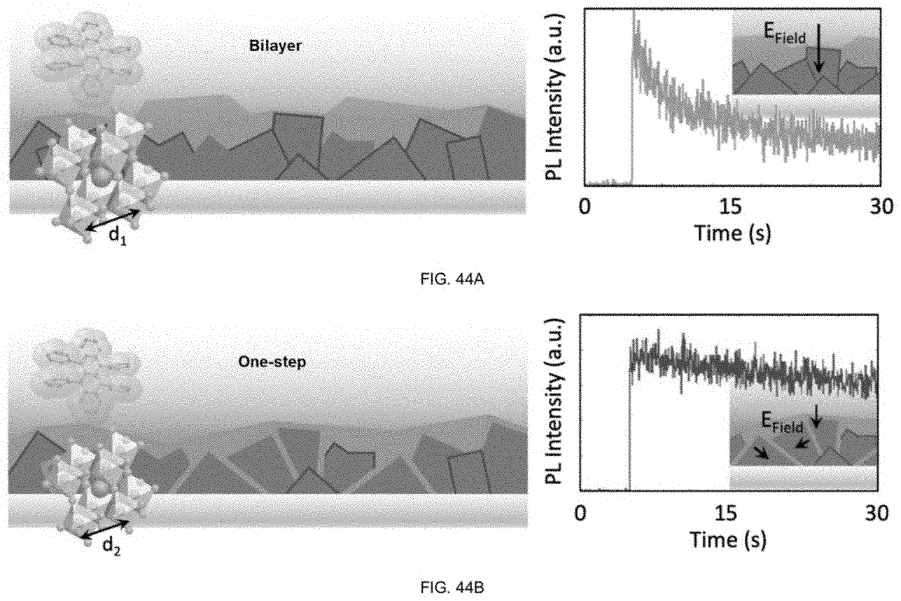

Combining the XRD, AFM and optical spectroscopy results, it is proposed that adding rubrene/DBP to the antisolvent creates a larger interfacial area between the perovskite and the organic layer, as the organic coats each individual grain on multiple sides (FIG. 44A). As a result, more carriers can be extracted, resulting in a high triplet population in the organic layer enabling efficient TTA at low incident powers.

This is further supported by the intensity traces shown in FIG. 44B for the bilayer device and the one-step fabricated device (10 mg/mL), respectively. The initial spike of the UC PL was previously attributed to a “precharging” effect stemming from an inherent built-in electric field. Due to the orientation of the interfaces, the magnitude of the built-in electric field is minimized (Inset FIGS. 44A-B), reducing the initial spiking of the UC PL intensity. A higher surface area furthermore allows for the carriers to be extracted more efficiently, as indicated by the high steady-state UC intensity and the increased quenching of the PL lifetimes as seen in FIG. 43A.

### Example 6: Optimization of Stoichiometry, Composition, Solvent, and Temperature

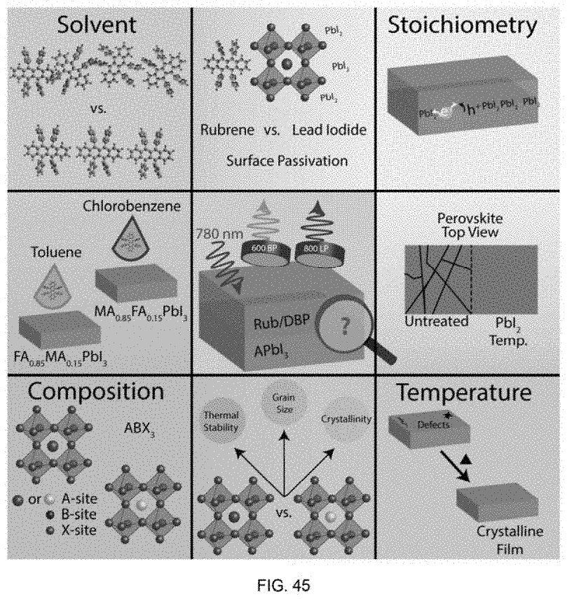

Our OIHP-sensitized TTA-UC system is comprised of a spin-coated rubrene annihilator layer doped with ˜1% DBP on top of a spin-coated perovskite sensitizer layer which allows for facile and inexpensive UC device fabrication. However, this all-solution processed device architecture still bears many challenges in terms of the ‘right’ processing conditions for the single layers as well as the ensemble performance optimization of the whole UC device. FIG. 45 is a summary of synthesis conditions having at least some importance to the properties of UC devices.

We fabricate perovskite sensitizer layers based on different compositions and surface passivation. In particular, MA_{0.85}FA_{0.15}PbI₃ films are made with and without an excess of PbI₂ to study the influence of surface passivation which are labeled as overstoichiometric (O) and stoichiometric (S), respectively. Here, the excess amount of PbI₂ was controlled by using a constant ratio of PbI₂ and the organic cations. To investigate the effect of the perovskite film composition, we fabricate overstoichiometric formamidinium-rich FA_{0.85}MA_{0.15}PbI₃ (FO) films. Our experience indicates that stoichiometric FA_{0.85}MA_{0.15}PbI₃ films are difficult to fabricate and exhibit sub-par properties, therefore we exclude this stoichiometry.

We have previously shown that the second spin-coating step for the organic upconverting layer based on rubrene/DBP can impact the underlying perovskite film by inducing surface trap states, which is counteracted by a passivating effect from the rubrene molecules. Our initial fabrication technique for the rubrene/DBP layer was based on the solvent toluene. However, we use chlorobenzene (CB) as the antisolvent to fabricate the perovskite films, therefore investigating the effect of a varying solvent is critical in understanding the effect on the perovskite/OSC interface. To study the effect of the solvent, we spin-coat the rub/DBP annihilator layer dissolved in different solvents onto the perovskite film, namely toluene (tol) and CB.

Lastly, we investigate the influence of post-fabrication annealing on the device performance. As mentioned earlier, the second spin-coating step can induce surface trap states in the perovskite film by dissolution of the top layer. Hence, an additional annealing step is expected to ‘heal’ the partially dissolved perovskite interface by self-passivation. Further, it is possible that a heat treatment can influence the packing of the OSC layer on a molecular level, and therefore change triplet diffusion or TTA. Here, a subset of the fabricated films and bilayer UC devices are subjected to an additional annealing step at 100° C. for 10 min.

Experimental Procedures

Device Fabrication.

A 2% Hellmanex solution was used to clean the glass substrates by sonication for 15 min. Afterwards, deionized water and ethanol were used to clean the substrates by sonication for 15 min in the respective solvent. The substrates were then placed for 15 min in an UV ozone plasma cleaner (Ossila). All perovskite films were prepared by using PbI₂ (1.2 M, 99.99% TCI) and MAI (1.2 M, Dyenamo) in a 1.09:1 or 1:1 ratio. Similar, PbI₂ (1.2 M, 99.99% TCI) and FAI (1.2 M, Dyenamo) were used in a 1.09:1 or 1:1 ratio. PbI₂ was dissolved in anhydrous DMF:DMSO (9:1 v:v). For the overstoichiometric (0, FO) and stoichiometric (S) samples, the obtained methylammonium- and formamidinium-based stock solutions were mixed in a ratio of 5:1 for the 1.09:1 and 1:1 stock solution ratios, respectively. For the formamidinium-rich (FO) perovskite, the above mentioned 1.09:1 stock solutions for the methylammonium- and formamidinium-based solutions were mixed in a ratio of 1:5. The perovskite layers were then spin-coated in a two-step program: 1000 rpm for 10 s and 4000 rpm for 30 s. Chlorobenzene was used as antisolvent during the second spin-coating process. The O and S films were annealed at 100° C. for 10 min, the formamidinium-based perovskites were annealed at 110° C. for 20 min under air-free conditions.

Rubrene (99.99%) and dibenzotetraphenylperiflanthene (DBP 98% HPLC) were purchased from Sigma Aldrich and used as received. Two different solutions were prepared. Rubrene was either dissolved in anhydrous toluene (Sigma Aldrich) or anhydrous chlorobenzene (Sigma Aldrich) at a concentration of 10 mg/mL. DBP was also dispersed in anhydrous toluene or anhydrous chlorobenzene at a concentration of 10 mg/mL. For the final solutions, rubrene in toluene was doped with 1.1% of DBP in toluene; rubrene in chlorobenzene was doped with 1.1% DBP in chlorobenzene. 20 μL were then spin-coated onto the perovskite films at 6000 rpm for 20 s. For the post-fabrication annealed samples (T), the bilayers were annealed for 10 min at 100° C.

To study the influence of the pure solvent, we only spin-coated 20 μL of toluene or chlorobenzene on the perovskite layer. The films were then sealed using a 2-part epoxy (Devcon) under nitrogen.

Optical Characterization.

A UV-vis spectrometer (Shimadzu UV-2450) was used to measure the absorption properties of all films. An OceanOptics spectrometer (HR2000+ES) under continuous wave excitation was used to measure steady-state PL spectra. To measure the influence of the different process conditions on the perovskite layer, we used a 780 nm (PicoQuant LDH-D-C-780) laser diode and an 800 nm long pass filter (Thorabs). To measure the upconverted steady-state behavior, we used 780 nm excitation and recorded the upconverted PL using a 600±40 nm bandpass filter (Thorlabs).

Time-resolved PL lifetimes were measured by time-correlated single-photon counting (TCSPC). A single photon avalanche photodiode (Micro Photon Devices) and a HydraHarp 400 (PicoQuant) was used to measure the photon arrival times using reflective optics. Perovskite lifetimes were measured with a 780 nm picosecond pulsed laser diode and an 800 long pass filter at a repetition rate of 31.25 kHz with 512 μs resolution. A silicon power meter (Thorlabs PM100-D) was used to measure the power of the incident laser beam.

Results and Discussion

Optical Characterization of Films.

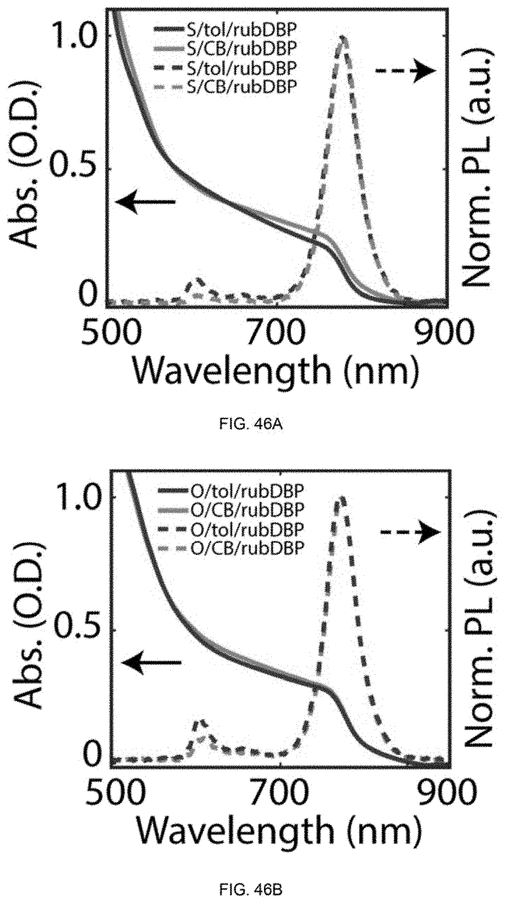

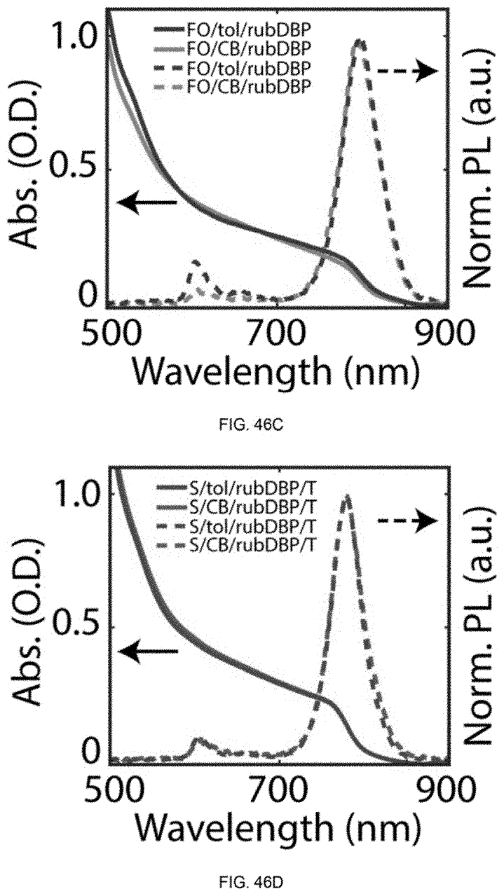

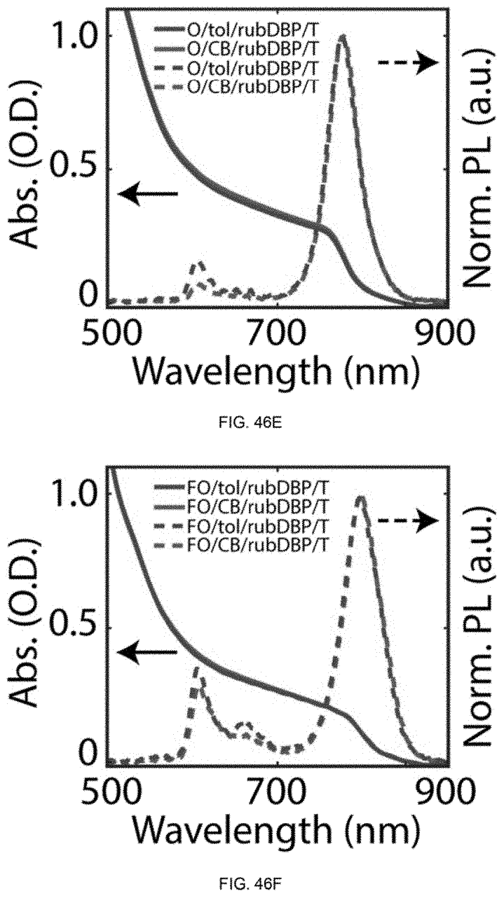

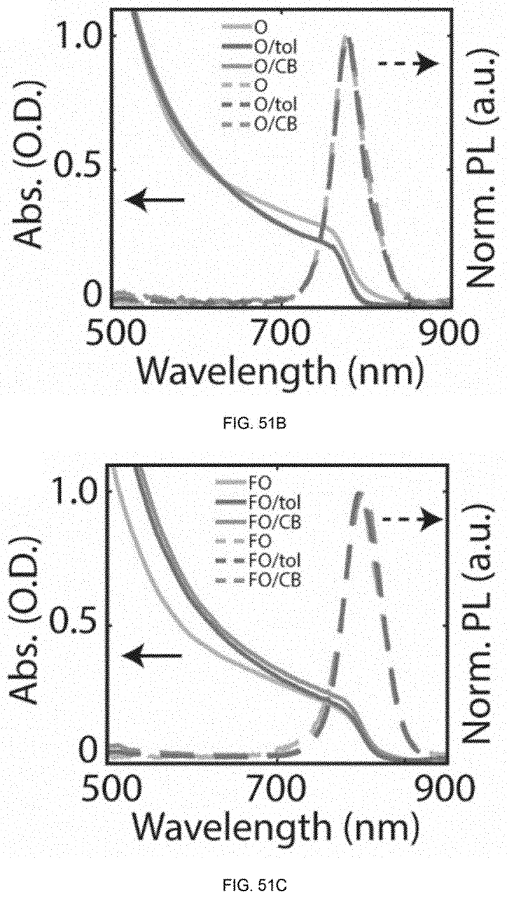

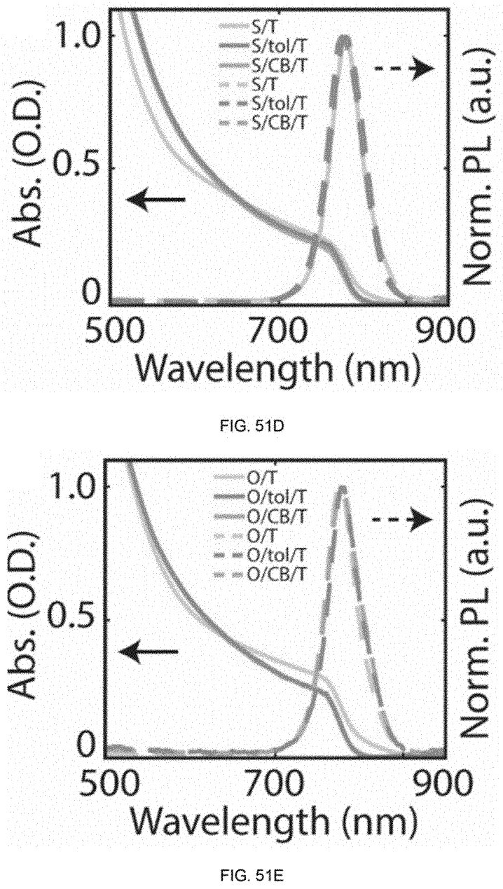

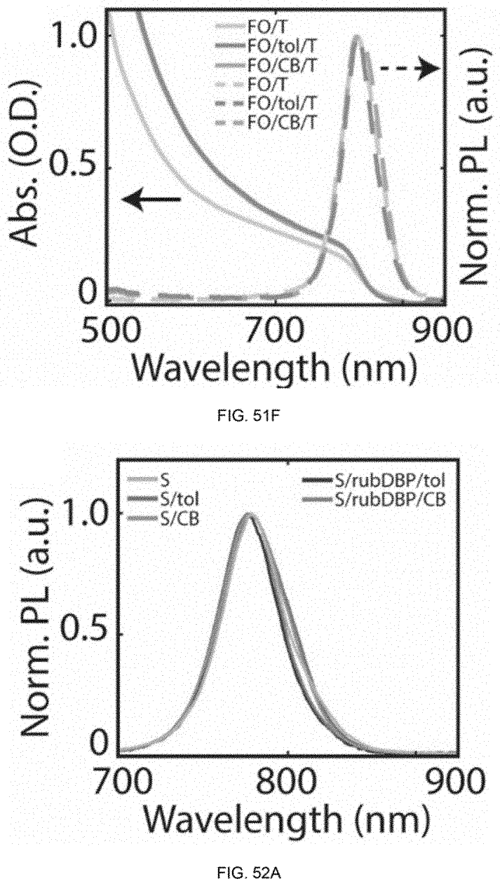

FIGS. 46A-46C show the optical characterization of the S, O and FO bilayer films under the different investigated fabrication conditions by means of absorption and steady-state PL spectroscopy. The investigated samples are named the following: S, O and FO represent the perovskite films, also referred to as ‘X’ throughout the manuscript, the fabricated bilayer devices with rub/DBP in toluene (X/tol/rubDBP) and rub/DBP in CB (X/CB/rubDBP), as well as the corresponding post-fabrication annealed bilayers: X/tol/rubDBP/T, X/CB/rubDBP/T (X=S, O, FO). The corresponding S, O, FO perovskite films and their heat-treated counterparts are labeled: X/T. The following control samples are also fabricated: O and S films with only tol or CB on top of the perovskite layer labeled as X/tol and X/CB (compare FIGS. 51A-51F, Table 7), and the corresponding heat-treated controls X/tol/T and X/CB/T.

TABLE 7
PL peak position, band gap, and PL decay lifetime, τ (1/e) for the perovskite-only control films

| | T | | | tol | | | CB | |
|---|---|---|---|---|---|---|---|---|
| | S | O | FO | S | O | FO | S | O |
| PL peak | 779 | 778 | 799 | 777 | 777 | 798 | 778 | 777 |
| position | | | | | | | | |
| (nm) | | | | | | | | |
| Band | 1.6 | 1.6 | 1.6 | 1.6 | 1.6 | 1.6 | 1.6 | 1.6 |
| gap | | | | | | | | |
| (eV) | | | | | | | | |
| τ (1/e) | 27.5 | 35.8 | 44 | 14.8 | 8.7 | 92.7 | 11.3 | 27.1 |
| (ns) | | | | | | | | |
| | | CB | tol/T | | | CB/T | | |
| | | FO | S | O | FO | S | O | FO |
| | PL peak | 801 | 775 | 780 | 796 | 780 | 777 | 800 |
| | position | | | | | | | |
| | (nm) | | | | | | | |
| | Band | 1.6 | 1.6 | 1.6 | 1.6 | 1.6 | 1.6 | 1.6 |
| | gap | | | | | | | |
| | (eV) | | | | | | | |
| | τ (1/e) | 85 | 25.1 | 10.2 | 81.9 | 40.4 | 14.8 | 79.4 |
| | (ns) | | | | | | | |

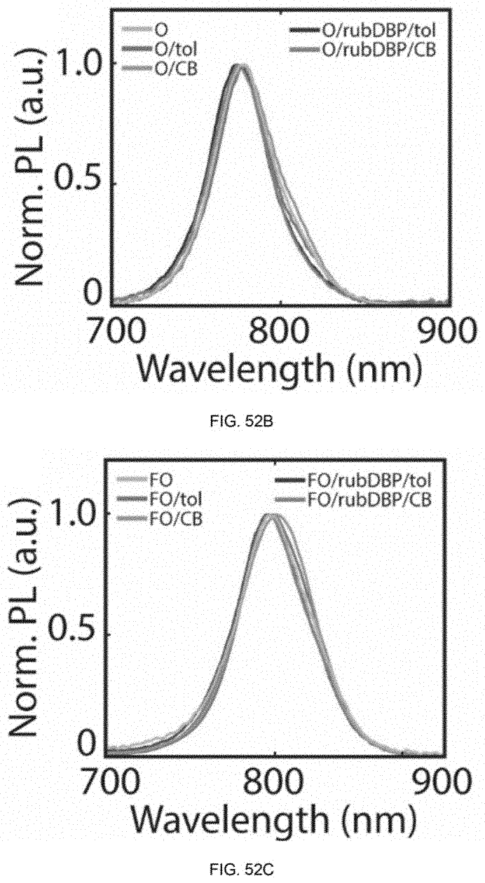

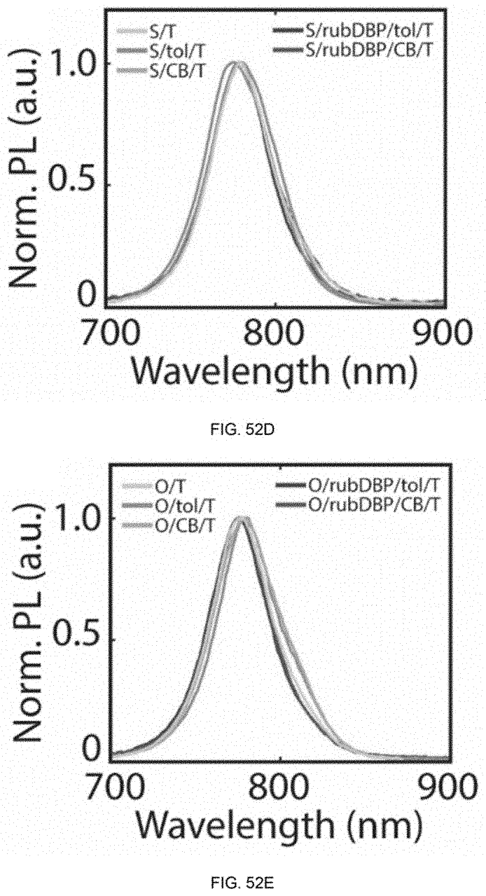

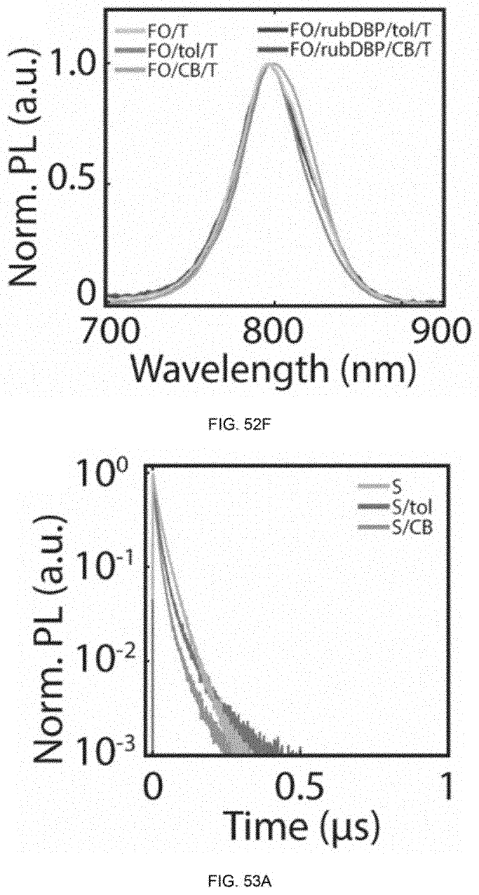

All samples show the expected strong absorption onset near 800 nm. The overall absorbance of the FO samples is slightly lower than that of the S and O films, indicating a thinner perovskite film. The photoluminescence (PL) properties show that the perovskite PL peak is centered at 778 nm for the S films and at 775 nm for O bilayer films, while the FO emission is red-shifted at 796 nm, in line with reports in literature. As observed previously, the overstoichiometric (O, FO) perovskite PL slightly blue-shifts by the addition of the organic OSC layer (rub/DBP) by approx. 2-3 nm which can be explained by a shift in the underlying perovskite composition (compare FIGS. 52A-52F, Table 6).

Absorption spectra and steady state spectra of the temperature-treated bilayer films are shown in FIGS. 46A-46C and 46D-46F, respectively. Interestingly, upon post-fabrication annealing, there is no discemable difference in the peak PL position, indicating that annealing recovers the intrinsic properties. The OSC emission is found at the expected wavelength for DBP emission: ˜605 nm for all devices. Overall, we find no discemable change in the steady-state optical properties of the perovskite layer, indicating that neither the solvent treatment, nor the second annealing step influences the absorbance onset, the film thickness or the PL peak position.

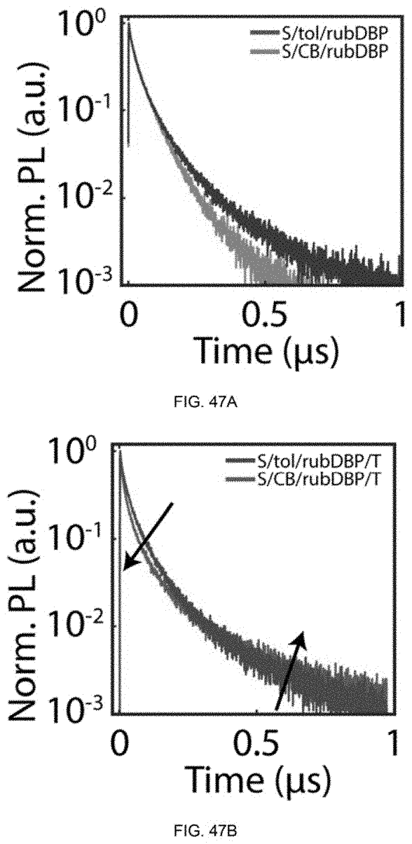

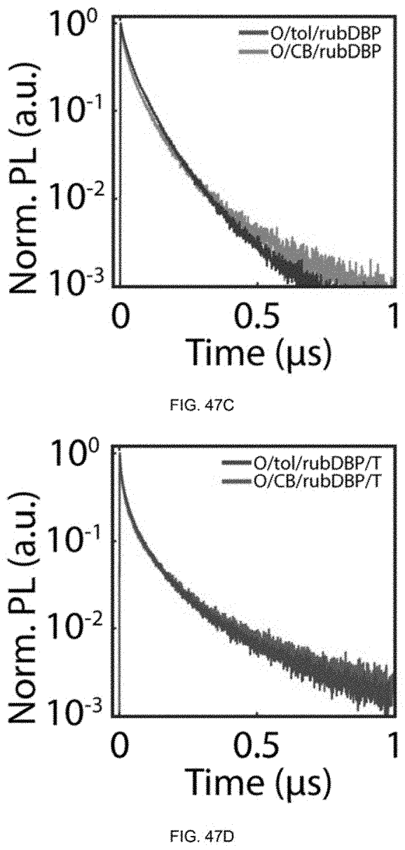

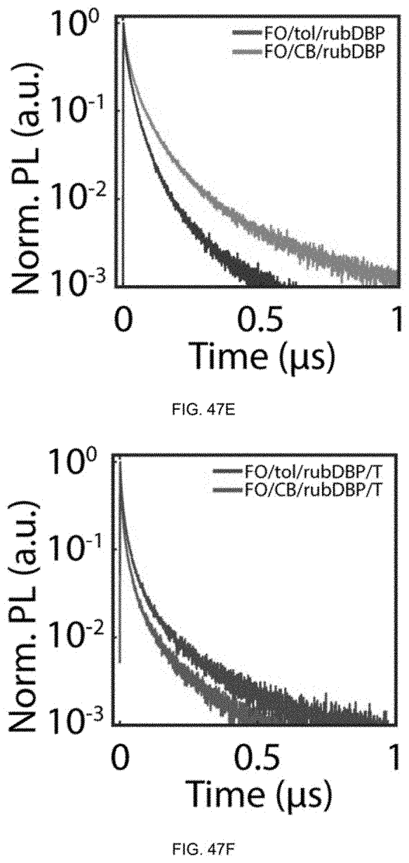

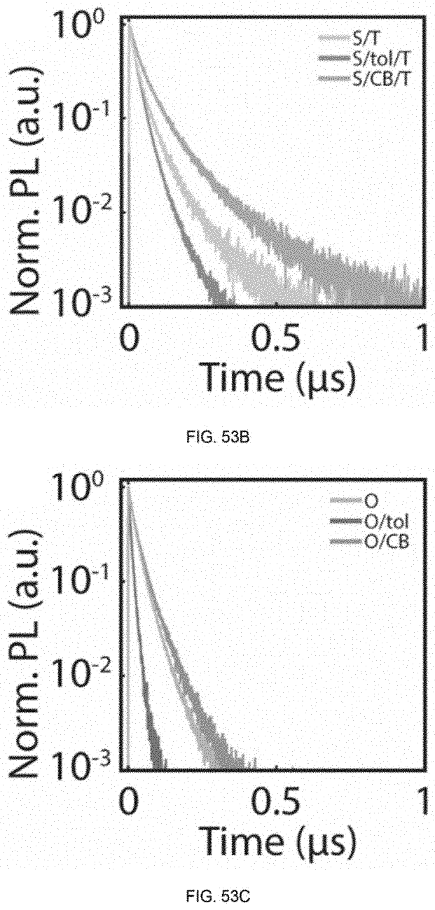

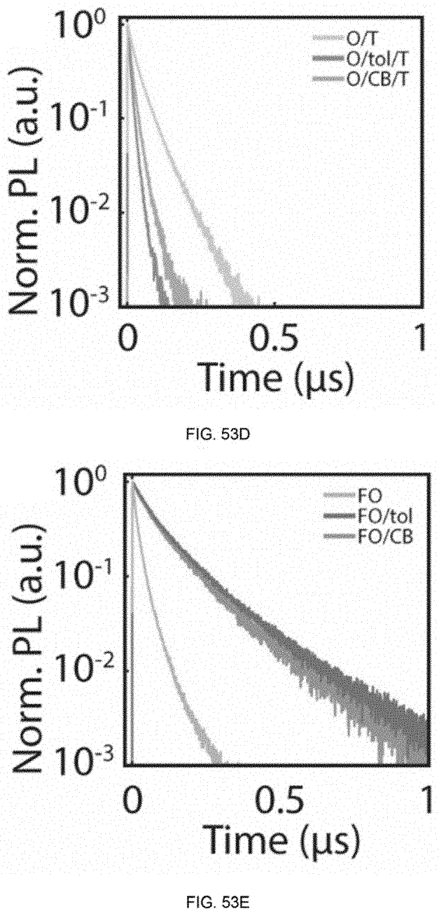

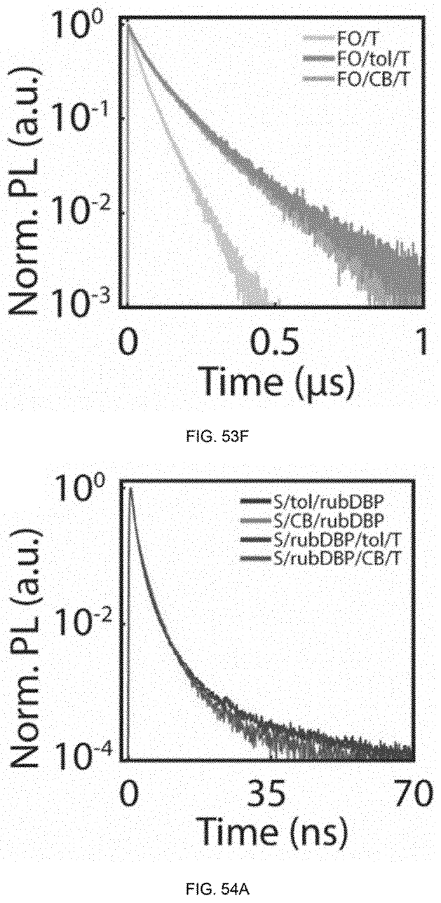

To further investigate the charge transfer from the perovskite layer to the OSC required in the desired UC process, we turn to time-resolved PL spectroscopy. Triplet sensitization occurs via electron and hole transfer from the perovskite to the rubrene, and manifests in a reduced perovskite lifetime of the bilayer films in comparison to the perovskite-only films (compare FIGS. 53A-53F). We have previously shown that a long-lived tail emerges upon the addition of the OSC, which can be explained both by a lower remaining carrier density in the perovskite and singlet back-transfer from the OSC layer. The X/tol/rubDBP and X/CB/rubDBP (X=S, O, FO) perovskite lifetimes show this expected behavior where a short decay is followed by a long-lived tail (FIGS. 47A-47F). We observe an increase in the early-time quenching for the FO-rich perovskite, indicating a higher level of charge extraction upon a compositional change from MA-rich to FA-rich.

Interestingly, the annealed samples X/tol/rubDBP/T and X/CB/rubDBP/T show a stronger initial decay than their as-fabricated counterparts, and a more pronounced long-lived tail as indicated by the black arrows in FIG. 47B. To first approximation, this hints at more quenching at early times, meaning more charges are being extracted at the interface. Thus, a higher UC yield would be expected. Furthermore, this is a clear indication that the interface between the perovskite and the OSC is crucial for charge extraction. We suggest that the additional annealing step after the OSC deposition reanneals the uppermost perovskite layer, which otherwise could potentially act as a tunneling barrier, similar to the effect of passivating ligands on quantum dots or as a surface trap.

Time-Resolved PL Spectroscopy.

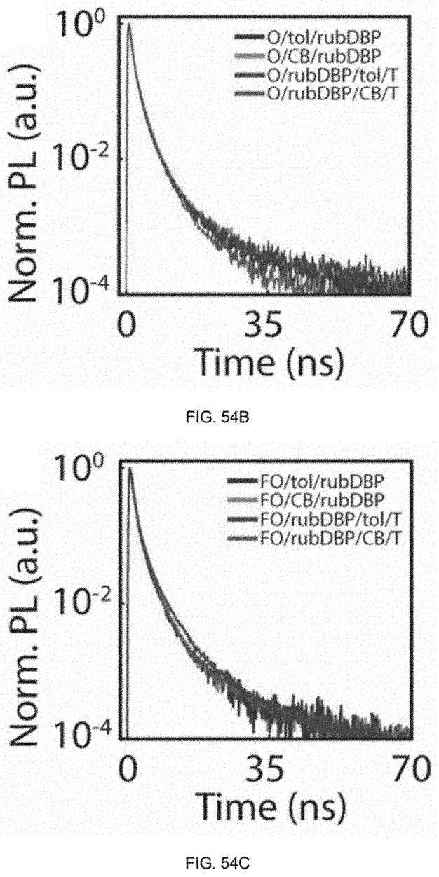

To further confirm that the OSC is not negatively impacted by the additional annealing step, we perform time-resolved PL spectroscopy (compare FIGS. 54A-54C), which shows identical decay dynamics for all fabrication conditions under direct 405 nm excitation. The steady-state and time-resolved optical properties of the fabricated perovskite films and UC devices are summarized in Table 6.

TABLE 6
PL Peak Position, Band Gap, and PL Decay Lifetime, τ (1/e) for All Investigated
Film Compositions and UC Bilayer Devices Fabricated under Different Processing Conditions

| | | | | tol/rubDBP | | | CB/rubDBP | |
|---|---|---|---|---|---|---|---|---|
| | S | O | FO | S | O | FO | S | O |
| PL peak | 779 | 777 | 797 | 777 | 774 | 798 | 778 | 775 |
| position | | | | | | | | |
| (nm) | | | | | | | | |
| Band | 1.6 | 1.6 | 1.6 | 1.6 | 1.6 | 1.6 | 1.6 | 1.6 |
| gap (eV) | | | | | | | | |
| τ (1/e) | 23.7 | 16.6 | 15.9 | 27.5 | 37.1 | 15.4 | 29.4 | 29 |
| (ns) | | | | | | | | |
| | | CB/ | | | | | | |
| | | rubDBP | tol/rubDBP/T | | | CB/rubDBP/T | | |
| | PL peak | FO | S | O | FO | S | O | FO |
| | position | 794 | 779 | 775 | 796 | 779 | 778 | 795 |
| | (nm) | | | | | | | |
| | Band | | | | | | | |
| | gap (eV) | 1.6 | 1.6 | 1.6 | 1.6 | 1.6 | 1.6 | 1.6 |
| | τ (1/e) | | | | | | | |
| | (ns) | 20.1 | 23.7 | 17.3 | 8.3 | 15.4 | 14.3 | 5.1 |

Upconverted Emission Under 780 nm CW Excitation.

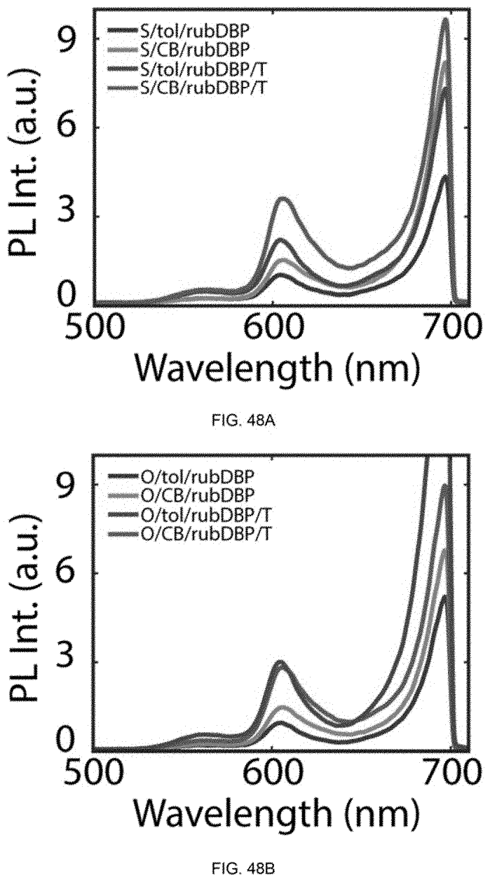

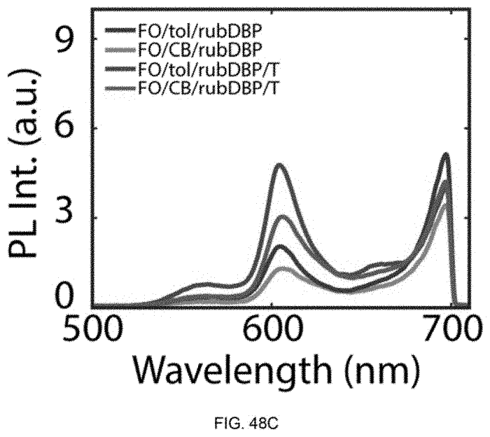

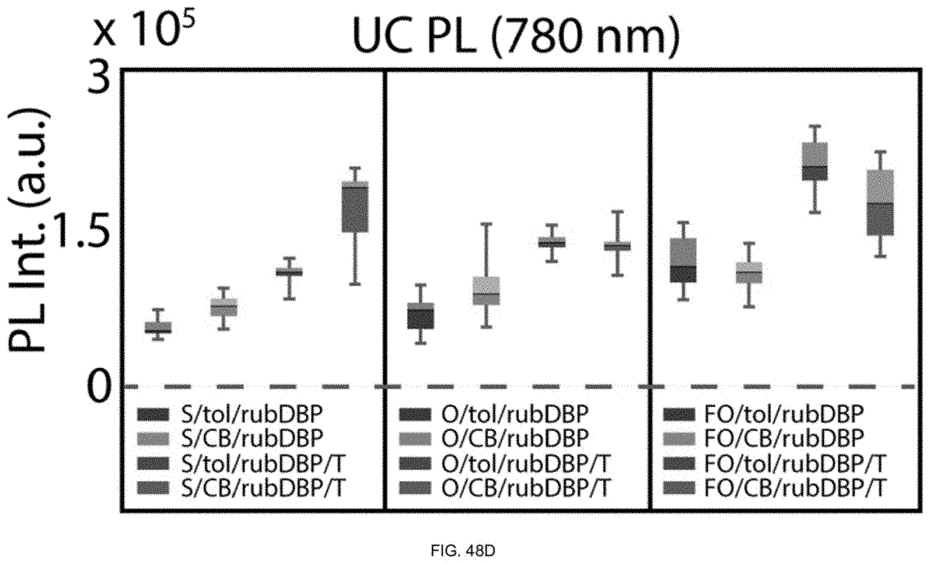

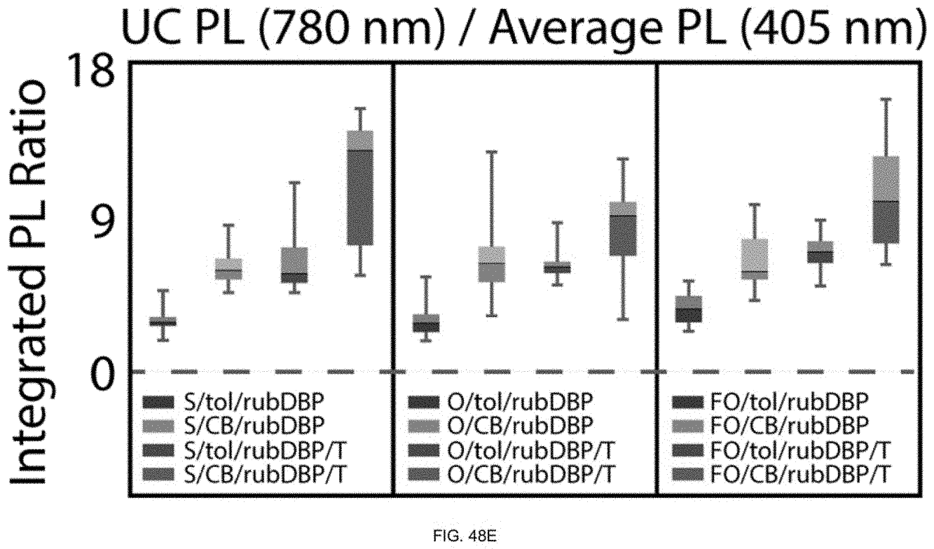

To unravel whether the increased rate of early-time quenching in the perovskite decay dynamics observed in FIGS. 47A-47F under post-fabrication annealing results in an increase in the triplet population and therefore an increased upconverted emission, we first investigate the upconverted emission obtained under 780 nm continuous-wave (CW) excitation. FIGS. 48A-48C highlight representative steady-state UC PL spectra under 780 nm excitation at 45.2 W/m². Clearly observed is the residual rubrene emission at 560 nm, the DBP emission at 605 nm, and the blue tail of the perovskite emission. The UC PL spectra were taken at 30 spots across the individual devices and integrated from 500-700 nm to obtain the box plots in FIGS. 48D-48E. As shown in FIGS. 48A-48C, the onset of the blue side of the perovskite emission occurs <700 nm. Therefore, the emission is integrated from 500-650 nm, and normalized by the emission under direct 405 nm excitation. A general trend can be observed: the UC PL intensity stemming from annealed devices is higher than the UC obtained in the devices without an additional annealing step. This further supports the hypothesis made earlier annealing improves the charge extraction at the perovskite/OSC interface. Further, the MA-rich perovskites (S, O) perform similar and show a higher UC emission intensity when CB is used as the solvent for the OSC. In contrast, FA-rich perovskite-based devices (FO) exhibit brighter emission when toluene is used as the solvent for the OSC. This indicates that MA and FA likely have different susceptibilities to the different solvents. Moreover, the FA-rich bilayers show an overall higher UC emission intensity than the MA-rich perovskite-based bilayers, in line with the increased quenching of the PL observed.

The UC efficiency η_{UC} (eq. 5) can generally be defined as the triplet energy transfer efficiency from the perovskite to rubrene η_{TET} and the TTA efficiency η+TTA. We neglect to include the efficiency of intersystem crossing (ISC), as our triplet sensitization mechanisms involves transfer of rapidly spin-mixing free carriers, and therefore is independent of ISC. The UC efficiency is often normalized by the annihilator QY ηₐₙₙ to remove any effects of the underlying OSC.

η_{UC}=η_{TET}η_{TTA}ηₐₙₙ. (5)

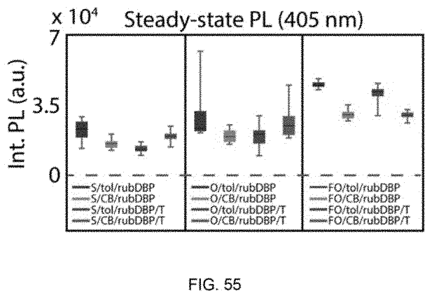

In FIG. 48E we show a box plot of the UC PL intensity normalized by the OSC PL intensity obtained under direct 405 nm excitation (compare FIG. 55), which shows the general trend that the OSC PL of bilayer films fabricated from toluene is brighter than the corresponding ones made with CB. Interestingly, we see that with this normalization, all treatments yield the same trend: the ratio of the UC PL and the emission under direct 405 nm excitation is higher for X/CB/rubDBP than for the X/tol/rubDBP UC devices and the corresponding annealed bilayers further outperform their unannealed counterparts, respectively.

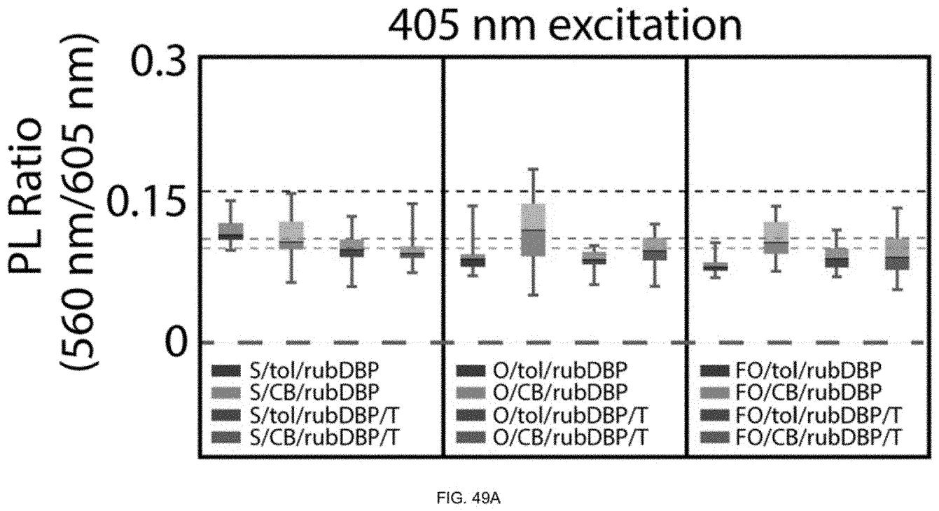

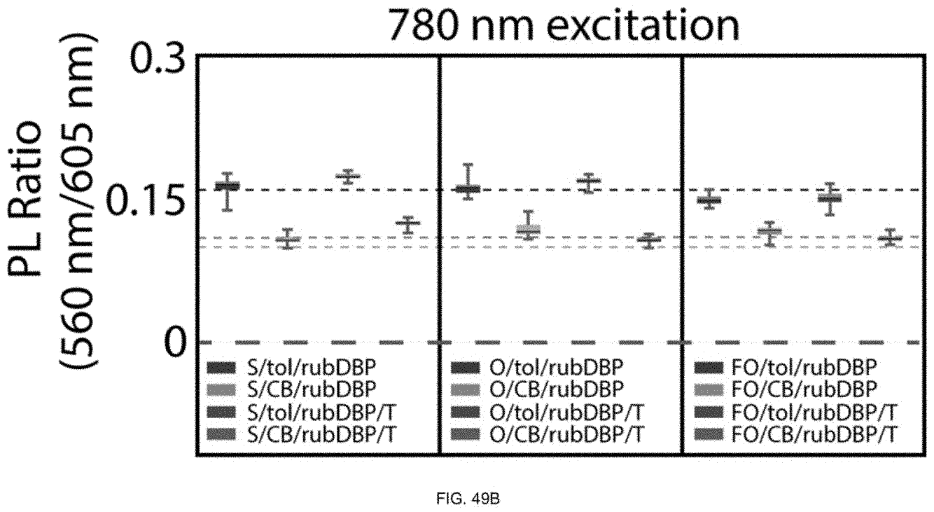

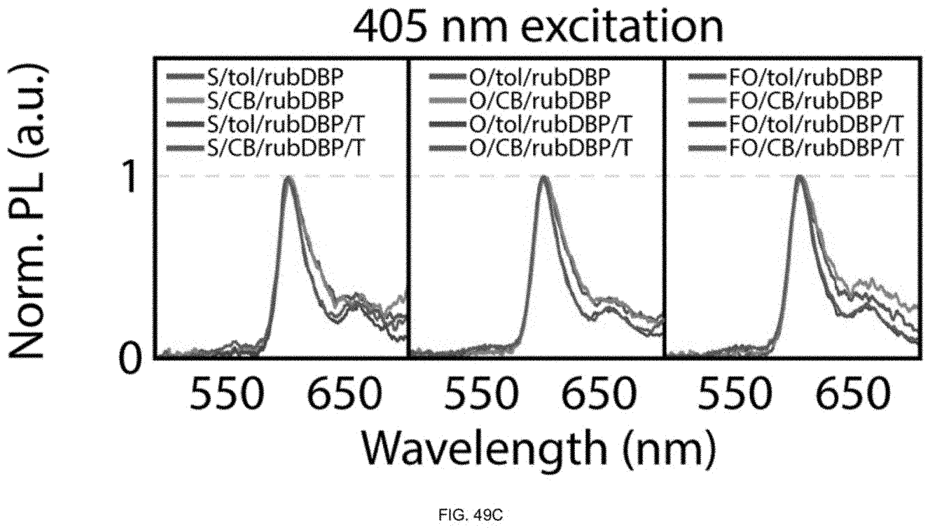

We have previously observed that the sub-population emitting following UC is a different one compared to the one which emits under direct excitation for bilayer devices fabricated using toluene as the solvent for the OSC. This conclusion is based on differences in the ratio of the residual rubrene peak emission at 560 nm and the DBP peak emission at 605 nm, indicating changes in the Förster resonance energy transfer (FRET) efficiency. As FRET is not sensitive to the process creating the singlet state, the FRET efficiency should not be dependent on whether the emission stems from direct excitation or UC. FIG. 49A highlights the ratio of the intensities at 560 nm and 605 nm under direct 405 nm excitation. Within error, this ratio is constant at 0.1±0.01, indicating fairly efficient FRET between rubrene and the dopant DBP. In FIG. 49B, we investigate the ratio of the residual rubrene PL and the DBP PL in the UC PL spectra under 780 nm excitation to study the influence of the solvent on the FRET efficiency and sub-population undergoing emission. For the CB-based devices, we find a similar average ratio of ˜0.11, while for the toluene-based UC devices a higher ratio of ˜0.16 is found. An increase in the ratio of rubrene vs. DBP peak emission indicates that less FRET is occurring, rather rubrene is emitting directly.

Again, this confirms that a different sub-population is emitting directly vs. in the UC PL for bilayer devices fabricated from toluene. However, for the CB-based OSC layer, the shape of the PL spectra, or ratio of emission at 560 nm and 605 nm is more comparable under 405 and 780 nm excitation. These differences in the resulting emission ratios indicate that the solvent is a vital ingredient in the performance and properties of the resulting OSC layer, as this can only be explained by a variation in the packing of the rubrene/DBP molecules. This assumption is further supported by changes in the shape of the obtained OSC emission spectrum (FIG. 49C): the emission spectrum of the OSC layer spin-coated from toluene shows the previously observed shape of isolated DBP molecules. On the other hand, the emission spectrum from the CB-based OSC layer shows broadened features and an increase of the intensity of the second vibronic feature at 657 nm, which is indicative of a different local environment of the DBP molecules.

Power Dependency of the UC PL

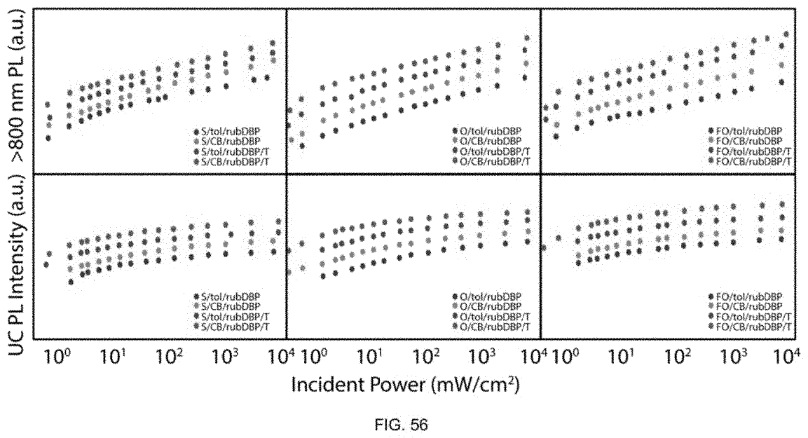

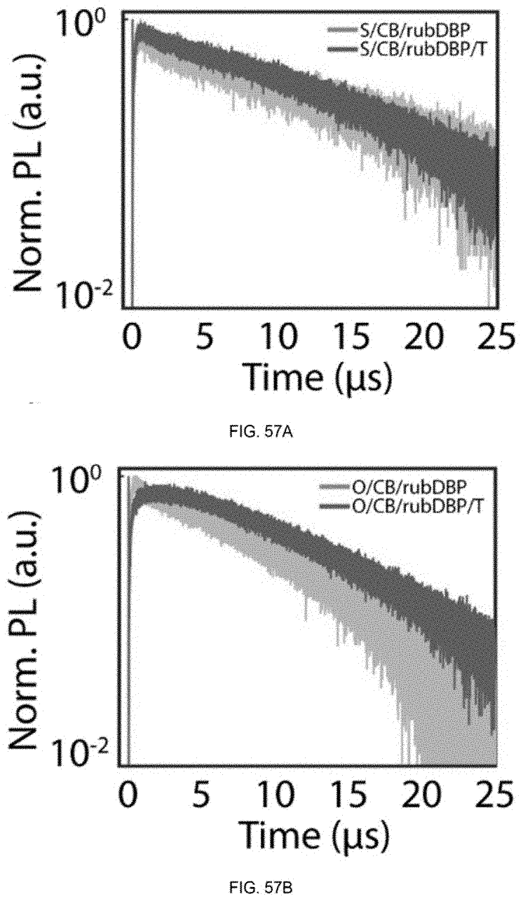

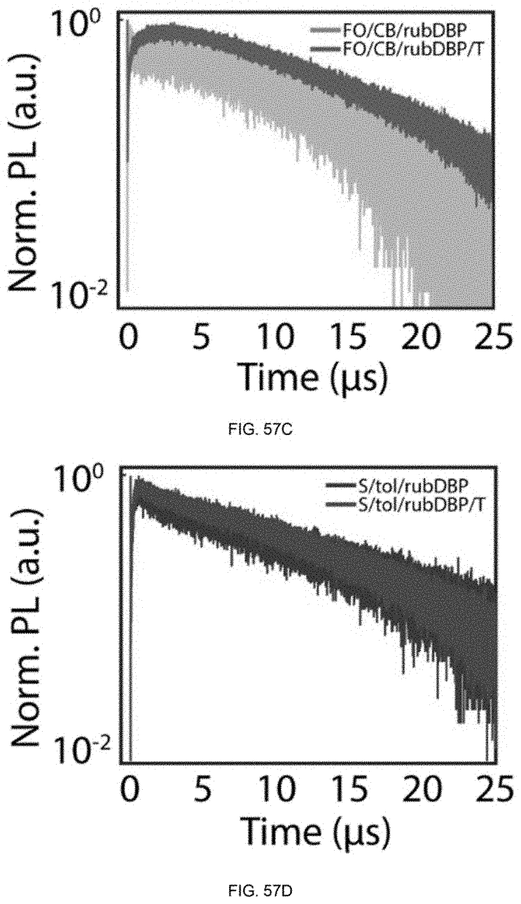

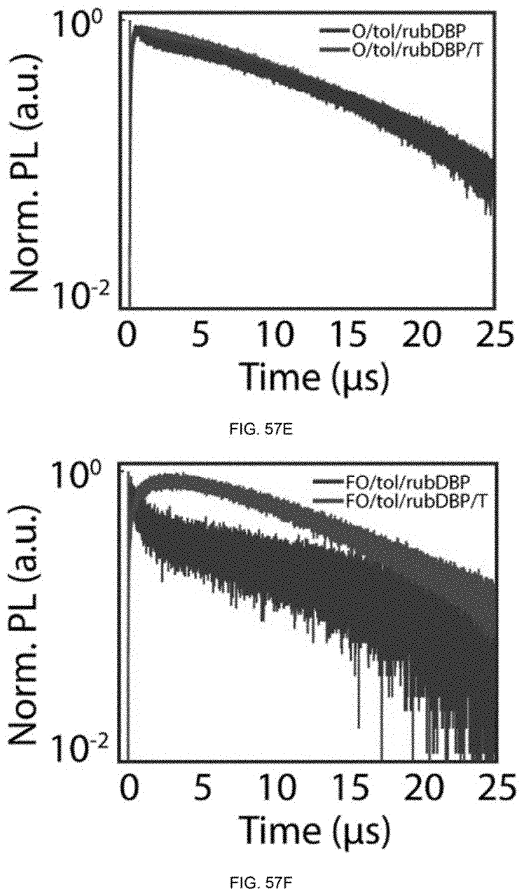

To further unravel the underlying causes for the roughly three-fold increase in the UC PL intensity after thermal annealing, we turn to the power dependency of the UC PL, which yield the intensity threshold Iₜₕ of efficient UC. The Iₜₕ is found at the change-over between inefficient TTA and efficient TTA, which manifests as a slope change from for the relationship between the UC PL and the incident power from quadratic to linear. We have previously shown that this relationship is further influenced by the underlying perovskite PL power dependency which exhibits a slope 1<β<2 due to non-geminate carrier recombination. Therefore, the observed slope changes from α=2β to α=β at the intensity threshold Iₜₕ. The power dependence of the UC PL does not show a distinct solvent- or annealing-dependent change (FIG. 56), indicating that the UC efficiency threshold Ii is invariant to the fabrication technique.

We have previously observed two independent rates of UC: rapid interface mediated UC and slow diffusion mediated UC which show vastly different observed UC QYs due to varying amounts of singlet back-transfer. As the Iₜₕ value appears invariant to the used composition, stoichiometry, solvent and second annealing step, changes in the underlying UC mechanism and actual UC efficiency are unlikely to be the root cause of the observed increased UC PL intensity in the annealed devices. Rather, we postulate that this is the result of the known changes in the perovskite/rubrene interface upon annealing, favoring diffusion-mediated UC far from the interface over interface-mediated TTA-UC, where the former has a higher observed QY due to reduced singlet back-transfer. The two mechanisms can be differentiated by time-resolved spectroscopy of the UC PL dynamics: interface-mediated transfer exhibits a short rise and a rapid decay, while diffusion-mediated TTA-UC is identified by its slow rise time, and long-lived decay corresponding to the triplet lifetime of rubrene in solid-state.

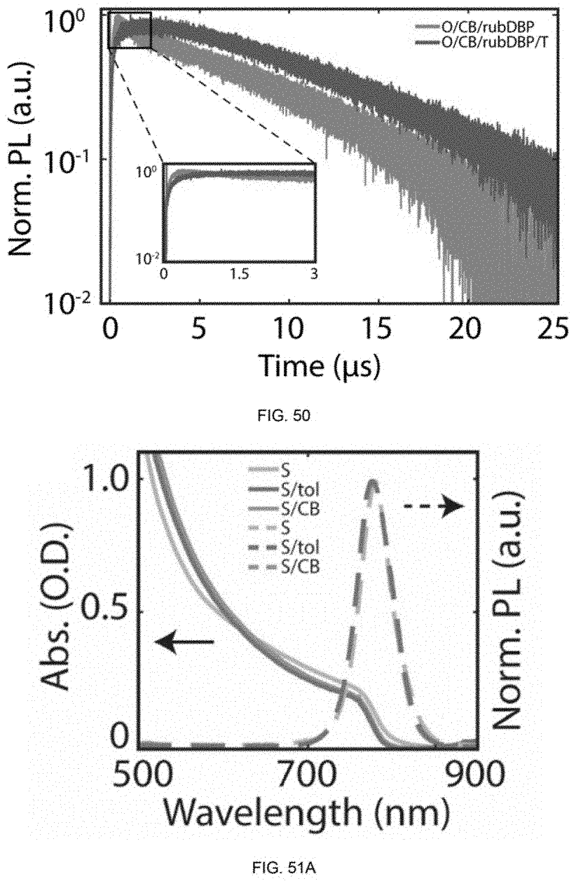

The obtained UC PL dynamics for the O/CB/rubDBP and O/CB/rubDBP/T are shown in FIG. 50 (compare FIG. 56 for additional compositions/treatments) further support this claim: after annealing, the mechanism shifts to a predominately diffusion-mediated UC process, as seen by the increase of the second rise time, in line with a higher observed UC intensity. Furthermore, this gives an indication that the interfacial region, presumably caused by a slight dissolution of the perovskite during the OSC deposition, has the capability to trap the triplet excitons and thus, yield the observed interface-mediated TTA-UC.

Conclusions.

To summarize, we find that the perovskite stoichiometry thus, PbI₂ surface passivation is not a key factor in the obtained UC intensity and efficiency. The threshold lI is invariant to the stoichiometry and all UC devices made with different processing conditions behave similarly. Known surface passivation by rubrene can likely counteract the passivation caused by excess PbI₂. Changing the composition from a MA-rich perovskite to a FA-rich perovskite yields a higher UC efficiency at the same integrated absorption value (compare Table 8). This is likely the result of increased quenching of charge carriers from the perovskite to the OSC layer, as seen in the PL decay dynamics. Therefore, the composition is a vital ingredient in the UC efficiency. CB and toluene have varying influence on the MA- and FA-rich perovskites, and can change the properties of the OSC due to variations in the molecular environment. Lastly, the largest effect is due to the post-processing annealing step, making this the key ingredient. The solution-based fabrication affects the perovskite surface, and the adverse effects can be negated by an additional annealing step to reform the perovskite surface. Annealing results in an increase in the fraction of high-efficiency diffusion-mediated TTA-UC, and therefore, an increase in the observed UC QY.

The spectrum of the 780 nm CW laser was fit by a Gaussian as shown in equation 6. The spectral overlap of the laser emission and the absorption for the perovskite film and the bilayers with the addition of rubDBP in tol or CB was integrated as a function of the wavelength and is shown in Table 8. T indicates annealed films.

$$f ( x ) = 0.9512 {e}^{- {( \frac{x - 778.3}{0.601 \; 9} )}^{2}} \qquad ( 6 )$$

TABLE 8
Calculated overlap integrals of the laser and the perovskite absorption

| | | tol | CB |
|---|---|---|---|
| S | 0.11451 | 0.11289 | 0.14989 |
| S/T | 0.12816 | 0.12924 | 0.12996 |
| O | 0.14813 | 0.14654 | 0.15195 |
| O/T | 0.15542 | 0.144 | 0.15342 |
| FO | 0.15697 | 0.14252 | 0.12289 |
| FO/T | 0.14802 | 0.15594 | 0.15433 |

It should be emphasized that the above-described embodiments of the present disclosure are merely possible examples of implementations, and are set forth only for a clear understanding of the principles of the disclosure. Many variations and modifications may be made to the above-described embodiments of the disclosure without departing substantially from the spirit and principles of the disclosure. All such modifications and variations are intended to be included herein within the scope of this disclosure.

We claim:

1. A method for upconversion of light in a solid-state optoelectronic device, the method comprising:
exposing a bulk semiconductor to a first light source comprising light of a first wavelength, wherein the bulk semiconductor is associated with an organic material capable of upconversion via triplet-triplet annihilation from triplet states in the organic material; and
observing light emitted from the organic material at a second wavelength, wherein the second wavelength is shorter than the first wavelength;
wherein exposing the bulk semiconductor to the first light source creates free charge carriers by promoting electrons from a valence band of the bulk semiconductor to a conduction band of the bulk semiconductor, and wherein the triplet states of the organic material are populated by charge transfer from the free charge carriers in the bulk semiconductor.

2. The method according to claim 1, wherein the first wavelength is between about 400 nm and about 1600 nm.

3. The method according to claim 1, wherein the bulk semiconductor comprises an organic or inorganic metal halide perovskite, a cadmium telluride, an indium phosphide, an indium gallium arsenide, a cadmium indium gallium selenide, a transition metal dichalcogenide, or a combination thereof.

4. The method according to claim 1, wherein the bulk semiconductor comprises a bandgap of from about 0.8 eV to about 2.5 eV.

5. The method according to claim 1, wherein the wherein the first wavelength is from about 10% to about 100% greater than the second wavelength.

6. The method according to claim 1, wherein the bulk semiconductor has an absorption coefficient at the first wavelength of from about 10² cm⁻¹ to about 104 cm⁻¹.

7. The method according to claim 1, wherein the organic material comprises
(i) an oligoacene, a heteroacene, a perylene, a phthalocyanine, an oligothiophene, a furane, an anthracene, a rubrene, a pentacene, or a derivative thereof, and
(ii) about 5% by weight or less of an emitter material based upon a total weight of the organic material.

8. A system for upconversion of light in a solid-state optoelectronic device, the system comprising a bulk semiconductor layer capable of absorbing a first wavelength of light and an organic material in contact with the bulk semiconductor, wherein the organic material is capable of upconversion via triplet-triplet annihilation from triplet states in the organic material to produce light at a second wavelength;
wherein exposing the bulk semiconductor to light at the first wavelength creates free charge carriers by promoting electrons from a valence band of the bulk semiconductor to a conduction band of the bulk semiconductor.

9. The system according to claim 8, wherein the first wavelength is between about 400 nm and about 1600 nm.

10. The system according to claim 8, wherein the bulk semiconductor comprises a metal halide perovskite, a cadmium telluride, an indium phosphide, an indium gallium arsenide, a cadmium indium gallium selenide, a transition metal dichalcogenide, or a combination thereof.

11. The system according to claim 8, wherein the bulk semiconductor comprises a bandgap of from about 0.8 eV to about 2.5 eV.

12. The system according to claim 8, wherein the wherein the first wavelength is from about 10% to about 100% greater than the second wavelength.

13. The system according to claim 8, wherein the bulk semiconductor has an absorption coefficient at the first wavelength of from about 10² cm⁻¹ to about 10 W cm⁻¹.

14. The system according to claim 8, wherein the organic material comprises an oligoacene, a heteroacene, a perylene, a phthalocyanine, an oligothiophene, a furane, an anthracene, a rubrene, a pentacene, or a derivative thereof.

15. The system according to claim 8, wherein the organic material further comprises a about 5% by weight or less of an emitter material based upon a total weight of the organic material.

16. A method for making a device for the upconversion of light, the method comprising:
(i) optionally spin-coating a base layer of a first bulk semiconductor solution on a substrate and annealing the base layer;
(ii) spin-coating a top layer of a second bulk semiconductor solution on the base layer, wherein the second bulk semiconductor solution further comprises an organic material;
(iii) annealing the top layer to form a film comprising a bulk semiconductor and an organic material; and
(iv) sealing the film in an oxygen-free environment;
wherein the bulk semiconductor is capable of absorbing a first wavelength of light and wherein the organic material is capable of upconversion via triplet-triplet annihilation from triplet states in the organic material to produce light at a second wavelength.

17. The method according to claim 16, wherein the organic material comprises an oligoacene, a heteroacene, a perylene, a phthalocyanine, an oligothiophene, a furane, an anthracene, a rubrene, a pentacene, or a derivative thereof.

18. The method according to claim 16, wherein the second bulk semiconductor solution further comprises about 5% by weight or less of an emitter material based upon a total weight of the organic material.

19. The method according to claim 16, wherein the bulk semiconductor comprises a metal halide perovskite, a cadmium telluride, an indium phosphide, an indium gallium arsenide, a cadmium indium gallium selenide, a transition metal dichalcogenide, or a combination thereof.

20. A device synthesized according to the method of claim 16.
